(19) United States
(12) Patent Application Publication
(10) Pub. No.: US 2026/0047043 A1
(43) Pub. Date: Feb. 12, 2026

(54) IMMERSION COOLING SYSTEMS, APPARATUS, AND RELATED METHODS

(71) Applicant: Intel Corporation, Santa Clara, CA (US)

(72) Inventors: Thomas Birch, Portland, OR (US); Jimmy Chuang, Taipei (TW); Yuehong Fan, Shanghai (CN); Jing-Hua John He, Portland, OR (US); Eric McAfee, Portland, OR (US); Suchismita Sarangi, Hillsboro, OR (US); David Shia, Portland, OR (US); Ming Tien, Taipei (TW); Chuanlou Wang, Shanghai (CN); Peng Wei, Shanghai (CN); Casey Winkel, Hillsboro, OR (US); Berhanu Wondimu, Beaverton, OR (US); Dong-Han Wu, Taipei (TW); Jay Wu, Taipei (TW); Shaorong Zhou, Shanghai (CN)

(73) Assignee: Intel Corporation, Santa Clara, CA (US)

(21) Appl. No.: 18/995,672

(22) PCT Filed: Sep. 30, 2022
(86) PCT No.: PCT/CN2022/123650

§ 371 Date: Jan. 16, 2025

(51) Int. Cl. H05K 7/20

(52) U.S. Cl. CPC H05K 7/20272; H05K 7/20145; H05K 7/20236; H05K 7/20263; H05K 7/20409; H05K 7/20718; H05K 7/20763

(57) ABSTRACT

Immersion cooling systems, apparatus, and related methods for cooling electronic computing platforms and/or associated electronic components are disclosed herein. An immersion cooling chassis includes a first face, a second face opposite the first face, a third face disposed between the first face and the second face, the third face perpendicular to the first face, a fourth face disposed between the first face and the second face, the fourth face perpendicular to the first face and opposite the third face, and a first portion to be cooled via a first convection of a coolant fluid, the first portion including a coolant inlet defined in the third face, and a coolant outlet defined in the first face, and a second portion to be cooled via a second convection of air, the second portion including an air inlet defined in the first face between the fourth face and the coolant outlet.

### FIELD OF THE DISCLOSURE

This disclosure relates generally to cooling systems and, more particularly, to immersion cooling systems, apparatus, and related methods.

### BACKGROUND

The use of liquids to cool electronic components is being explored for its benefits over more traditional air cooling systems, as there is an increasing need to address thermal management risks resulting from increased thermal design power in high performance systems (e.g., CPU and/or GPU servers in data centers, cloud computing, edge computing, and the like). More particularly, relative to air, liquid has inherent advantages of higher specific heat (when no boiling is involved) and higher latent heat of vaporization (when boiling is involved).

### BRIEF DESCRIPTION OF THE DRAWINGS

FIG. 1 illustrates one or more example environments in which teachings of this disclosure may be implemented.

FIG. 2 illustrates at least one example of a data center for executing workloads with disaggregated resources.

FIG. 3 illustrates at least one example of a pod that may be included in the data center of FIG. 2.

FIG. 4 is a perspective view of at least one example of a rack that may be included in the pod of FIG. 3.

FIG. 5 is a side elevation view of the rack of FIG. 4.

FIG. 6 is a perspective view of the rack of FIG. 4 having a sled mounted therein.

FIG. 7 is a is a block diagram of at least one example of a top side of the sled of FIG. 6.

FIG. 8 is a block diagram of at least one example of a bottom side of the sled of FIG. 7.

FIG. 9 is a block diagram of at least one example of a compute sled usable in the data center of FIG. 2.

FIG. 10 is a top perspective view of at least one example of the compute sled of FIG. 9.

FIG. 11 is a block diagram of at least one example of an accelerator sled usable in the data center of FIG. 2.

FIG. 12 is a top perspective view of at least one example of the accelerator sled of FIG. 10.

FIG. 13 is a block diagram of at least one example of a storage sled usable in the data center of FIG. 2.

FIG. 14 is a top perspective view of at least one example of the storage sled of FIG. 13.

FIG. 15 is a block diagram of at least one example of a memory sled usable in the data center of FIG. 2.

FIG. 16 is a block diagram of a system that may be established within the data center of FIG. 2 to execute workloads with managed nodes of disaggregated resources.

FIGS. 17A-17C are various views of a cut-away of a prior tank including a prior chassis.

FIGS. 18A-18C are various views of a cut-away of an example tank including an example chassis in accordance with teachings of this disclosure.

FIG. 19A is a front view of another example chassis in accordance with teachings of this disclosure.

FIG. 19B is a detail view of a portion of the chassis of FIG. 19A.

FIG. 20 is a perspective view of an example tank and an example chassis including an internal flow path in accordance with teachings of this disclosure.

FIG. 21 illustrates a flow of coolant between the tank of FIG. 20 and a cooling distribution unit.

FIG. 22 is a perspective view of the example manifold of FIG. 20.

FIG. 23 is a cross-sectional view of a portion of the tank and the manifold of FIG. 20.

FIG. 24 is a perspective view of the chassis of FIG. 20.

FIG. 25 is a front view of the chassis of FIG. 20 in a first configuration with the manifold of FIGS. 22 and 23.

FIGS. 26 and 27 are various views of a chassis and another example manifold in accordance with teachings of this disclosure.

FIG. 28 is a front view of a system including a prior tank and a prior chassis.

FIG. 29A is a front view of an example system including a tank and a chassis including a cold plate with an integrated pump in accordance with teachings of this disclosure.

FIG. 29B is a front view of the cold plate of FIG. 29A.

FIG. 30 is a front view of another example system including a tank and a chassis in accordance with teachings of this disclosure.

FIG. 31 is a front view of another example system including a tank and a chassis in accordance with teachings of this disclosure.

FIG. 32 is a front view of another example system including a tank and a chassis in accordance with teachings of this disclosure.

FIG. 33 is a front view of another example system including a tank and a chassis in accordance with teachings of this disclosure.

FIG. 34 is an exploded view of a prior heat sink.

FIGS. 35A and 35B are perspective views of a cold plate in accordance with teachings of this disclosure.

FIG. 36 is an exploded view of the cold plate of FIGS. 35A and 35B.

FIG. 37 is a flow diagram of example operations that can be used to assemble the cold plate of FIGS. 35A-36.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly that might, for example, otherwise share a same name.

As used herein, “approximately” and “about” refer to dimensions that may not be exact due to manufacturing tolerances and/or other real world imperfections.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “processor circuitry” is defined to include (i) one or more special purpose electrical circuits structured to perform specific operation(s) and including one or more semiconductor-based logic devices (e.g., electrical hardware implemented by one or more transistors), and/or (ii) one or more general purpose semiconductor-based electrical circuits programmed with instructions to perform specific operations and including one or more semiconductor-based logic devices (e.g., electrical hardware implemented by one or more transistors). Examples of processor circuitry include programmed microprocessors, Field Programmable Gate Arrays (FPGAs) that may instantiate instructions, Central Processor Units (CPUs), Graphics Processor Units (GPUs), Digital Signal Processors (DSPs), XPUs, or microcontrollers and integrated circuits such as Application Specific Integrated Circuits (ASICs). For example, an XPU may be implemented by a heterogeneous computing system including multiple types of processor circuitry (e.g., one or more FPGAs, one or more CPUs, one or more GPUs, one or more DSPs, etc., and/or a combination thereof) and application programming interface(s) (API(s)) that may assign computing task(s) to whichever one(s) of the multiple types of the processing circuitry is/are best suited to execute the computing task(s).

### DETAILED DESCRIPTION

As noted above, the use of liquids to cool electronic components is being explored for its benefits over more traditional air cooling systems, as there are increasing needs to address thermal management risks resulting from increased thermal design power in high performance systems (e.g., CPU and/or GPU servers in data centers, cloud computing, edge computing, and the like). More particularly, relative to air, liquid has inherent advantages of higher specific heat (when no boiling is involved) and higher latent heat of vaporization (when boiling is involved). In some instances, liquid can be used to indirectly cool electronic components by cooling a cold plate that is thermally coupled to the electronic components. An alternative approach is to directly immerse electronic components in the cooling liquid. In direct immersion cooling, the liquid can be in direct contact with the electronic components to directly draw away heat from the electronic components. To enable the cooling liquid to be in direct contact with electronic components, the cooling liquid is electrically insulative (e.g., a dielectric liquid).

Direct immersion cooling can involve at least one of single-phase immersion cooling or two-phase immersion cooling. As used herein, single-phase immersion cooling means the cooling fluid (sometimes also referred to herein as cooling liquid or coolant) used to cool electronic components draws heat away from heat sources (e.g., electronic components) without changing phase (e.g., without boiling and becoming vapor). Such cooling fluids are referred to herein as single-phase cooling fluids, liquids, or coolants. By contrast, as used herein, two-phase immersion cooling means the cooling fluid (in this case, a cooling liquid) vaporizes or boils from the heat generated by the electronic components to be cooled, thereby changing from the liquid phase to the vapor phase. The gaseous vapor may subsequently be condensed back into a liquid (e.g., via a condenser) to again be used in the cooling process. Such cooling fluids are referred to herein as two-phase cooling fluids, liquids, or coolants. Notably, gases (e.g., air) can also be used to cool components and, therefore, may also be referred to as a cooling fluid and/or a coolant. However, immersion cooling typically involves at least one cooling liquid (which may or may not change to the vapor phase when in use). Example systems, apparatus, and associated methods to improve immersion cooling systems and/or associated cooling processes are disclosed herein.

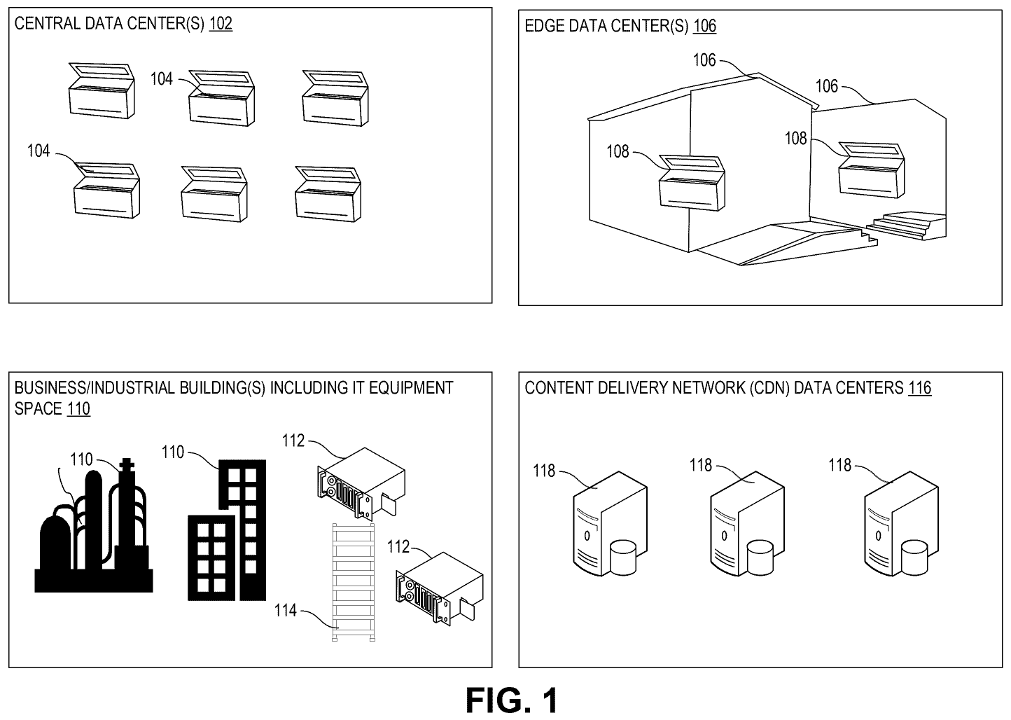

FIG. 1 illustrates one or more example environments in which teachings of this disclosure may be implemented. The example environment(s) of FIG. 1 can include one or more central data centers 102. The central data center(s) 102 can store a large number of servers used by, for instance, one or more organizations for data processing, storage, etc. As illustrated in FIG. 1, the central data center(s) 102 include a plurality of immersion tank(s) 104 to facilitate cooling of the servers and/or other electronic components stored at the central data center(s) 102. The immersion tank(s) 104 can provide for single-phase immersion cooling or two-phase immersion cooling.

The example environments of FIG. 1 can be part of an edge computing system. For instance, the example environments of FIG. 1 can include edge data centers or micro-data centers 106. The edge data center(s) 106 can include, for example, data centers located at a base of a cell tower. In some examples, the edge data center(s) 106 are located at or near a top of a cell tower and/or other utility pole. The edge data center(s) 106 include respective housings that store server(s), where the server(s) can be in communication with, for instance, the server(s) stored at the central data center(s) 102, client devices, and/or other computing devices in the edge network. Example housings of the edge data center(s) 106 may include materials that form one or more exterior surfaces that partially or fully protect contents therein, in which protection may include weather protection, hazardous environment protection (e.g., EMI, vibration, extreme temperatures), and/or enable submergibility. Example housings may include power circuitry to provide power for stationary and/or portable implementations, such as AC power inputs, DC power inputs, AC/DC or DC/AC converter(s), power regulators, transformers, charging circuitry, batteries, wired inputs and/or wireless power inputs. As illustrated in FIG. 1, the edge data center(s) 106 can include immersion tank(s) 108 to store server(s) and/or other electronic component(s) located at the edge data center(s) 106.

The example environment(s) of FIG. 1 can include buildings 110 for purposes of business and/or industry that store information technology (IT) equipment in, for example, one or more rooms of the building(s) 110. For example, as represented in FIG. 1, server(s) 112 can be stored with server rack(s) 114 that support the server(s) 112 (e.g., in an opening of slot of the rack 114). In some examples, the server(s) 112 located at the buildings 110 include on-premise server(s) of an edge computing network, where the on-premise server(s) are in communication with remote server(s) (e.g., the server(s) at the edge data center(s) 106) and/or other computing device(s) within an edge network.

The example environment(s) of FIG. 1 include content delivery network (CDN) data center(s) 116. The CDN data center(s) 116 of this example include server(s) 118 that cache content such as images, webpages, videos, etc. accessed via user devices. The server(s) 118 of the CDN data centers 116 can be disposed in immersion cooling tank(s) such as the immersion tanks 104, 108 shown in connection with the data centers 102, 106.

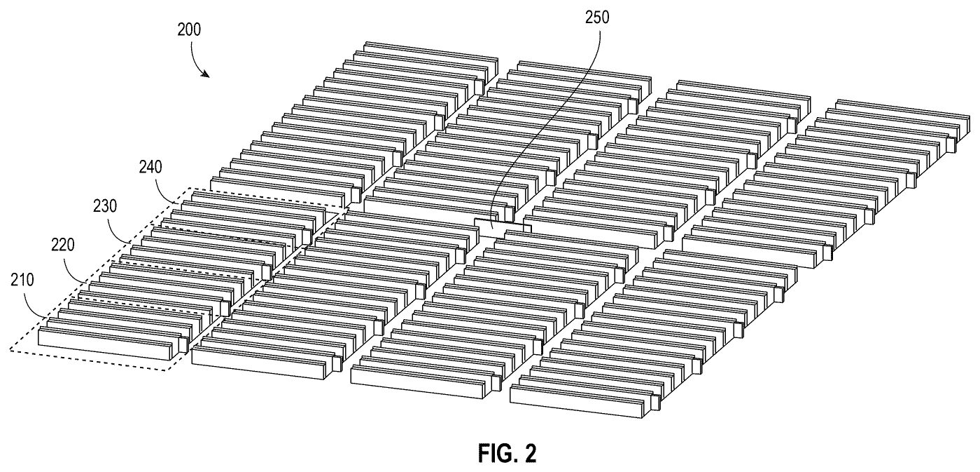

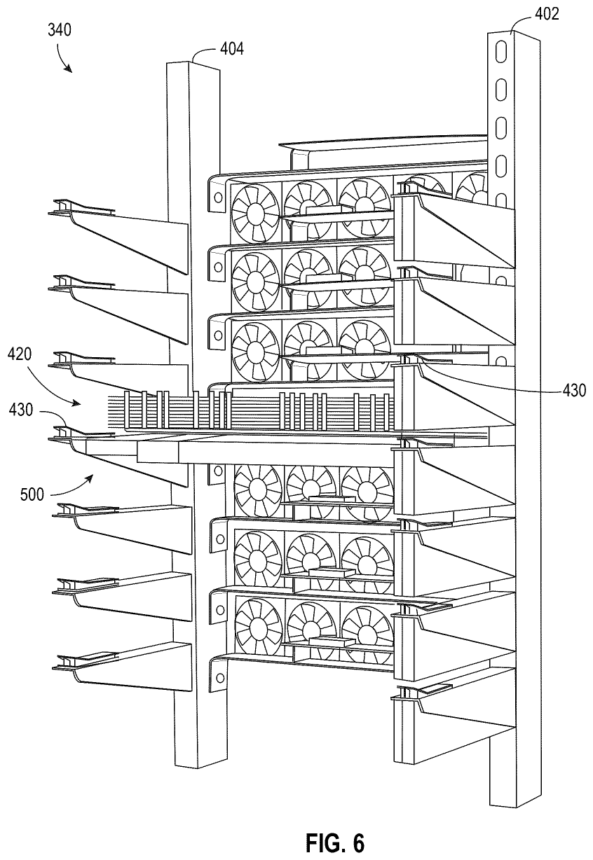

In some instances, the example data centers 102, 106, 116 and/or building(s) 110 of FIG. 1 include servers and/or other electronic components that are cooled independent of immersion tanks (e.g., the immersion tanks 104, 108) and/or an associated immersion cooling system. That is, in some examples, some or all of the servers and/or other electronic components in the data centers 102, 106, 116 and/or building(s) 110 can be cooled by air and/or liquid coolants without immersing the servers and/or other electronic components therein. Thus, in some examples, the immersion tanks 104, 108 of FIG. 1 may be omitted. Further, the example data centers 102, 106, 116 and/or building(s) 110 of FIG. 1 can correspond to, be implemented by, and/or be adaptations of the example data center 200 described in further detail below in connection with FIGS. 2-16.

Although a certain number of cooling tank(s) and other component(s) are shown in the figures, any number of such components may be present. Also, the example cooling data centers and/or other structures or environments disclosed herein are not limited to arrangements of the size that are depicted in FIG. 1. For instance, the structures containing example cooling systems and/or components thereof disclosed herein can be of a size that includes an opening to accommodate service personnel, such as the example data center(s) 106 of FIG. 1, but can also be smaller (e.g., a “doghouse” enclosure). For instance, the structures containing example cooling systems and/or components thereof disclosed herein can be sized such that access (e.g., the only access) to an interior of the structure is a port for service personnel to reach into the structure. In some examples, the structures containing example cooling systems and/or components thereof disclosed herein are be sized such that only a tool can reach into the enclosure because the structure may be supported by, for a utility pole or radio tower, or a larger structure.

FIG. 2 illustrates an example data center 200 in which disaggregated resources may cooperatively execute one or more workloads (e.g., applications on behalf of customers). The illustrated data center 200 includes multiple platforms 210, 220, 230, 240 (referred to herein as pods), each of which includes one or more rows of racks. Although the data center 200 is shown with multiple pods, in some examples, the data center 200 may be implemented as a single pod. As described in more detail herein, a rack may house multiple sleds. A sled may be primarily equipped with a particular type of resource (e.g., memory devices, data storage devices, accelerator devices, general purpose processors), i.e., resources that can be logically coupled to form a composed node. Some such nodes may act as, for example, a server. In the illustrative example, the sleds in the pods 210, 220, 230, 240 are connected to multiple pod switches (e.g., switches that route data communications to and from sleds within the pod). The pod switches, in turn, connect with spine switches 250 that switch communications among pods (e.g., the pods 210, 220, 230, 240) in the data center 200. In some examples, the sleds may be connected with a fabric using Intel Omni-Path™ technology. In other examples, the sleds may be connected with other fabrics, such as InfiniBand or Ethernet. As described in more detail herein, resources within the sleds in the data center 200 may be allocated to a group (referred to herein as a “managed node”) containing resources from one or more sleds to be collectively utilized in the execution of a workload. The workload can execute as if the resources belonging to the managed node were located on the same sled. The resources in a managed node may belong to sleds belonging to different racks, and even to different pods 210, 220, 230, 240. As such, some resources of a single sled may be allocated to one managed node while other resources of the same sled are allocated to a different managed node (e.g., first processor circuitry assigned to one managed node and second processor circuitry of the same sled assigned to a different managed node).

A data center including disaggregated resources, such as the data center 200, can be used in a wide variety of contexts, such as enterprise, government, cloud service provider, and communications service provider (e.g., Telco's), as well in a wide variety of sizes, from cloud service provider mega-data centers that consume over 200,000 sq. ft. to single- or multi-rack installations for use in base stations.

In some examples, the disaggregation of resources is accomplished by using individual sleds that include predominantly a single type of resource (e.g., compute sleds including primarily compute resources, memory sleds including primarily memory resources). The disaggregation of resources in this manner, and the selective allocation and deallocation of the disaggregated resources to form a managed node assigned to execute a workload, improves the operation and resource usage of the data center 200 relative to typical data centers. Such typical data centers include hyperconverged servers containing compute, memory, storage and perhaps additional resources in a single chassis. For example, because a given sled will contain mostly resources of a same particular type, resources of that type can be upgraded independently of other resources. Additionally, because different resource types (processors, storage, accelerators, etc.) typically have different refresh rates, greater resource utilization and reduced total cost of ownership may be achieved. For example, a data center operator can upgrade the processor circuitry throughout a facility by only swapping out the compute sleds. In such a case, accelerator and storage resources may not be contemporaneously upgraded and, rather, may be allowed to continue operating until those resources are scheduled for their own refresh. Resource utilization may also increase. For example, if managed nodes are composed based on requirements of the workloads that will be running on them, resources within a node are more likely to be fully utilized. Such utilization may allow for more managed nodes to run in a data center with a given set of resources, or for a data center expected to run a given set of workloads, to be built using fewer resources.

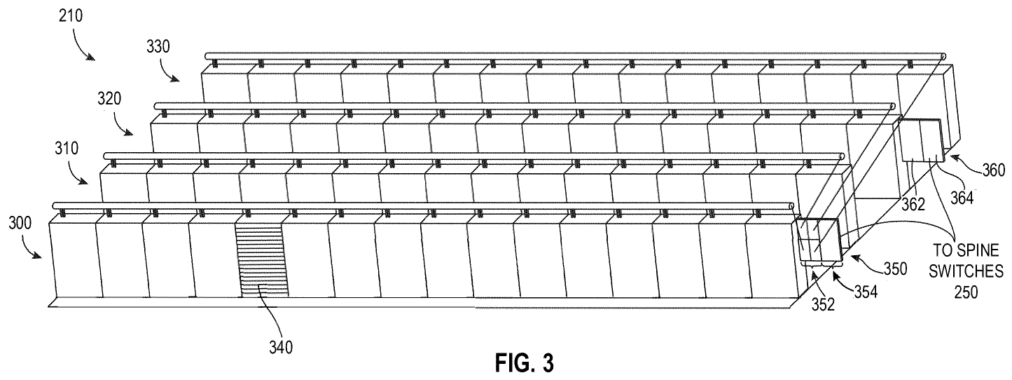

Referring now to FIG. 3, the pod 210, in the illustrative example, includes a set of rows 300, 310, 320, 330 of racks 340. Individual ones of the racks 340 may house multiple sleds (e.g., sixteen sleds) and provide power and data connections to the housed sleds, as described in more detail herein. In the illustrative example, the racks are connected to multiple pod switches 350, 360. The pod switch 350 includes a set of ports 352 to which the sleds of the racks of the pod 210 are connected and another set of ports 354 that connect the pod 210 to the spine switches 250 to provide connectivity to other pods in the data center 200. Similarly, the pod switch 360 includes a set of ports 362 to which the sleds of the racks of the pod 210 are connected and a set of ports 364 that connect the pod 210 to the spine switches 250. As such, the use of the pair of switches 350, 360 provides an amount of redundancy to the pod 210. For example, if either of the switches 350, 360 fails, the sleds in the pod 210 may still maintain data communication with the remainder of the data center 200 (e.g., sleds of other pods) through the other switch 350, 360. Furthermore, in the illustrative example, the switches 250, 350, 360 may be implemented as dual-mode optical switches, capable of routing both Ethernet protocol communications carrying Internet Protocol (IP) packets and communications according to a second, high-performance link-layer protocol (e.g., PCI Express) via optical signaling media of an optical fabric.

It should be appreciated that any one of the other pods 220, 230, 240 (as well as any additional pods of the data center 200) may be similarly structured as, and have components similar to, the pod 210 shown in and disclosed in regard to FIG. 3 (e.g., a given pod may have rows of racks housing multiple sleds as described above). Additionally, while two pod switches 350, 360 are shown, it should be understood that in other examples, a different number of pod switches may be present, providing even more failover capacity. In other examples, pods may be arranged differently than the rows-of-racks configuration shown in FIGS. 2 and 3. For example, a pod may include multiple sets of racks arranged radially, i.e., the racks are equidistant from a center switch.

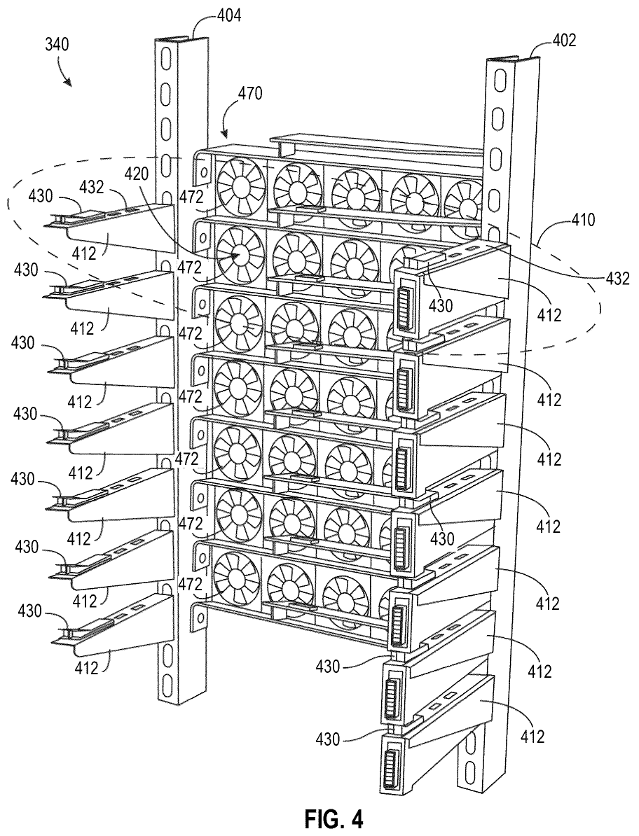

FIGS. 4-6 illustrate an example rack 340 of the data center 200. As shown in the illustrated example, the rack 340 includes two elongated support posts 402, 404, which are arranged vertically. For example, the elongated support posts 402, 404 may extend upwardly from a floor of the data center 200 when deployed. The rack 340 also includes one or more horizontal pairs 410 of elongated support arms 412 (identified in FIG. 4 via a dashed ellipse) configured to support a sled of the data center 200 as discussed below. One elongated support arm 412 of the pair of elongated support arms 412 extends outwardly from the elongated support post 402 and the other elongated support arm 412 extends outwardly from the elongated support post 404.

In the illustrative examples, at least some of the sleds of the data center 200 are chassis-less sleds. That is, such sleds have a chassis-less circuit board substrate on which physical resources (e.g., processors, memory, accelerators, storage, etc.) are mounted as discussed in more detail below. As such, the rack 340 is configured to receive the chassis-less sleds. For example, a given pair 410 of the elongated support arms 412 defines a sled slot 420 of the rack 340, which is configured to receive a corresponding chassis-less sled. To do so, the elongated support arms 412 include corresponding circuit board guides 430 configured to receive the chassis-less circuit board substrate of the sled. The circuit board guides 430 are secured to, or otherwise mounted to, a top side 432 of the corresponding elongated support arms 412. For example, in the illustrative example, the circuit board guides 430 are mounted at a distal end of the corresponding elongated support arm 412 relative to the corresponding elongated support post 402, 404. For clarity of FIGS. 4-6, not every circuit board guide 430 may be referenced in each figure. In some examples, at least some of the sleds include a chassis and the racks 340 are suitably adapted to receive the chassis.

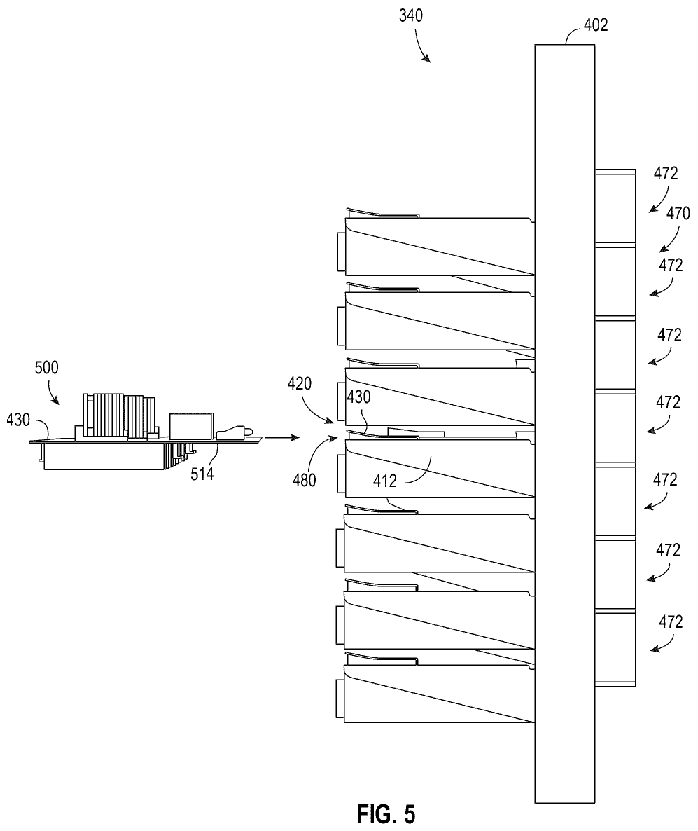

The circuit board guides 430 include an inner wall that defines a circuit board slot 480 configured to receive the chassis-less circuit board substrate of a sled 500 when the sled 500 is received in the corresponding sled slot 420 of the rack 340. To do so, as shown in FIG. 5, a user (or robot) aligns the chassis-less circuit board substrate of an illustrative chassis-less sled 500 to a sled slot 420. The user, or robot, may then slide the chassis-less circuit board substrate forward into the sled slot 420 such that each side edge 514 of the chassis-less circuit board substrate is received in a corresponding circuit board slot 480 of the circuit board guides 430 of the pair 410 of elongated support arms 412 that define the corresponding sled slot 420 as shown in FIG. 5. By having robotically accessible and robotically manipulable sleds including disaggregated resources, the different types of resource can be upgraded independently of one other and at their own optimized refresh rate. Furthermore, the sleds are configured to blindly mate with power and data communication cables in the rack 340, enhancing their ability to be quickly removed, upgraded, reinstalled, and/or replaced. As such, in some examples, the data center 200 may operate (e.g., execute workloads, undergo maintenance and/or upgrades, etc.) without human involvement on the data center floor. In other examples, a human may facilitate one or more maintenance or upgrade operations in the data center 200.

It should be appreciated that the circuit board guides 430 are dual sided. That is, a circuit board guide 430 includes an inner wall that defines a circuit board slot 480 on each side of the circuit board guide 430. In this way, the circuit board guide 430 can support a chassis-less circuit board substrate on either side. As such, a single additional elongated support post may be added to the rack 340 to turn the rack 340 into a two-rack solution that can hold twice as many sled slots 420 as shown in FIG. 4. The illustrative rack 340 includes seven pairs 410 of elongated support arms 412 that define seven corresponding sled slots 420. The sled slots 420 are configured to receive and support a corresponding sled 500 as discussed above. In other examples, the rack 340 may include additional or fewer pairs 410 of elongated support arms 412 (i.e., additional or fewer sled slots 420). It should be appreciated that because the sled 500 is chassis-less, the sled 500 may have an overall height that is different than typical servers. As such, in some examples, the height of a given sled slot 420 may be shorter than the height of a typical server (e.g., shorter than a single rank unit, referred to as “1U”). That is, the vertical distance between pairs 410 of elongated support arms 412 may be less than a standard rack unit “1U.” Additionally, due to the relative decrease in height of the sled slots 420, the overall height of the rack 340 in some examples may be shorter than the height of traditional rack enclosures. For example, in some examples, the elongated support posts 402, 404 may have a length of six feet or less. Again, in other examples, the rack 340 may have different dimensions. For example, in some examples, the vertical distance between pairs 410 of elongated support arms 412 may be greater than a standard rack unit “1U”. In such examples, the increased vertical distance between the sleds allows for larger heatsinks to be attached to the physical resources and for larger fans to be used (e.g., in the fan array 470 described below) for cooling the sleds, which in turn can allow the physical resources to operate at increased power levels. Further, it should be appreciated that the rack 340 does not include any walls, enclosures, or the like. Rather, the rack 340 is an enclosure-less rack that is opened to the local environment. In some cases, an end plate may be attached to one of the elongated support posts 402, 404 in those situations in which the rack 340 forms an end-of-row rack in the data center 200.

In some examples, various interconnects may be routed upwardly or downwardly through the elongated support posts 402, 404. To facilitate such routing, the elongated support posts 402, 404 include an inner wall that defines an inner chamber in which interconnects may be located. The interconnects routed through the elongated support posts 402, 404 may be implemented as any type of interconnects including, but not limited to, data or communication interconnects to provide communication connections to the sled slots 420, power interconnects to provide power to the sled slots 420, and/or other types of interconnects.

The rack 340, in the illustrative example, includes a support platform on which a corresponding optical data connector (not shown) is mounted. Such optical data connectors are associated with corresponding sled slots 420 and are configured to mate with optical data connectors of corresponding sleds 500 when the sleds 500 are received in the corresponding sled slots 420. In some examples, optical connections between components (e.g., sleds, racks, and switches) in the data center 200 are made with a blind mate optical connection. For example, a door on a given cable may prevent dust from contaminating the fiber inside the cable. In the process of connecting to a blind mate optical connector mechanism, the door is pushed open when the end of the cable approaches or enters the connector mechanism. Subsequently, the optical fiber inside the cable may enter a gel within the connector mechanism and the optical fiber of one cable comes into contact with the optical fiber of another cable within the gel inside the connector mechanism.

The illustrative rack 340 also includes a fan array 470 coupled to the cross-support arms of the rack 340. The fan array 470 includes one or more rows of cooling fans 472, which are aligned in a horizontal line between the elongated support posts 402, 404. In the illustrative example, the fan array 470 includes a row of cooling fans 472 for the different sled slots 420 of the rack 340. As discussed above, the sleds 500 do not include any on-board cooling system in the illustrative example and, as such, the fan array 470 provides cooling for such sleds 500 received in the rack 340. In other examples, some or all of the sleds 500 can include on-board cooling systems. Further, in some examples, the sleds 500 and/or the racks 340 may include and/or incorporate a liquid and/or immersion cooling system to facilitate cooling of electronic component(s) on the sleds 500. The rack 340, in the illustrative example, also includes different power supplies associated with different ones of the sled slots 420. A given power supply is secured to one of the elongated support arms 412 of the pair 410 of elongated support arms 412 that define the corresponding sled slot 420. For example, the rack 340 may include a power supply coupled or secured to individual ones of the elongated support arms 412 extending from the elongated support post 402. A given power supply includes a power connector configured to mate with a power connector of a sled 500 when the sled 500 is received in the corresponding sled slot 420. In the illustrative example, the sled 500 does not include any on-board power supply and, as such, the power supplies provided in the rack 340 supply power to corresponding sleds 500 when mounted to the rack 340. A given power supply is configured to satisfy the power requirements for its associated sled, which can differ from sled to sled. Additionally, the power supplies provided in the rack 340 can operate independent of each other. That is, within a single rack, a first power supply providing power to a compute sled can provide power levels that are different than power levels supplied by a second power supply providing power to an accelerator sled. The power supplies may be controllable at the sled level or rack level, and may be controlled locally by components on the associated sled or remotely, such as by another sled or an orchestrator.

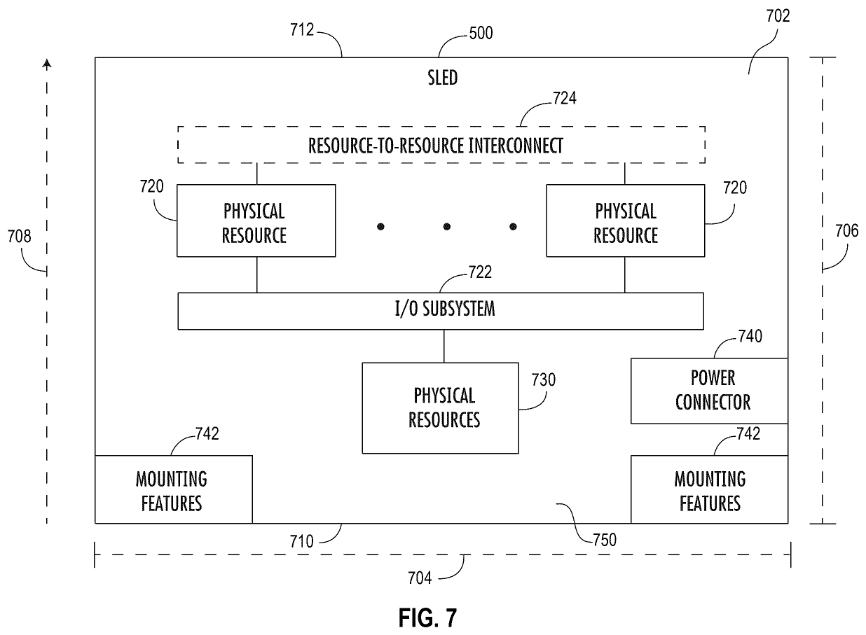

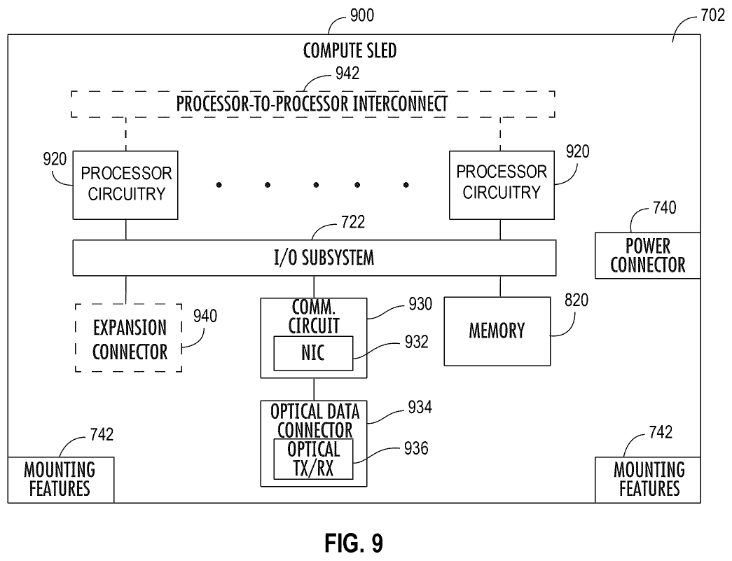

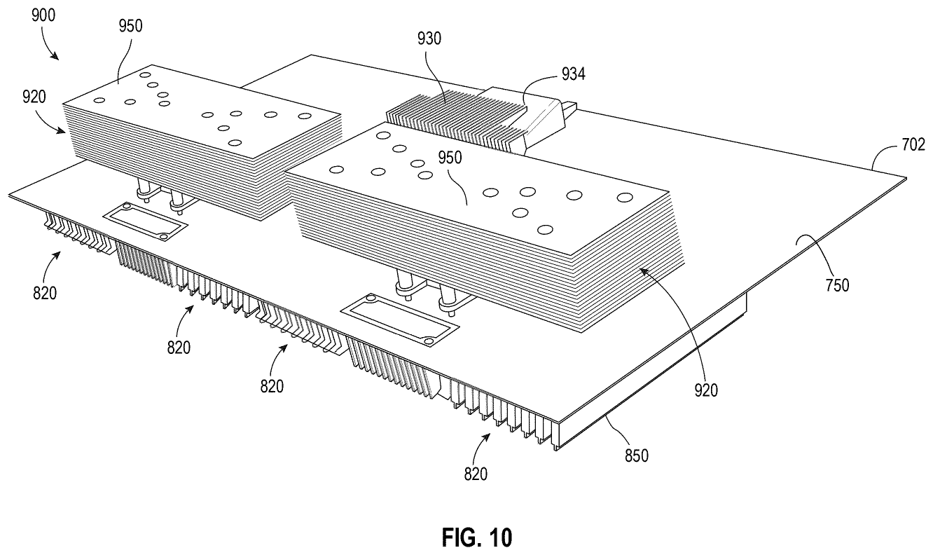

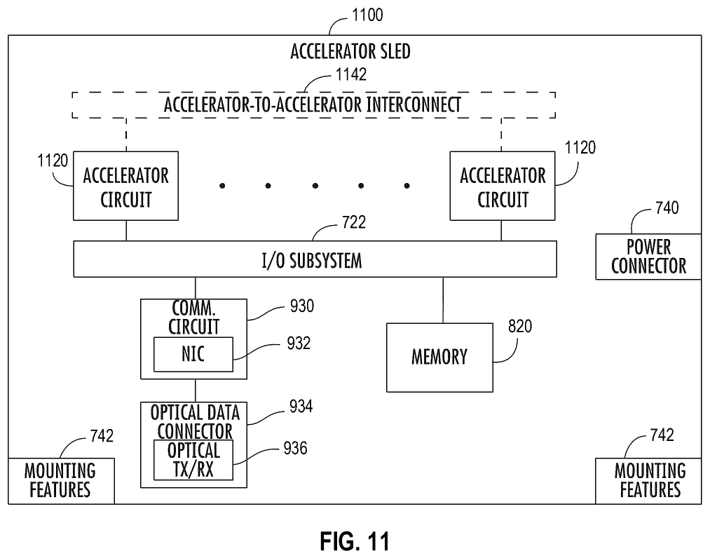

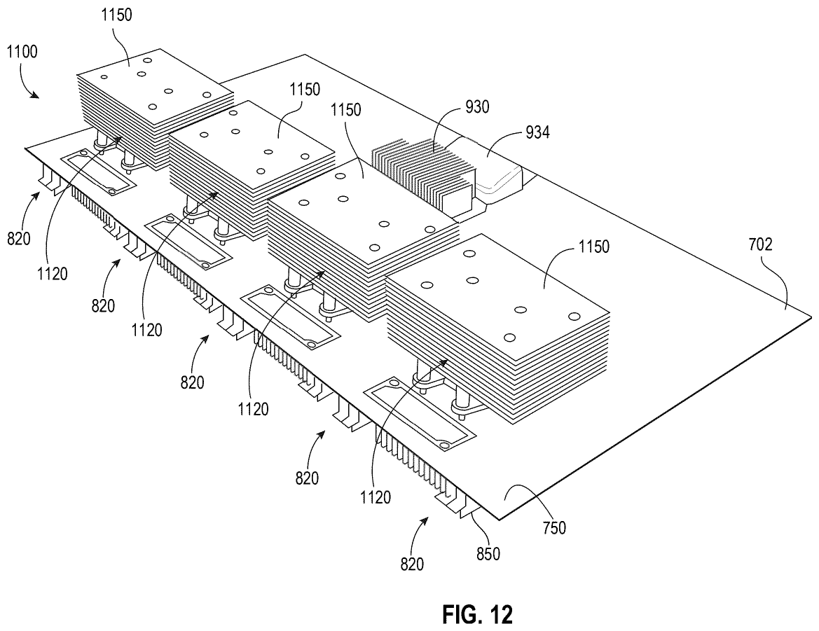

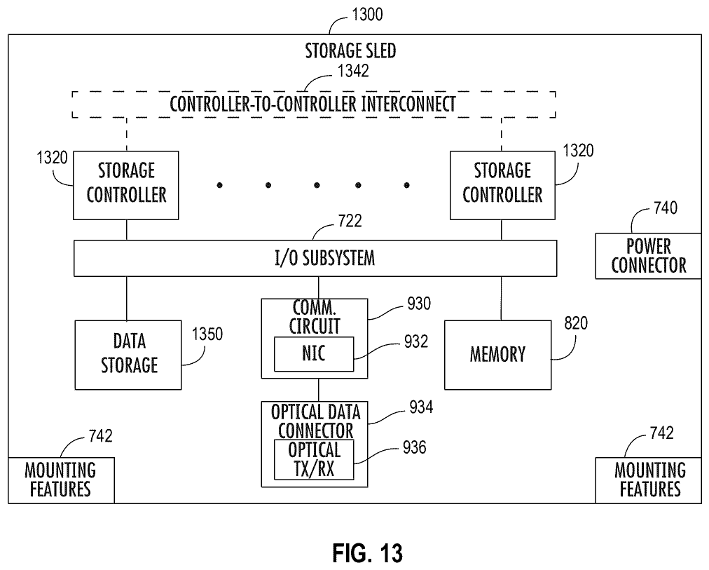

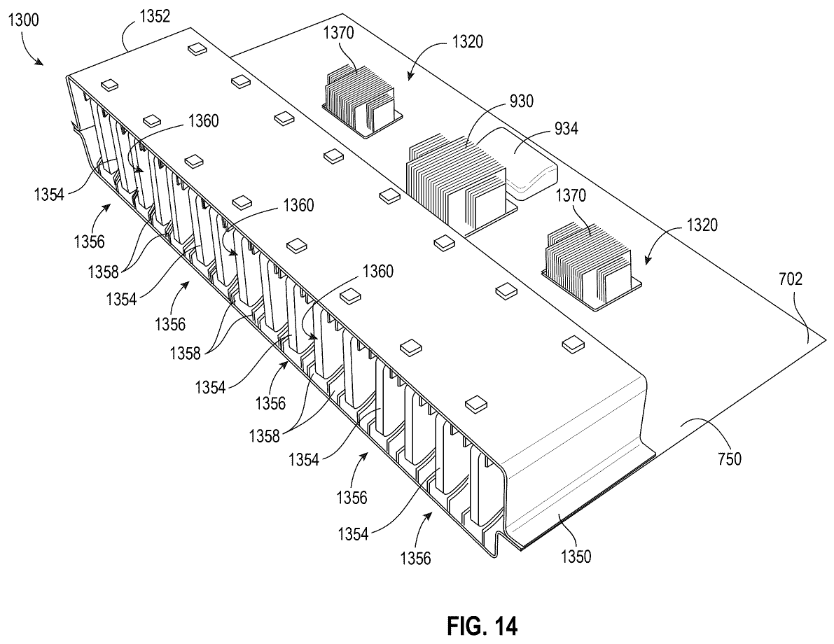

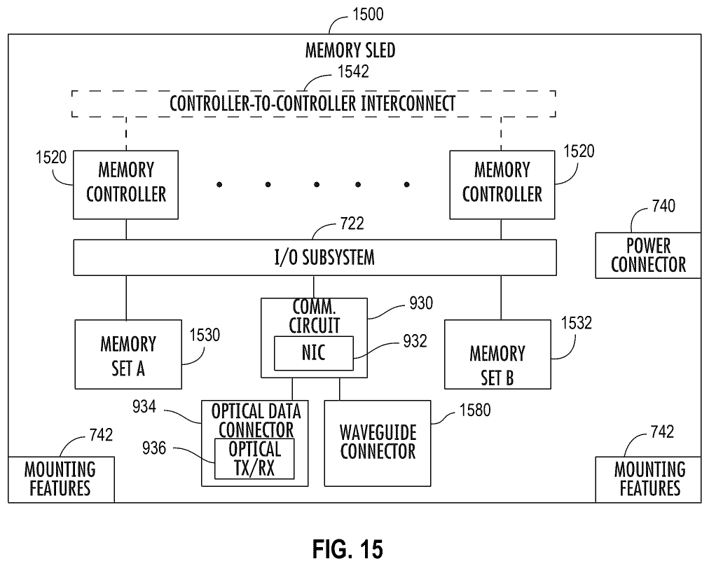

Referring now to FIG. 7, the sled 500, in the illustrative example, is configured to be mounted in a corresponding rack 340 of the data center 200 as discussed above. In some examples, a give sled 500 may be optimized or otherwise configured for performing particular tasks, such as compute tasks, acceleration tasks, data storage tasks, etc. For example, the sled 500 may be implemented as a compute sled 900 as discussed below in regard to FIGS. 9 and 10, an accelerator sled 1100 as discussed below in regard to FIGS. 11 and 12, a storage sled 1300 as discussed below in regard to FIGS. 13 and 14, or as a sled optimized or otherwise configured to perform other specialized tasks, such as a memory sled 1500, discussed below in regard to FIG. 15.

As discussed above, the illustrative sled 500 includes a chassis-less circuit board substrate 702, which supports various physical resources (e.g., electrical components) mounted thereon. It should be appreciated that the circuit board substrate 702 is “chassis-less” in that the sled 500 does not include a housing or enclosure. Rather, the chassis-less circuit board substrate 702 is open to the local environment. The chassis-less circuit board substrate 702 may be formed from any material capable of supporting the various electrical components mounted thereon. For example, in an illustrative example, the chassis-less circuit board substrate 702 is formed from an FR-4 glass-reinforced epoxy laminate material. Other materials may be used to form the chassis-less circuit board substrate 702 in other examples.

As discussed in more detail below, the chassis-less circuit board substrate 702 includes multiple features that improve the thermal cooling characteristics of the various electrical components mounted on the chassis-less circuit board substrate 702. As discussed, the chassis-less circuit board substrate 702 does not include a housing or enclosure, which may improve the airflow over the electrical components of the sled 500 by reducing those structures that may inhibit air flow. For example, because the chassis-less circuit board substrate 702 is not positioned in an individual housing or enclosure, there is no vertically-arranged backplane (e.g., a back plate of the chassis) attached to the chassis-less circuit board substrate 702, which could inhibit air flow across the electrical components. Additionally, the chassis-less circuit board substrate 702 has a geometric shape configured to reduce the length of the airflow path across the electrical components mounted to the chassis-less circuit board substrate 702. For example, the illustrative chassis-less circuit board substrate 702 has a width 704 that is greater than a depth 706 of the chassis-less circuit board substrate 702. In one particular example, the chassis-less circuit board substrate 702 has a width of about 21 inches and a depth of about 9 inches, compared to a typical server that has a width of about 17 inches and a depth of about 39 inches. As such, an airflow path 708 that extends from a front edge 710 of the chassis-less circuit board substrate 702 toward a rear edge 712 has a shorter distance relative to typical servers, which may improve the thermal cooling characteristics of the sled 500. Furthermore, although not illustrated in FIG. 7, the various physical resources mounted to the chassis-less circuit board substrate 702 in this example are mounted in corresponding locations such that no two substantively heat-producing electrical components shadow each other as discussed in more detail below. That is, no two electrical components, which produce appreciable heat during operation (i.e., greater than a nominal heat sufficient enough to adversely impact the cooling of another electrical component), are mounted to the chassis-less circuit board substrate 702 linearly in-line with each other along the direction of the airflow path 708 (i.e., along a direction extending from the front edge 710 toward the rear edge 712 of the chassis-less circuit board substrate 702). The placement and/or structure of the features may be suitable adapted when the electrical component(s) are being cooled via liquid (e.g., one phase or two phase immersion cooling).

As discussed above, the illustrative sled 500 includes one or more physical resources 720 mounted to a top side 750 of the chassis-less circuit board substrate 702. Although two physical resources 720 are shown in FIG. 7, it should be appreciated that the sled 500 may include one, two, or more physical resources 720 in other examples. The physical resources 720 may be implemented as any type of processor, controller, or other compute circuit capable of performing various tasks such as compute functions and/or controlling the functions of the sled 500 depending on, for example, the type or intended functionality of the sled 500. For example, as discussed in more detail below, the physical resources 720 may be implemented as high-performance processors in examples in which the sled 500 is implemented as a compute sled, as accelerator co-processors or circuits in examples in which the sled 500 is implemented as an accelerator sled, storage controllers in examples in which the sled 500 is implemented as a storage sled, or a set of memory devices in examples in which the sled 500 is implemented as a memory sled.

The sled 500 also includes one or more additional physical resources 730 mounted to the top side 750 of the chassis-less circuit board substrate 702. In the illustrative example, the additional physical resources include a network interface controller (NIC) as discussed in more detail below. Depending on the type and functionality of the sled 500, the physical resources 730 may include additional or other electrical components, circuits, and/or devices in other examples.

The physical resources 720 are communicatively coupled to the physical resources 730 via an input/output (I/O) subsystem 722. The I/O subsystem 722 may be implemented as circuitry and/or components to facilitate input/output operations with the physical resources 720, the physical resources 730, and/or other components of the sled 500. For example, the I/O subsystem 722 may be implemented as, or otherwise include, memory controller hubs, input/output control hubs, integrated sensor hubs, firmware devices, communication links (e.g., point-to-point links, bus links, wires, cables, waveguides, light guides, printed circuit board traces, etc.), and/or other components and subsystems to facilitate the input/output operations. In the illustrative example, the I/O subsystem 722 is implemented as, or otherwise includes, a double data rate 4 (DDR4) data bus or a DDR5 data bus.

In some examples, the sled 500 may also include a resource-to-resource interconnect 724. The resource-to-resource interconnect 724 may be implemented as any type of communication interconnect capable of facilitating resource-to-resource communications. In the illustrative example, the resource-to-resource interconnect 724 is implemented as a high-speed point-to-point interconnect (e.g., faster than the I/O subsystem 722). For example, the resource-to-resource interconnect 724 may be implemented as a QuickPath Interconnect (QPI), an UltraPath Interconnect (UPI), or other high-speed point-to-point interconnect dedicated to resource-to-resource communications.

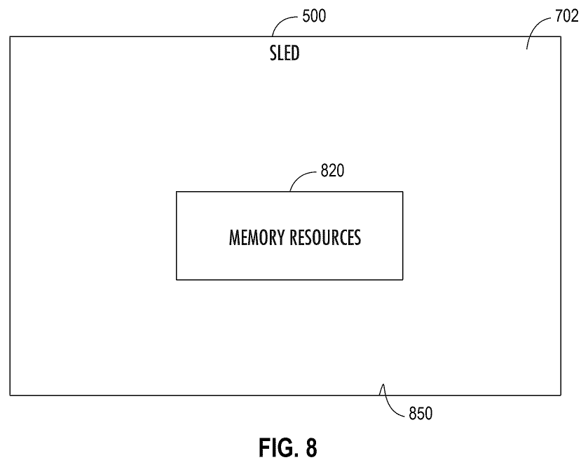

The sled 500 also includes a power connector 740 configured to mate with a corresponding power connector of the rack 340 when the sled 500 is mounted in the corresponding rack 340. The sled 500 receives power from a power supply of the rack 340 via the power connector 740 to supply power to the various electrical components of the sled 500. That is, the sled 500 does not include any local power supply (i.e., an on-board power supply) to provide power to the electrical components of the sled 500. The exclusion of a local or on-board power supply facilitates the reduction in the overall footprint of the chassis-less circuit board substrate 702, which may increase the thermal cooling characteristics of the various electrical components mounted on the chassis-less circuit board substrate 702 as discussed above. In some examples, voltage regulators are placed on a bottom side 850 (see FIG. 8) of the chassis-less circuit board substrate 702 directly opposite of processor circuitry 920 (see FIG. 9), and power is routed from the voltage regulators to the processor circuitry 920 by vias extending through the circuit board substrate 702. Such a configuration provides an increased thermal budget, additional current and/or voltage, and better voltage control relative to typical printed circuit boards in which processor power is delivered from a voltage regulator, in part, by printed circuit traces.

In some examples, the sled 500 may also include mounting features 742 configured to mate with a mounting arm, or other structure, of a robot to facilitate the placement of the sled 700 in a rack 340 by the robot. The mounting features 742 may be implemented as any type of physical structures that allow the robot to grasp the sled 500 without damaging the chassis-less circuit board substrate 702 or the electrical components mounted thereto. For example, in some examples, the mounting features 742 may be implemented as non-conductive pads attached to the chassis-less circuit board substrate 702. In other examples, the mounting features may be implemented as brackets, braces, or other similar structures attached to the chassis-less circuit board substrate 702. The particular number, shape, size, and/or make-up of the mounting feature 742 may depend on the design of the robot configured to manage the sled 500.

Referring now to FIG. 8, in addition to the physical resources 730 mounted on the top side 750 of the chassis-less circuit board substrate 702, the sled 500 also includes one or more memory devices 820 mounted to a bottom side 850 of the chassis-less circuit board substrate 702. That is, the chassis-less circuit board substrate 702 is implemented as a double-sided circuit board. The physical resources 720 are communicatively coupled to the memory devices 820 via the I/O subsystem 722. For example, the physical resources 720 and the memory devices 820 may be communicatively coupled by one or more vias extending through the chassis-less circuit board substrate 702. Different ones of the physical resources 720 may be communicatively coupled to different sets of one or more memory devices 820 in some examples. Alternatively, in other examples, different ones of the physical resources 720 may be communicatively coupled to the same ones of the memory devices 820.

The memory devices 820 may be implemented as any type of memory device capable of storing data for the physical resources 720 during operation of the sled 500, such as any type of volatile (e.g., dynamic random access memory (DRAM), etc.) or non-volatile memory. Volatile memory may be a storage medium that requires power to maintain the state of data stored by the medium. Non-limiting examples of volatile memory may include various types of random access memory (RAM), such as dynamic random access memory (DRAM) or static random access memory (SRAM). One particular type of DRAM that may be used in a memory module is synchronous dynamic random access memory (SDRAM). In particular examples, DRAM of a memory component may comply with a standard promulgated by JEDEC, such as JESD79F for DDR SDRAM, JESD79-2F for DDR2 SDRAM, JESD79-3F for DDR3 SDRAM, JESD79-4A for DDR4 SDRAM, JESD209 for Low Power DDR (LPDDR), JESD209-2 for LPDDR2, JESD209-3 for LPDDR3, and JESD209-4 for LPDDR4. Such standards (and similar standards) may be referred to as DDR-based standards and communication interfaces of the storage devices that implement such standards may be referred to as DDR-based interfaces.

In one example, the memory device is a block addressable memory device, such as those based on NAND or NOR technologies. A memory device may also include next-generation nonvolatile devices, such as Intel 3D XPoint™ memory or other byte addressable write-in-place nonvolatile memory devices. In one example, the memory device may be or may include memory devices that use chalcogenide glass, multi-threshold level NAND flash memory, NOR flash memory, single or multi-level Phase Change Memory (PCM), a resistive memory, nanowire memory, ferroelectric transistor random access memory (FeTRAM), anti-ferroelectric memory, magnetoresistive random access memory (MRAM) memory that incorporates memristor technology, resistive memory including the metal oxide base, the oxygen vacancy base and the conductive bridge Random Access Memory (CB-RAM), or spin transfer torque (STT)-MRAM, a spintronic magnetic junction memory based device, a magnetic tunneling junction (MTJ) based device, a DW (Domain Wall) and SOT (Spin Orbit Transfer) based device, a thyristor based memory device, or a combination of any of the above, or other memory. The memory device may refer to the die itself and/or to a packaged memory product. In some examples, the memory device may include a transistor-less stackable cross point architecture in which memory cells sit at the intersection of word lines and bit lines and are individually addressable and in which bit storage is based on a change in bulk resistance.

Referring now to FIG. 9, in some examples, the sled 500 may be implemented as a compute sled 900. The compute sled 900 is optimized, or otherwise configured, to perform compute tasks. As discussed above, the compute sled 900 may rely on other sleds, such as acceleration sleds and/or storage sleds, to perform such compute tasks. The compute sled 900 includes various physical resources (e.g., electrical components) similar to the physical resources of the sled 500, which have been identified in FIG. 9 using the same reference numbers. The description of such components provided above in regard to FIGS. 7 and 8 applies to the corresponding components of the compute sled 900 and is not repeated herein for clarity of the description of the compute sled 900.

In the illustrative compute sled 900, the physical resources 720 include processor circuitry 920. Although only two blocks of processor circuitry 920 are shown in FIG. 9, it should be appreciated that the compute sled 900 may include additional processor circuits 920 in other examples. Illustratively, the processor circuitry 920 corresponds to high-performance processors 920 and may be configured to operate at a relatively high power rating. Although the high-performance processor circuitry 920 generates additional heat operating at power ratings greater than typical processors (which operate at around 155-230 W), the enhanced thermal cooling characteristics of the chassis-less circuit board substrate 702 discussed above facilitate the higher power operation. For example, in the illustrative example, the processor circuitry 920 is configured to operate at a power rating of at least 250 W. In some examples, the processor circuitry 920 may be configured to operate at a power rating of at least 350 W.

In some examples, the compute sled 900 may also include a processor-to-processor interconnect 942. Similar to the resource-to-resource interconnect 724 of the sled 500 discussed above, the processor-to-processor interconnect 942 may be implemented as any type of communication interconnect capable of facilitating processor-to-processor interconnect 942 communications. In the illustrative example, the processor-to-processor interconnect 942 is implemented as a high-speed point-to-point interconnect (e.g., faster than the I/O subsystem 722). For example, the processor-to-processor interconnect 942 may be implemented as a QuickPath Interconnect (QPI), an UltraPath Interconnect (UPI), or other high-speed point-to-point interconnect dedicated to processor-to-processor communications.

The compute sled 900 also includes a communication circuit 930. The illustrative communication circuit 930 includes a network interface controller (NIC) 932, which may also be referred to as a host fabric interface (HFI). The NIC 932 may be implemented as, or otherwise include, any type of integrated circuit, discrete circuits, controller chips, chipsets, add-in-boards, daughtercards, network interface cards, or other devices that may be used by the compute sled 900 to connect with another compute device (e.g., with other sleds 500). In some examples, the NIC 932 may be implemented as part of a system-on-a-chip (SoC) that includes one or more processors, or included on a multichip package that also contains one or more processors. In some examples, the NIC 932 may include a local processor (not shown) and/or a local memory (not shown) that are both local to the NIC 932. In such examples, the local processor of the NIC 932 may be capable of performing one or more of the functions of the processor circuitry 920. Additionally or alternatively, in such examples, the local memory of the NIC 932 may be integrated into one or more components of the compute sled at the board level, socket level, chip level, and/or other levels.

The communication circuit 930 is communicatively coupled to an optical data connector 934. The optical data connector 934 is configured to mate with a corresponding optical data connector of the rack 340 when the compute sled 900 is mounted in the rack 340. Illustratively, the optical data connector 934 includes a plurality of optical fibers which lead from a mating surface of the optical data connector 934 to an optical transceiver 936. The optical transceiver 936 is configured to convert incoming optical signals from the rack-side optical data connector to electrical signals and to convert electrical signals to outgoing optical signals to the rack-side optical data connector. Although shown as forming part of the optical data connector 934 in the illustrative example, the optical transceiver 936 may form a portion of the communication circuit 930 in other examples.

In some examples, the compute sled 900 may also include an expansion connector 940. In such examples, the expansion connector 940 is configured to mate with a corresponding connector of an expansion chassis-less circuit board substrate to provide additional physical resources to the compute sled 900. The additional physical resources may be used, for example, by the processor circuitry 920 during operation of the compute sled 900. The expansion chassis-less circuit board substrate may be substantially similar to the chassis-less circuit board substrate 702 discussed above and may include various electrical components mounted thereto. The particular electrical components mounted to the expansion chassis-less circuit board substrate may depend on the intended functionality of the expansion chassis-less circuit board substrate. For example, the expansion chassis-less circuit board substrate may provide additional compute resources, memory resources, and/or storage resources. As such, the additional physical resources of the expansion chassis-less circuit board substrate may include, but is not limited to, processors, memory devices, storage devices, and/or accelerator circuits including, for example, field programmable gate arrays (FPGA), application-specific integrated circuits (ASICs), security co-processors, graphics processing units (GPUs), machine learning circuits, or other specialized processors, controllers, devices, and/or circuits.

Referring now to FIG. 10, an illustrative example of the compute sled 900 is shown. As shown, the processor circuitry 920, communication circuit 930, and optical data connector 934 are mounted to the top side 750 of the chassis-less circuit board substrate 702. Any suitable attachment or mounting technology may be used to mount the physical resources of the compute sled 900 to the chassis-less circuit board substrate 702. For example, the various physical resources may be mounted in corresponding sockets (e.g., a processor socket), holders, or brackets. In some cases, some of the electrical components may be directly mounted to the chassis-less circuit board substrate 702 via soldering or similar techniques.

As discussed above, the separate processor circuitry 920 and the communication circuit 930 are mounted to the top side 750 of the chassis-less circuit board substrate 702 such that no two heat-producing, electrical components shadow each other. In the illustrative example, the processor circuitry 920 and the communication circuit 930 are mounted in corresponding locations on the top side 750 of the chassis-less circuit board substrate 702 such that no two of those physical resources are linearly in-line with others along the direction of the airflow path 708. It should be appreciated that, although the optical data connector 934 is in-line with the communication circuit 930, the optical data connector 934 produces no or nominal heat during operation.

The memory devices 820 of the compute sled 900 are mounted to the bottom side 850 of the of the chassis-less circuit board substrate 702 as discussed above in regard to the sled 500. Although mounted to the bottom side 850, the memory devices 820 are communicatively coupled to the processor circuitry 920 located on the top side 750 via the I/O subsystem 722. Because the chassis-less circuit board substrate 702 is implemented as a double-sided circuit board, the memory devices 820 and the processor circuitry 920 may be communicatively coupled by one or more vias, connectors, or other mechanisms extending through the chassis-less circuit board substrate 702. Different processor circuitry 920 (e.g., different processors) may be communicatively coupled to a different set of one or more memory devices 820 in some examples. Alternatively, in other examples, different processor circuitry 920 (e.g., different processors) may be communicatively coupled to the same ones of the memory devices 820. In some examples, the memory devices 820 may be mounted to one or more memory mezzanines on the bottom side of the chassis-less circuit board substrate 702 and may interconnect with a corresponding processor circuitry 920 through a ball-grid array.

Different processor circuitry 920 (e.g., different processors) include and/or is associated with corresponding heatsinks 950 secured thereto. Due to the mounting of the memory devices 820 to the bottom side 850 of the chassis-less circuit board substrate 702 (as well as the vertical spacing of the sleds 500 in the corresponding rack 340), the top side 750 of the chassis-less circuit board substrate 702 includes additional “free” area or space that facilitates the use of heatsinks 950 having a larger size relative to traditional heatsinks used in typical servers. Additionally, due to the improved thermal cooling characteristics of the chassis-less circuit board substrate 702, none of the processor heatsinks 950 include cooling fans attached thereto. That is, the heatsinks 950 may be fan-less heatsinks. In some examples, the heatsinks 950 mounted atop the processor circuitry 920 may overlap with the heatsink attached to the communication circuit 930 in the direction of the airflow path 708 due to their increased size, as illustratively suggested by FIG. 10.

Referring now to FIG. 11, in some examples, the sled 500 may be implemented as an accelerator sled 1100. The accelerator sled 1100 is configured, to perform specialized compute tasks, such as machine learning, encryption, hashing, or other computational-intensive task. In some examples, for example, a compute sled 900 may offload tasks to the accelerator sled 1100 during operation. The accelerator sled 1100 includes various components similar to components of the sled 500 and/or the compute sled 900, which have been identified in FIG. 11 using the same reference numbers. The description of such components provided above in regard to FIGS. 7, 8, and 9 apply to the corresponding components of the accelerator sled 1100 and is not repeated herein for clarity of the description of the accelerator sled 1100.

In the illustrative accelerator sled 1100, the physical resources 720 include accelerator circuits 1120. Although only two accelerator circuits 1120 are shown in FIG. 11, it should be appreciated that the accelerator sled 1100 may include additional accelerator circuits 1120 in other examples. For example, as shown in FIG. 12, the accelerator sled 1100 may include four accelerator circuits 1120. The accelerator circuits 1120 may be implemented as any type of processor, co-processor, compute circuit, or other device capable of performing compute or processing operations. For example, the accelerator circuits 1120 may be implemented as, for example, field programmable gate arrays (FPGA), application-specific integrated circuits (ASICs), security co-processors, graphics processing units (GPUs), neuromorphic processor units, quantum computers, machine learning circuits, or other specialized processors, controllers, devices, and/or circuits.

In some examples, the accelerator sled 1100 may also include an accelerator-to-accelerator interconnect 1142. Similar to the resource-to-resource interconnect 724 of the sled 700 discussed above, the accelerator-to-accelerator interconnect 1142 may be implemented as any type of communication interconnect capable of facilitating accelerator-to-accelerator communications. In the illustrative example, the accelerator-to-accelerator interconnect 1142 is implemented as a high-speed point-to-point interconnect (e.g., faster than the I/O subsystem 722). For example, the accelerator-to-accelerator interconnect 1142 may be implemented as a QuickPath Interconnect (QPI), an UltraPath Interconnect (UPI), or other high-speed point-to-point interconnect dedicated to processor-to-processor communications. In some examples, the accelerator circuits 1120 may be daisy-chained with a primary accelerator circuit 1120 connected to the NIC 932 and memory 820 through the I/O subsystem 722 and a secondary accelerator circuit 1120 connected to the NIC 932 and memory 820 through a primary accelerator circuit 1120.

Referring now to FIG. 12, an illustrative example of the accelerator sled 1100 is shown. As discussed above, the accelerator circuits 1120, the communication circuit 930, and the optical data connector 934 are mounted to the top side 750 of the chassis-less circuit board substrate 702. Again, the individual accelerator circuits 1120 and communication circuit 930 are mounted to the top side 750 of the chassis-less circuit board substrate 702 such that no two heat-producing, electrical components shadow each other as discussed above. The memory devices 820 of the accelerator sled 1100 are mounted to the bottom side 850 of the of the chassis-less circuit board substrate 702 as discussed above in regard to the sled 700. Although mounted to the bottom side 850, the memory devices 820 are communicatively coupled to the accelerator circuits 1120 located on the top side 750 via the I/O subsystem 722 (e.g., through vias). Further, the accelerator circuits 1120 may include and/or be associated with a heatsink 1150 that is larger than a traditional heatsink used in a server. As discussed above with reference to the heatsinks 950 of FIG. 9, the heatsinks 1150 may be larger than traditional heatsinks because of the “free” area provided by the memory resources 820 being located on the bottom side 850 of the chassis-less circuit board substrate 702 rather than on the top side 750.

Referring now to FIG. 13, in some examples, the sled 500 may be implemented as a storage sled 1300. The storage sled 1300 is configured, to store data in a data storage 1350 local to the storage sled 1300. For example, during operation, a compute sled 900 or an accelerator sled 1100 may store and retrieve data from the data storage 1350 of the storage sled 1300. The storage sled 1300 includes various components similar to components of the sled 500 and/or the compute sled 900, which have been identified in FIG. 13 using the same reference numbers. The description of such components provided above in regard to FIGS. 7, 8, and 9 apply to the corresponding components of the storage sled 1300 and is not repeated herein for clarity of the description of the storage sled 1300.

In the illustrative storage sled 1300, the physical resources 720 includes storage controllers 1320. Although only two storage controllers 1320 are shown in FIG. 13, it should be appreciated that the storage sled 1300 may include additional storage controllers 1320 in other examples. The storage controllers 1320 may be implemented as any type of processor, controller, or control circuit capable of controlling the storage and retrieval of data into the data storage 1350 based on requests received via the communication circuit 930. In the illustrative example, the storage controllers 1320 are implemented as relatively low-power processors or controllers. For example, in some examples, the storage controllers 1320 may be configured to operate at a power rating of about 75 watts.

In some examples, the storage sled 1300 may also include a controller-to-controller interconnect 1342. Similar to the resource-to-resource interconnect 724 of the sled 500 discussed above, the controller-to-controller interconnect 1342 may be implemented as any type of communication interconnect capable of facilitating controller-to-controller communications. In the illustrative example, the controller-to-controller interconnect 1342 is implemented as a high-speed point-to-point interconnect (e.g., faster than the I/O subsystem 722). For example, the controller-to-controller interconnect 1342 may be implemented as a QuickPath Interconnect (QPI), an UltraPath Interconnect (UPI), or other high-speed point-to-point interconnect dedicated to processor-to-processor communications.

Referring now to FIG. 14, an illustrative example of the storage sled 1300 is shown. In the illustrative example, the data storage 1350 is implemented as, or otherwise includes, a storage cage 1352 configured to house one or more solid state drives (SSDs) 1354. To do so, the storage cage 1352 includes a number of mounting slots 1356, which are configured to receive corresponding solid state drives 1354. The mounting slots 1356 include a number of drive guides 1358 that cooperate to define an access opening 1360 of the corresponding mounting slot 1356. The storage cage 1352 is secured to the chassis-less circuit board substrate 702 such that the access openings face away from (i.e., toward the front of) the chassis-less circuit board substrate 702. As such, solid state drives 1354 are accessible while the storage sled 1300 is mounted in a corresponding rack 304. For example, a solid state drive 1354 may be swapped out of a rack 340 (e.g., via a robot) while the storage sled 1300 remains mounted in the corresponding rack 340.

The storage cage 1352 illustratively includes sixteen mounting slots 1356 and is capable of mounting and storing sixteen solid state drives 1354. The storage cage 1352 may be configured to store additional or fewer solid state drives 1354 in other examples. Additionally, in the illustrative example, the solid state drives are mounted vertically in the storage cage 1352, but may be mounted in the storage cage 1352 in a different orientation in other examples. A given solid state drive 1354 may be implemented as any type of data storage device capable of storing long term data. To do so, the solid state drives 1354 may include volatile and non-volatile memory devices discussed above.

As shown in FIG. 14, the storage controllers 1320, the communication circuit 930, and the optical data connector 934 are illustratively mounted to the top side 750 of the chassis-less circuit board substrate 702. Again, as discussed above, any suitable attachment or mounting technology may be used to mount the electrical components of the storage sled 1300 to the chassis-less circuit board substrate 702 including, for example, sockets (e.g., a processor socket), holders, brackets, soldered connections, and/or other mounting or securing techniques.

As discussed above, the individual storage controllers 1320 and the communication circuit 930 are mounted to the top side 750 of the chassis-less circuit board substrate 702 such that no two heat-producing, electrical components shadow each other. For example, the storage controllers 1320 and the communication circuit 930 are mounted in corresponding locations on the top side 750 of the chassis-less circuit board substrate 702 such that no two of those electrical components are linearly in-line with each other along the direction of the airflow path 708.

The memory devices 820 (not shown in FIG. 14) of the storage sled 1300 are mounted to the bottom side 850 (not shown in FIG. 14) of the chassis-less circuit board substrate 702 as discussed above in regard to the sled 500. Although mounted to the bottom side 850, the memory devices 820 are communicatively coupled to the storage controllers 1320 located on the top side 750 via the I/O subsystem 722. Again, because the chassis-less circuit board substrate 702 is implemented as a double-sided circuit board, the memory devices 820 and the storage controllers 1320 may be communicatively coupled by one or more vias, connectors, or other mechanisms extending through the chassis-less circuit board substrate 702. The storage controllers 1320 include and/or are associated with a heatsink 1370 secured thereto. As discussed above, due to the improved thermal cooling characteristics of the chassis-less circuit board substrate 702 of the storage sled 1300, none of the heatsinks 1370 include cooling fans attached thereto. That is, the heatsinks 1370 may be fan-less heatsinks.

Referring now to FIG. 15, in some examples, the sled 500 may be implemented as a memory sled 1500. The storage sled 1500 is optimized, or otherwise configured, to provide other sleds 500 (e.g., compute sleds 900, accelerator sleds 1100, etc.) with access to a pool of memory (e.g., in two or more sets 1530, 1532 of memory devices 820) local to the memory sled 1300. For example, during operation, a compute sled 900 or an accelerator sled 1100 may remotely write to and/or read from one or more of the memory sets 1530, 1532 of the memory sled 1300 using a logical address space that maps to physical addresses in the memory sets 1530, 1532. The memory sled 1500 includes various components similar to components of the sled 500 and/or the compute sled 900, which have been identified in FIG. 15 using the same reference numbers. The description of such components provided above in regard to FIGS. 7, 8, and 9 apply to the corresponding components of the memory sled 1500 and is not repeated herein for clarity of the description of the memory sled 1500.

In the illustrative memory sled 1500, the physical resources 720 include memory controllers 1520. Although only two memory controllers 1520 are shown in FIG. 15, it should be appreciated that the memory sled 1500 may include additional memory controllers 1520 in other examples. The memory controllers 1520 may be implemented as any type of processor, controller, or control circuit capable of controlling the writing and reading of data into the memory sets 1530, 1532 based on requests received via the communication circuit 930. In the illustrative example, the memory controllers 1520 are connected to corresponding memory sets 1530, 1532 to write to and read from memory devices 820 (not shown) within the corresponding memory set 1530, 1532 and enforce any permissions (e.g., read, write, etc.) associated with sled 500 that has sent a request to the memory sled 1500 to perform a memory access operation (e.g., read or write).

In some examples, the memory sled 1500 may also include a controller-to-controller interconnect 1542. Similar to the resource-to-resource interconnect 724 of the sled 500 discussed above, the controller-to-controller interconnect 1542 may be implemented as any type of communication interconnect capable of facilitating controller-to-controller communications. In the illustrative example, the controller-to-controller interconnect 1542 is implemented as a high-speed point-to-point interconnect (e.g., faster than the I/O subsystem 722). For example, the controller-to-controller interconnect 1542 may be implemented as a QuickPath Interconnect (QPI), an UltraPath Interconnect (UPI), or other high-speed point-to-point interconnect dedicated to processor-to-processor communications. As such, in some examples, a memory controller 1520 may access, through the controller-to-controller interconnect 1542, memory that is within the memory set 1532 associated with another memory controller 1520. In some examples, a scalable memory controller is made of multiple smaller memory controllers, referred to herein as “chiplets”, on a memory sled (e.g., the memory sled 1500). The chiplets may be interconnected (e.g., using EMIB (Embedded Multi-Die Interconnect Bridge) technology). The combined chiplet memory controller may scale up to a relatively large number of memory controllers and I/O ports, (e.g., up to 16 memory channels). In some examples, the memory controllers 1520 may implement a memory interleave (e.g., one memory address is mapped to the memory set 1530, the next memory address is mapped to the memory set 1532, and the third address is mapped to the memory set 1530, etc.). The interleaving may be managed within the memory controllers 1520, or from CPU sockets (e.g., of the compute sled 900) across network links to the memory sets 1530, 1532, and may improve the latency associated with performing memory access operations as compared to accessing contiguous memory addresses from the same memory device.

Further, in some examples, the memory sled 1500 may be connected to one or more other sleds 500 (e.g., in the same rack 340 or an adjacent rack 340) through a waveguide, using the waveguide connector 1580. In the illustrative example, the waveguides are 74 millimeter waveguides that provide 16 Rx (i.e., receive) lanes and 16 Tx (i.e., transmit) lanes. Different ones of the lanes, in the illustrative example, are either 16 GHz or 32 GHz. In other examples, the frequencies may be different. Using a waveguide may provide high throughput access to the memory pool (e.g., the memory sets 1530, 1532) to another sled (e.g., a sled 500 in the same rack 340 or an adjacent rack 340 as the memory sled 1500) without adding to the load on the optical data connector 934.

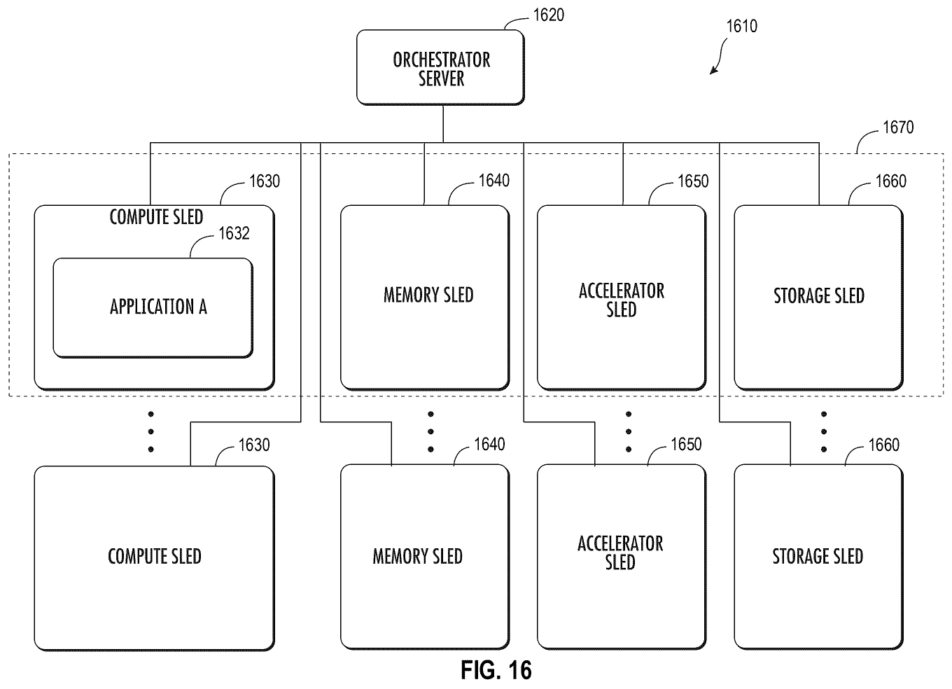

Referring now to FIG. 16, a system for executing one or more workloads (e.g., applications) may be implemented in accordance with the data center 200. In the illustrative example, the system 1610 includes an orchestrator server 1620, which may be implemented as a managed node including a compute device (e.g., processor circuitry 920 on a compute sled 900) executing management software (e.g., a cloud operating environment, such as OpenStack) that is communicatively coupled to multiple sleds 500 including a large number of compute sleds 1630 (e.g., similar to the compute sled 900), memory sleds 1640 (e.g., similar to the memory sled 1500), accelerator sleds 1650 (e.g., similar to the memory sled 1000), and storage sleds 1660 (e.g., similar to the storage sled 1300). One or more of the sleds 1630, 1640, 1650, 1660 may be grouped into a managed node 1670, such as by the orchestrator server 1620, to collectively perform a workload (e.g., an application 1632 executed in a virtual machine or in a container). The managed node 1670 may be implemented as an assembly of physical resources 720, such as processor circuitry 920, memory resources 820, accelerator circuits 1120, or data storage 1350, from the same or different sleds 500. Further, the managed node may be established, defined, or “spun up” by the orchestrator server 1620 at the time a workload is to be assigned to the managed node or at any other time, and may exist regardless of whether any workloads are presently assigned to the managed node. In the illustrative example, the orchestrator server 1620 may selectively allocate and/or deallocate physical resources 720 from the sleds 500 and/or add or remove one or more sleds 500 from the managed node 1670 as a function of quality of service (QoS) targets (e.g., a target throughput, a target latency, a target number of instructions per second, etc.) associated with a service level agreement for the workload (e.g., the application 1632). In doing so, the orchestrator server 1620 may receive telemetry data indicative of performance conditions (e.g., throughput, latency, instructions per second, etc.) in different ones of the sleds 500 of the managed node 1670 and compare the telemetry data to the quality of service targets to determine whether the quality of service targets are being satisfied. The orchestrator server 1620 may additionally determine whether one or more physical resources may be deallocated from the managed node 1670 while still satisfying the QoS targets, thereby freeing up those physical resources for use in another managed node (e.g., to execute a different workload). Alternatively, if the QoS targets are not presently satisfied, the orchestrator server 1620 may determine to dynamically allocate additional physical resources to assist in the execution of the workload (e.g., the application 1632) while the workload is executing. Similarly, the orchestrator server 1620 may determine to dynamically deallocate physical resources from a managed node if the orchestrator server 1620 determines that deallocating the physical resource would result in QoS targets still being met.

Additionally, in some examples, the orchestrator server 1620 may identify trends in the resource utilization of the workload (e.g., the application 1632), such as by identifying phases of execution (e.g., time periods in which different operations, having different resource utilizations characteristics, are performed) of the workload (e.g., the application 1632) and pre-emptively identifying available resources in the data center 200 and allocating them to the managed node 1670 (e.g., within a predefined time period of the associated phase beginning). In some examples, the orchestrator server 1620 may model performance based on various latencies and a distribution scheme to place workloads among compute sleds and other resources (e.g., accelerator sleds, memory sleds, storage sleds) in the data center 200. For example, the orchestrator server 1620 may utilize a model that accounts for the performance of resources on the sleds 500 (e.g., FPGA performance, memory access latency, etc.) and the performance (e.g., congestion, latency, bandwidth) of the path through the network to the resource (e.g., FPGA). As such, the orchestrator server 1620 may determine which resource(s) should be used with which workloads based on the total latency associated with different potential resource(s) available in the data center 200 (e.g., the latency associated with the performance of the resource itself in addition to the latency associated with the path through the network between the compute sled executing the workload and the sled 500 on which the resource is located).

In some examples, the orchestrator server 1620 may generate a map of heat generation in the data center 200 using telemetry data (e.g., temperatures, fan speeds, etc.) reported from the sleds 500 and allocate resources to managed nodes as a function of the map of heat generation and predicted heat generation associated with different workloads, to maintain a target temperature and heat distribution in the data center 200. Additionally or alternatively, in some examples, the orchestrator server 1620 may organize received telemetry data into a hierarchical model that is indicative of a relationship between the managed nodes (e.g., a spatial relationship such as the physical locations of the resources of the managed nodes within the data center 200 and/or a functional relationship, such as groupings of the managed nodes by the customers the managed nodes provide services for, the types of functions typically performed by the managed nodes, managed nodes that typically share or exchange workloads among each other, etc.). Based on differences in the physical locations and resources in the managed nodes, a given workload may exhibit different resource utilizations (e.g., cause a different internal temperature, use a different percentage of processor or memory capacity) across the resources of different managed nodes. The orchestrator server 1620 may determine the differences based on the telemetry data stored in the hierarchical model and factor the differences into a prediction of future resource utilization of a workload if the workload is reassigned from one managed node to another managed node, to accurately balance resource utilization in the data center 200. In some examples, the orchestrator server 1620 may identify patterns in resource utilization phases of the workloads and use the patterns to predict future resource utilization of the workloads.

To reduce the computational load on the orchestrator server 1620 and the data transfer load on the network, in some examples, the orchestrator server 1620 may send self-test information to the sleds 500 to enable a given sled 500 to locally (e.g., on the sled 500) determine whether telemetry data generated by the sled 500 satisfies one or more conditions (e.g., an available capacity that satisfies a predefined threshold, a temperature that satisfies a predefined threshold, etc.). The given sled 500 may then report back a simplified result (e.g., yes or no) to the orchestrator server 1620, which the orchestrator server 1620 may utilize in determining the allocation of resources to managed nodes.

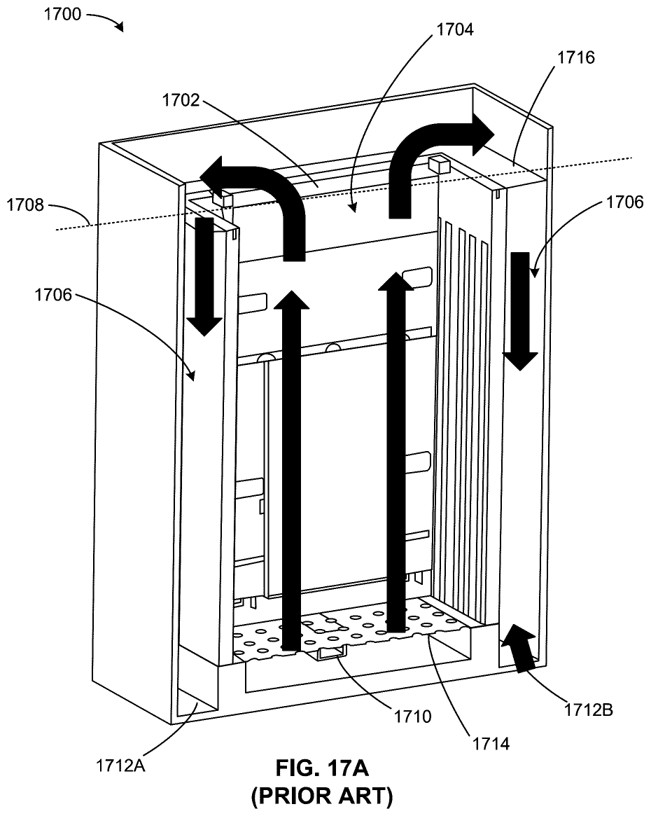

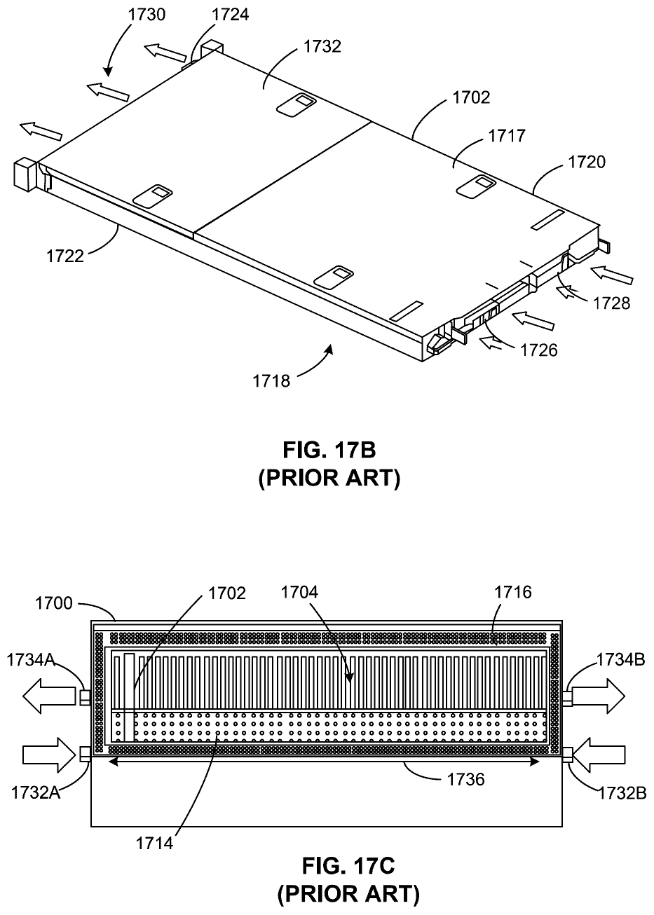

FIG. 17A is a perspective view of a cut-away of a prior tank 1700 including a prior chassis 1702. In FIG. 17A, the tank 1700 is a single-phase immersion cooling system including an inner tank 1704 and an outer tank 1706. In FIG. 17A, the inner tank 1704 and the outer tank 1706 are filled with a coolant to an example coolant level 1708. In FIG. 17A, the coolant enters the tank 1700 through a first tank inlet 1710, flows over the chassis 1702 through the inner tank 1704, enters the outer tank 1706, and exits the tank 1700 via a first tank outlet 1712A and a second tank outlet 1712B. In FIG. 17A, after flowing through the first tank inlet 1710, the coolant is rectified via a rectification plate 1714. In FIG. 17A, after flowing through the inner tank 1704, the coolant transits from the inner tank 1704 to the outer tank 1706 via an opening covered by a grate 1716.

The chassis 1702 is disposed in (e.g., supported by, couples within) the inner tank 1704 of the tank 1700. The chassis 1702 can include one or more electronic components (e.g., compute components). The tank 1700 can include a plurality of additional chassis disposed in parallel to the chassis 1702, which are similarly cooled via the circulation of the coolant. Operation of the chassis 1702 generates a comparatively high amount of heat, which is absorbed and dissipated via the circulation of the coolant through the tank 1700.

The tank 1700 is a prior single phase immersion cooling tank. The coolant enters the tank 1700 through the first tank inlet 1710 at an entry temperature and flows through the rectification plate 1714 to rectify the flow of the coolant (e.g., make the coolant more uniform, etc.). After flowing through the rectification plate 1714, the coolant flows through the inner tank 1704, thereby cooling the chassis 1702 via convection. After reaching the top of the chassis 1702 (where the top is relative to the orientation of the chassis 1702 shown in FIG. 17A) and/or the coolant level 1708, the coolant flows into the outer tank 1706, via the holed grate 1716, and exits the tank 1700 via the inner outlets 1712A, 1712B. During operation of the tank 1700 and the chassis 1702, the coolant enters and leaves the tank 1700 (e.g., via natural flow, via one or more pump(s), etc.) at a constant and equal rate, thereby maintaining the coolant level 1708 while continuously cycling hot coolant out of the tank 1700 for cooling.

FIG. 17B is a perspective view of the prior chassis 1702 of FIG. 17A. In FIG. 17B, the chassis 1702 has a front face 1717, a rear face 1718, a first side 1720, a second side 1722, a top 1724, and a bottom 1726. In FIG. 17B, the chassis 1702 has a chassis inlet 1728 on the bottom 1726 and a chassis outlet 1730 on the top 1724. In FIG. 17B, the compute components of the chassis 1702 are enclosed by a cover 1732.

The chassis 1702 includes the chassis inlet 1728 and the chassis outlet 1730 to allow coolant to enter and leave the interior of the chassis during operation of the tank 1700 and the chassis 1702. In FIG. 17B, the sides 1722, 1720 and the faces 1717, 1718 do not include holes (i.e., inlets, outlets, etc.) that would enable coolant to enter or leave the interior of the chassis 1702 in other manners than via the inlet 1728 and the outlet 1730. As such, during circulation of the coolant through the inner tank 1704, the coolant flows through the interior of the chassis in a flow circuit defined by the chassis inlet 1728 and the chassis outlet 1730.

FIG. 17C is a top view of the prior tank 1700 of FIG. 17A. In FIG. 17C, the coolant enters the tank 1700 through a second tank inlet 1732A and a third tank inlet 1732B and exits the tank via a first tank outlet 1734A and a second tank outlet 1734B. The prior tank 1700 and the chassis 1702 are described in a vertical orientation. It should be contemplated that other orientations can be used for immersion cooling systems (e.g., horizontal systems, etc.).

In FIGS. 17A and 17C, the tank 1700 is depicted including the single chassis 1702. However, in operation the tank 1700 can include a plurality of chassis disposed in parallel with the chassis 1702 along a length 1736 of the inner tank 1704. Each of the parallelly-mounted chassis is submerged under the coolant level 1708 and are cooled via the circulation of the coolant. Hot coolant is removed the tank 1700 via the outlets 1734A, 1734B, after which the coolant is cooled via a heat exchanger (e.g., via a shell and tube heat exchanger with facility tap water, etc.). After the coolant is cooled to an appropriate entry temperature, the coolant is returned to the tank 1700 via the tank inlets 1732A, 1732B to cool the chassis 1702. As such, the coolant can be used repeatedly, with some comparatively small coolant infusions required to account for incidental evaporation and/or leaks.

The prior system illustrated in FIGS. 17A-17C (e.g., the tank 1700 and the chassis 1702, etc.) may adequately cool the heat generated by the operation of the compute components associated with the chassis 1702. However, the dielectric coolant used in conjunction with the prior system of FIGS. 17A-17C is costly. Given that data centers (e.g., the data center 200 of FIG. 2, etc.) can use numerous tanks similar to the tank 1700, the costs associated with coolant alone for such data centers can be prohibitive.

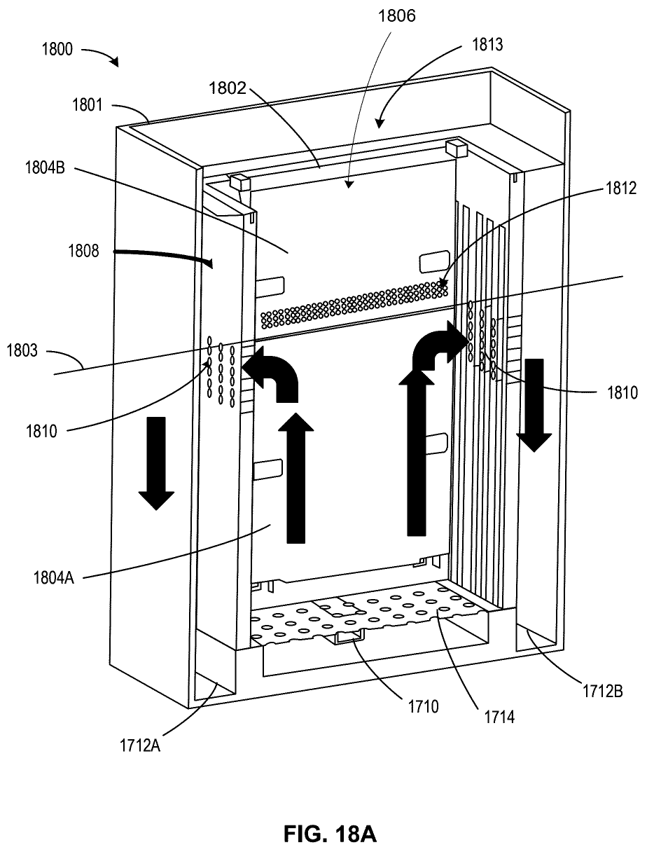

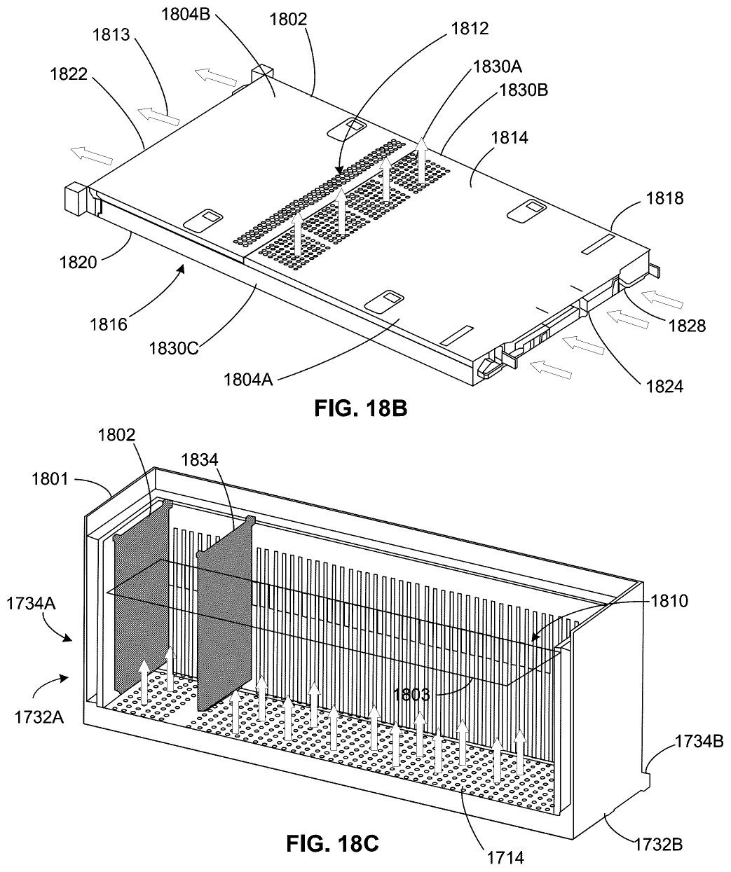

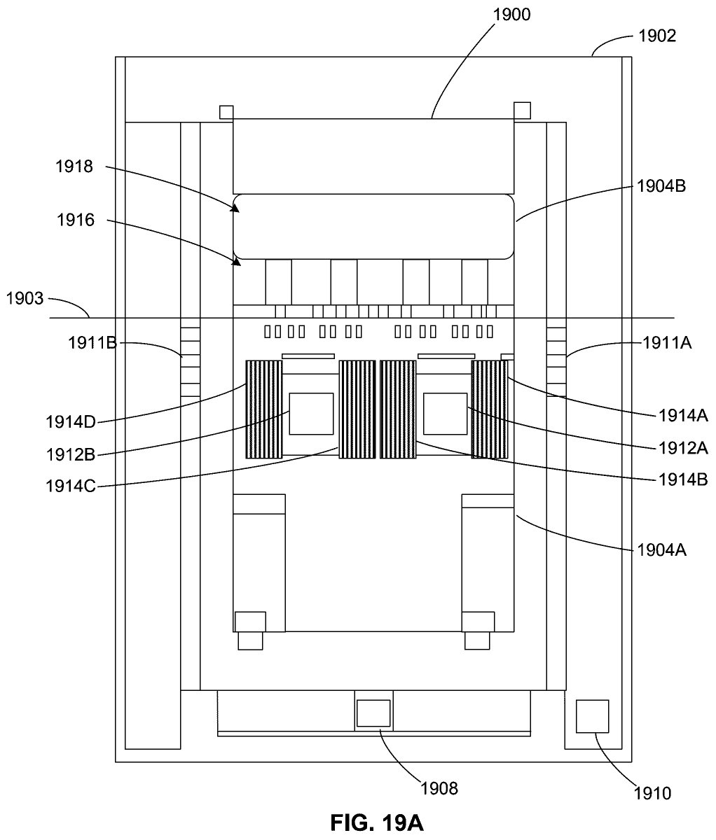

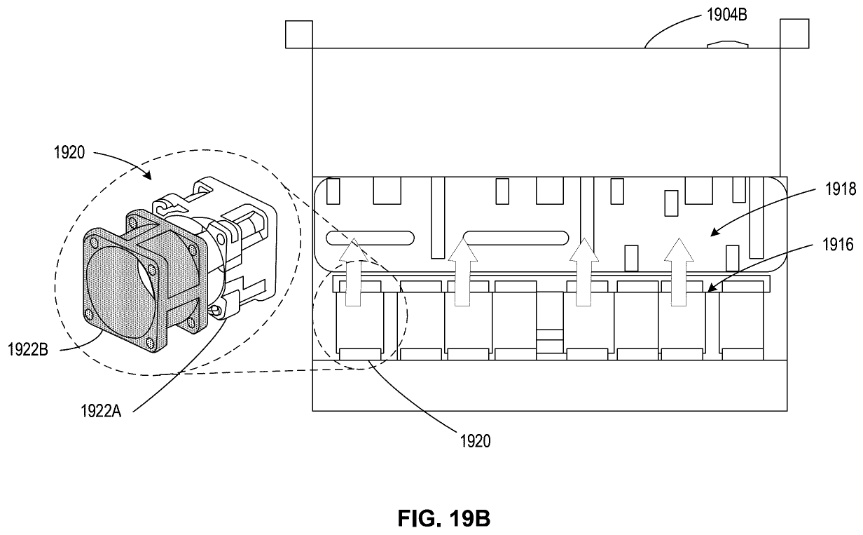

The following examples of FIGS. 18A-19B refer to immersion cooling systems that use a lesser volume of coolant without reducing cooling capability. For ease of description, when the same reference number is used in connection with FIGS. 18A-19B as was used in FIGS. 17A-17C, the reference number is intended be associated with the same meaning as used in FIGS. 17A-17C unless indicated otherwise.

FIG. 18A is a perspective view of a cut-away of an example cooling system 1800 in accordance with teachings of this disclosure. In the illustrated example of FIG. 18A, the cooling system 1800 includes an example tank 1801 and an example chassis 1802 disposed therein. The example tank 1801 is filled with coolant to an example coolant level 1803. The example chassis 1802 includes an example first portion 1804A and an example second chassis 1804B. In the illustrated example of FIG. 18A, the tank 1801 includes an example inner tank 1806 and an example outer tank 1808, both of which are filled with a coolant to the example coolant level 1803. In the illustrated example of FIG. 18A, the coolant enters that tank through the first tank inlet 1710, flows over the first chassis portion 1804A through the inner tank 1806, enters the outer tank 1808 via example holes 1810, and exits the tank the first tank outlet 1712A and the second tank outlet 1712B. In the illustrated example of FIG. 18A, after flowing through the first tank inlet 1710, the coolant is rectified (e.g., made more directional, etc.) via a rectification plate 1714. In the illustrated example of FIG. 18A, the second portion 1804B of the chassis 1802 includes an example chassis air inlet 1812 and an example chassis air outlet 1813, which cool the second portion 1804B via forced convection.

The chassis 1802 couples with or is otherwise supported by the inner tank 1806 of the tank 1801. The chassis 1802 can include one or more compute units (e.g., processors, etc.) and related compute components (e.g., power supplies, permanent memory, temporary memory, etc.). In the illustrated example of FIG. 18A, the first portion 1804A of the chassis 1802 is cooled via circulation of the coolant and the second portion 1804B of the chassis 1802 is cooled via the circulation of air. In some examples, the components of the chassis 1802 with comparatively greater average TDP (e.g., CPUs, GPUS, DIMM, etc.) are disposed within the first portion 1804A and components of the chassis with comparatively lower average TDP (e.g., solid-state drives, hard disk drives, etc.) are disposed within the second portion 1802B. As such, in the illustrated example of FIG. 18A, components with higher thermal design power are cooled via a first method (e.g., immersion cooling, liquid convection, etc.) and components with lower thermal components are cooled via a second method (e.g., air convection, etc.), where the first method can provide for more efficient cooling of high TDP devices than the second method. In other examples, the components of the chassis 1802 can be disposed in the chassis 1802 in other arrangements. Additionally or alternatively, the compute units of the chassis 1802 can have any suitable orientation/layout/form factor (e.g., spreadcore, shadowed, etc.). Additionally or alternatively, the chassis 1802 can include any suitable number of compute units. The tank 1801 can include a plurality of additional chassis disposed in parallel to the chassis 1802, which are similarly cooled via the circulation of the coolant and/or air. As used herein, the term “spread core” refers to a chassis form factor in which the compute nodes carried by the chassis are disposed in parallel, relative to the fluid flow. As used herein, the term “shadowed” refers to a chassis form factor in which the compute nodes carried by the chassis are disposed in sequence, relative to the fluid flow It should be appreciated that an amount of heat generated by the example compute units discussed herein can vary. In some instances, the heat can be generated by the compute device(s) at a constant or substantially rate based on, for example workloads performed by the compute device(s), the type of compute device, etc. In some instances, the amount of heat generated by the compute device can vary over time (e.g., increase or decrease based on execution of different tasks, throttling, different types of integrated circuitry, etc.).

The tank 1801 is a cooling tank including liquid cooling functionality and airing cooling functionality. In the illustrated example of FIG. 18A, the coolant enters the tank 1801 through the first tank inlet 1710 at an entry temperature and flows through the rectification plate 1714 to rectify the flow of the coolant (e.g., make the coolant more uniform, etc.). In other examples, the rectification plate 1714 is absent. In the illustrated example of FIG. 18A, after flowing through the rectification plate 1714, the coolant flows through the inner tank 1704, thereby cooling the first portion 1804A of the chassis 1802 via convection. After reaching the top of the first portion 1804A of the chassis 1802 (where the top is relative to the orientation of the chassis 1802 in FIG. 18A) and/or the coolant level 1803, the coolant flows into the outer tank 1808 via the holes 1810 and exits the tank 1801 via the inner outlets 1712A, 1712B. During operation of the tank 1801, the coolant enters and leaves the tank 1801 (e.g., via natural flow, via one or more pump(s), etc.) at a constant and equal rate, thereby maintaining the coolant level 1803 while continuously cycling hot coolant out of the tank 1801 for cooling the compute components carried by the chassis 1802. Simultaneously or substantially simultaneously to the circulation of the coolant over the first portion 1804A, the second portion 1804B is cooled via air cooling (e.g., similar to the systems illustrated above in conjunction with FIGS. 4-6, etc.). In the illustrated example, the second portion 1804B of the chassis 1802 includes the chassis air inlet 1812 disposed above and proximate to (e.g., adjacent or substantially adjacent to) the coolant level 1803 and a chassis air outlet 1813 at the top of the chassis 1802 when the chassis 1802 is oriented as shown in FIG. 18A.

FIG. 18B is a perspective view of the chassis 1802 of FIG. 18A. In the example of FIG. 18B, the chassis 1802 has an example front face 1814, an example rear face 1816, an example first side 1818, an example second side 1820, an example top 1822, and an example bottom 1824 (where, for illustrative purposes, the front face 1814, rear face 1816, top 1822, and bottom 1824 are relative to the orientation of the chassis 1802 shown in FIG. 18B). In the example of FIG. 18B, the chassis 1802 has an example chassis coolant inlet 1828 defined in the bottom 1824 and an example first chassis coolant outlet 1830A, an example second chassis coolant outlet 1830B, and an example third chassis coolant outlet 1830C, which are defined in the front face 1814, the first side 1818, and the second side 1820, respectively. In illustrated example of FIG. 18B, the compute components of the chassis 1802 are enclosed by a cover defined by the faces 1814, 1816 for protection of the compute components.

The chassis 1802 includes the chassis coolant inlet 1828 and the chassis coolant outlet 1830A, 1830B, 1830C to allow coolant to enter and leave the interior of the first portion 1804A during operation of the tank 1801. In the illustrated example of FIG. 18B, the chassis coolant inlet 1828 is on the bottom 1824. In other examples, the chassis coolant inlet 1828 can be defined at any other suitable location (e.g., on the front face 1814, on one or more the sides 1818, 1820, etc.). In some examples, some of the chassis coolant outlets 1830A, 1830B, 1830C can be absent. Additionally or alternatively, the chassis coolant outlets 1830A, 1830B, 1830C can be disposed at any other suitable location. Additionally or alternatively, the chassis 1802 can include additional coolant inlets and/or coolants outlets disposed on the sides 1818, 1820, the front face 1814, the rear face 1816, and/or the top 1822. During circulation of the coolant through the inner tank 1806, the coolant flows through the interior of the chassis 1802 in a flow circuit defined by the chassis coolant inlet 1828 and the chassis coolant outlets 1830A, 1830B, 1830C.

The chassis 1802 includes the chassis air inlet 1812 and the chassis air outlet 1813 to allow air to enter and leave the interior of the second portion 1804B during operation of the tank 1801 and the chassis 1802. In the illustrated example of FIG. 18B, the chassis air inlet 1812 is defined in the front face 1814 proximate to the chassis coolant outlet 1830A of the first portion 1804A. In other examples, the air inlet 1812 can at any other suitable location (e.g., on the front face 1814 and distal to the chassis coolant outlet 1830A, on one or more the sides 1818, 1820, etc.). In the illustrated example of FIG. 18B, the chassis air outlet 1813 is define in the top 1822 of the chassis 1802. In other examples, the air inlet 1812 can be disposed at any other suitable location (e.g., on the front face 1814, on one or more the sides 1818, 1820, etc.). Additionally or alternatively, the chassis 1802 can include additional air inlets and/or outlets disposed on the sides 1818, 1820, the front face 1814, the rear face 1816, and/or the top 1822.

In some examples, the interior of the first portion 1804A and the interior of the second portion 1804B can include a wall (e.g., an internal wall, etc.) to physically separate the components disposed in the first portion 1804A and the components disposed in the second portion 1804B of the chassis 1802. In other examples, the interior of the first portion 1804A and the interior of the second portion 1804B can be open and/or in fluid communication. In some such examples, the internal wall disposed between the first portion 1804A and the second portion 1804B can include one or more holes.

FIG. 18C is a perspective view of the tank 1801 of FIG. 18A. In the illustrated example of FIG. 18C, the coolant enters the tank 1801 through the second tank inlet 1732A and the third tank inlet 1732B and exits the tank 1801 via the first tank outlet 1734A of FIG. 17C and the second tank outlet 1734B of FIG. 17C. In the illustrated example of FIGS. 18A-18C, the tank 1801 and the chassis 1802 are shown in a vertical orientation. In other examples, the tank 1801 and the chassis 1802 can have any other suitable orientation (e.g., horizontal, etc.).

In the illustrated example of FIGS. 18A and 18C, the tank 1801 is depicted including the two chassis 1802, 1834. However, in some examples, the tank 1801 can include a plurality of chassis disposed in parallel with the chassis 1802, 1834. In such examples, each of the parallelly-mounted chassis can include (a) corresponding portions (e.g., equivalent to the first portion 1804A of the chassis 1802, etc.) submerged under the coolant level 1803 that are cooled via the circulation of the coolant and (b) corresponding portions (e.g., equivalent to the second portion 1804B of the chassis 1802, etc.) that are above the coolant level 1803 that are cooled via air cooling. Hot coolant is removed the tank 1801 via the outlets 1734A, 1734B, after which the coolant is cooled via a heat exchanger (e.g., via a shell and tube heat exchanger with facility tap water, etc.). After the coolant is cooled to a particular (e.g., predefined, appropriate) entry temperature, the coolant is returned to the tank 1700 via the tank inlets 1732A, 1732B to cool the compute components carried by the first portion 1804A. As such, the coolant can be used repeatedly, with some comparatively small coolant infusions to account for incidental evaporation and/or leaks. In some examples, hot air produced by the second portion 1804B is vented into ambient conditions of the tank 1801. In some such examples, the hot air is cooled via the air conditioning associated with the data center. In other examples, the hot air produced by the tank 1801 can be cooled by any other suitable means.

FIG. 19A is a front view of another example chassis 1900 disposed in an example tank 1902 in accordance with teachings of this disclosure. The example tank 1902 is filled with coolant to example coolant level 1903. The example chassis 1900 includes an example first chassis portion 1904A and an example second portion 1904B. In the illustrated example of FIG. 19A, the tank 1902 includes an example tank coolant inlet 1908, an example tank coolant outlet 1910, example first holes 1911A and example second holes 1911B. In the illustrated example, a cover (not illustrated) of the chassis 1900 has been removed and the internal components of the chassis 1900 are visible. The example first portion includes an example first compute unit 1912A, an example second compute unit 1912B, an example first DIMM 1914A, an example second DIMM 1914B, an example third DIMM 1914C, and example fourth DIMM 1914D. The example second portion 1904B includes an example fan array 1916 and an example disk array 1918.

The tank 1902 is a cooling tank (e.g., a single-phase cooling tank) that includes liquid cooling functionality and airing cooling functionality. In the illustrated example of FIG. 19A, the coolant enters the tank 1902 through the tank coolant inlet 1908 at an entry temperature and flows an inner portion of the tank 1902 thereby cooling the first portion 1904A of the chassis 1900 via convection. After reaching a boundary (e.g., the top) of the first portion 1904A of the chassis 1900 and/or the coolant level 1903, the coolant flows into an outer portion of the tank 1902, via the holes 1911A, 1911B, and exits the tank 1801 via the tank coolant outlets 1910. During operation of the tank 1902 and the chassis 1900, the coolant enters and leaves the tank 1902 (e.g., via natural flow, via one or more pump(s), etc.) at a constant and equal rate, thereby maintaining the coolant level 1903 while continuously cycling hot coolant out of the tank 1902 for cooling.

The chassis 1900 is segregated into the first portion 1904A, which is submerged under the coolant level 1903 and cooled thereby, and the second portion 1904B, which is cooled via the circulation of air caused by the fan array 1916. The fan array 1916 and the second portion 1904B are disclosed below in conjunction with FIG. 19B. In the illustrated example of FIG. 19A, the first portion 1904A includes compute components that have a comparatively high TDP including the compute units 1912A, 1912B and the DIMMs 1914A, 1914B, 1914C, 1914D and the second portion 1904B includes components with comparatively low TDP including the memory array 1918. Additionally or alternatively, the first portion 1904A can include other high power and/or thermally challenging components including additional compute units, additionally memory, GPUs, VRs, add-in cards, power supply units, etc. Additionally or alternatively, the second portion 1904B can include other low power and/or less thermally challenging components including additional SSDs, additional HDDs, optical drives, etc. In some examples, the memory array 1918 can include a plurality of SSDs, HDD's and/or any other suitable memory components, optical drives, etc. In the illustrated example of FIG. 19A, the chassis 1900 has an example spreadcore configuration (e.g., the compute units 1912A, 1912B are disposed in parallel). In other examples, the chassis 1900 can be in a shadowed configuration (e.g., the compute units 1912A, 1912B disposed in sequence). Additionally or alternatively, the chassis 1900 can have any other suitable configuration and/or any other suitable number of compute units.

FIG. 19B is a detail view of the second portion 1904B of the chassis 1900 of FIG. 19A. In the illustrated example of FIG. 19B, the fan array 1916 includes an example fan assembly 1920. In the illustrated example of FIG. 19B, the fan assembly 1920 includes a first fan 1922A and a second fan 1922B. The first fan 1922A can be, for instance, a low speed fan. In the illustrated example of FIG. 19B, the second fan 1922B does not include a rotor and, thus, may be referred to as a dummy fan. In other examples, the dummy fan 1922B can include an unpowered rotor. In the illustrated example of FIG. 19B, the chassis 1900 is a retrofitted designed from a fully air-cooled system. The fan array 1916 is disposed on the chassis 1900 to direct airflow onto the compute components (e.g., the disk array 1918). In the illustrated example of FIG. 19B, the fan assembly 1920 includes a dual rotor configuration due to prior configuration slots in the chassis 1900. In some examples, the low speed fan 1922A can be a single rotor fan. However, in this example, due to the reduced cooling demand of the second portion 1904B (e.g., cooling the low TDP portions of the second portion 1904B, rather than the whole chassis 1900, etc.), the fan assembly 1920 includes the low-speed fan 1922A and the dummy fan 1922B. In other examples, the fan assembly 1920 can include any other suitable components. The fan array 1916 can include any suitable number of fan assemblies similar to the fan assembly 1920.

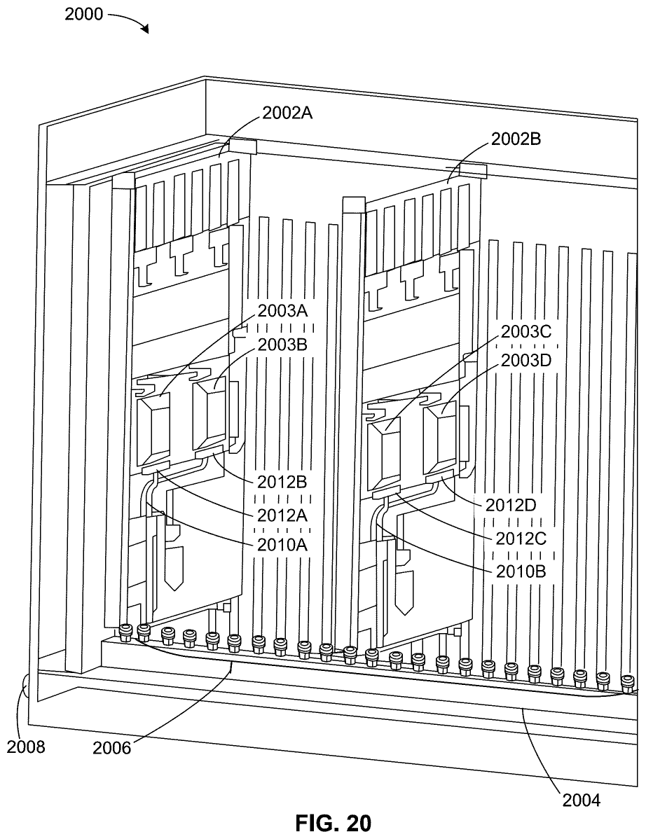

FIG. 20 is a perspective view of an example tank 2000 in accordance with teachings of this disclosure. In the illustrated example of FIG. 20, the tank 2000 includes an example first chassis 2002A, which includes an example first compute unit 2003A and an example second compute unit 2003B, and example second chassis 2002B, which includes an example third compute unit 2003C and an example fourth compute unit 2003D. The example tank 2000 includes an example manifold 2004, an example array of connector array 2006, and an example manifold inlet 2008. In the illustrated example of FIG. 20, the first chassis 2002A includes an example first internal flow path 2010A, an example first nozzle 2012A, and example second nozzle 2012B. In the illustrated example of FIG. 20, the second chassis 2002B includes an example second internal flow path 2010B, an example third nozzle 2012C, and example fourth nozzle 2012D. The chassis 2002A, 2002B can include additional or fewer compute units and/or compute components.

The example tank 2000 of FIG. 20 is a single phase immersion cooling tank. For example, coolant can enter the tank 2000 via a tank inlet (not illustrated in FIG. 20) and the manifold inlet 2008 and then flow through an inner portion of the tank 2000 and the internal flow paths 2010A, 2010B, respectively. After flowing over the chassis 2002A, 2002B of the tank 2000 and absorbing heat therefrom (e.g., heat generated by the compute components carried by the chassis 2002A, 2002B), the coolant can enter an outer portion of the tank 2000, and flow into an outlet of the tank 2000 to be cooled and subsequently recirculated through the tank 2000. During operation of the tank 2000 and the chassis disposed therein (e.g., the chassis 2002A, 2002B, etc.), the coolant enters and leaves the tank 2000 (e.g., via natural flow, via one or more pump(s), etc.) at a constant and equal or substantially constant and equal rate, thereby maintaining the coolant at constant level in the tank 2000 and cooling the chassis 2002A, 2002B.

The chassis 2002A, 2002B are supported by (e.g., coupled within) the tank 2000 via ones of the connector array 2006. The chassis 2002A, 2002B include one or more processing units (e.g., the compute units 2003A, 2003B, 2003C, 2003D, etc.) and related computing components (e.g., power supplies, permeant memory, temporary memory, etc.). In the illustrated example of FIG. 20, the chassis 2002A, 2002B have a spreadcore form factor (e.g., the first compute unit 2003A and the second compute unit 2003B are disposed in parallel on the first chassis 2002A, the third compute unit 2003C and the fourth compute unit 2003D are disposed in parallel on the second chassis 2002B, etc.). In other examples, the compute units 2003A, 2003B, 2003C, 2003D of the chassis 2002A, 2002B can have any suitable orientation(s)/layout(s)/form factor(s) (e.g., shadowed, etc.). Operation of the compute component(s) of the chassis 2002A, 2002B generates heat, which is absorbed and dissipated via the circulation of the coolant through the tank 2000. The tank 2000 can include a plurality of additional chassis disposed in parallel to the chassis 2002A, 2002B, which are similarly cooled via the circulation of the coolant through the tank 2000 and/or additional internal flow paths (e.g., similar to the internal flow paths 2010A, 2010B, etc.).

The internal flow paths 2010A, 2010B are flow paths defined in the chassis 2002A, 2002B, respectively. In the illustrated example of FIG. 20, the first internal flow path 2010A of the first chassis 2002A extends between (a) one of the connector array 2006 and the first nozzle 2012A and (b) the second nozzle 2012B. In some examples, some or both of the internal flow paths 2010A, 2010B can be insulated and/or composed of a material with low thermal conductivity to reduce heating of the coolant within of the internal flow paths 2010A, 2010B by the comparatively warmer coolant of the main flow path of the tank 2000.

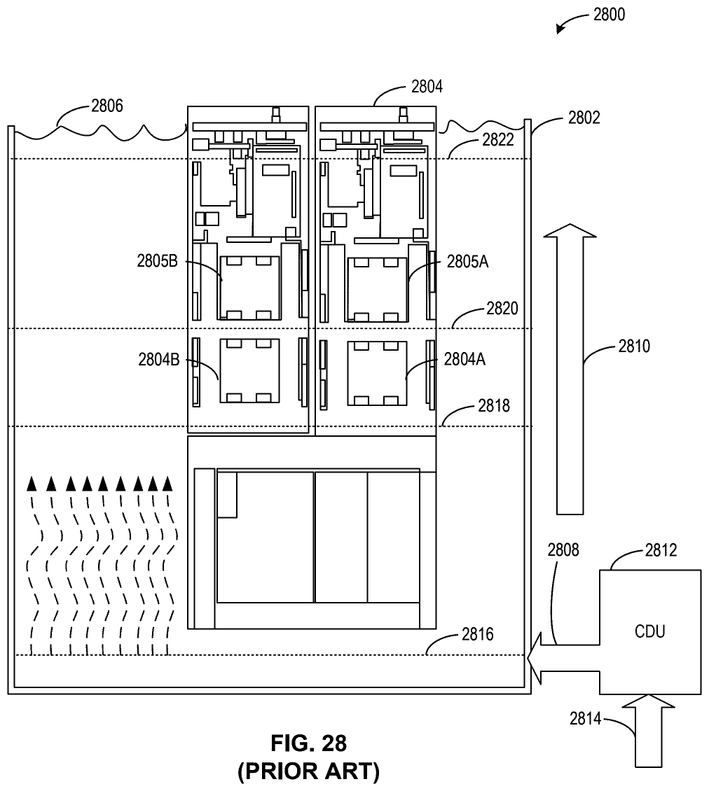

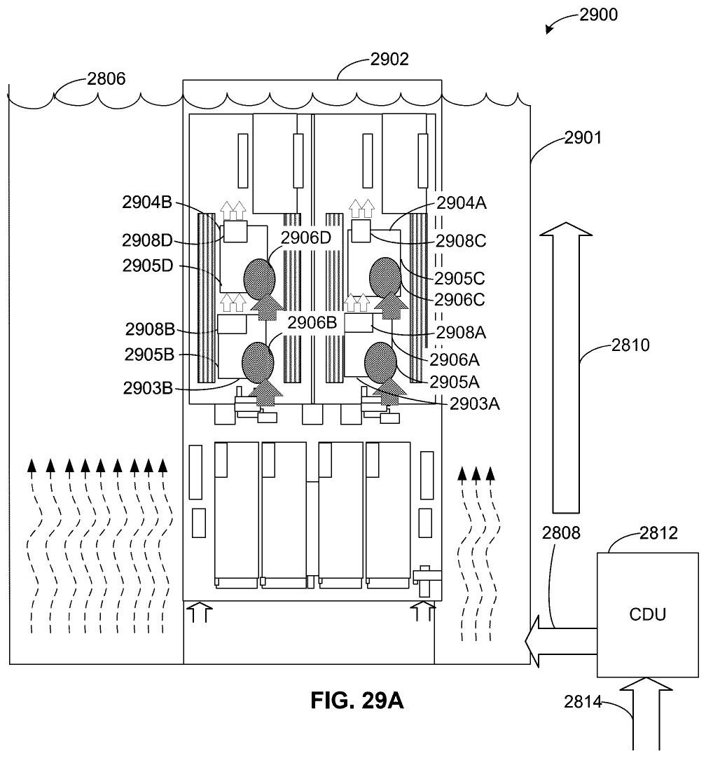

In the illustrated example of FIG. 20, the second internal flow path 2010B of the second chassis 2002B extends between one of the connector array 2006 and the third nozzle 2012C and the fourth nozzle 2012D. In the illustrated example of FIG. 20, the nozzles 2012A, 2012B, 2012C, 2012D facilitate local convection cooling (e.g., spot forced or driven cooling at a particular location) of the compute units 2003A, 2003B, 2003C, 2003D. The nozzles 2012A, 2012B, 2012C, 2012D can have any suitable size and/or geometry to provide for distribution of comparatively colder and faster flowing coolant from the internal flow paths 2010A, 2010B over the compute units 2003A, 2003B, 2003C, 2003D. In other examples, some or all of the nozzles 2012A, 2012B, 2012C, 2012D can be absent. In such examples, the internal flow paths 2010A, 2010B can extend to an inlet associated with a cold plate coupled to one or more compute units 2003A, 2003B, 2003C, 2003D. Example compute units and tanks including compute units with internal flow paths are disclosed below in conjunction with FIGS. 28-36. In some examples, the internal flow paths 2010A, 2010B can have an outlet with a same diameter and/or smaller diameter as the tube(s) of the internal flow paths 2010A, 2010B.

In some examples, during operation, the compute units 2003A, 2003B, 2003C, 2003D have comparatively higher TDP requirement(s) when compared to other components of the chassis 2002A, 2002B. In some examples, if the compute units 2003A, 2003B, 2003C, 2003D are adequately cooled, the compute units 2003A, 2003B, 2003C, 2003D could be damaged and/or their performance could be throttled to prevent overheating. In the illustrated example, the compute units 2003A, 2003B, 2003C, 2003D are cooled via the circulation of coolant via the main flow path of the tank 2000. Additionally, the compute units 2003A, 2003B, 2003C, 2003D are additionally cooled via circulation of coolant via the internal flow paths 2010A, 2010B. In the illustrated example of FIG. 18, coolant for the internal flow paths 2010A, 2010B enters the tank 2000 via the manifold 2004 in parallel to the coolant entering the main flow path of the tank 2000. After entering the manifold 2004, the coolant flows through the ones of the connector array 2006 into the internal flow paths 2010A, 2010B of the chassis 2002A, 2002B, respectively. As coolant from the internal flow paths 2010A, 2010B exits via the nozzles 2012A, 2012B, 2012C, 2012D and reenters the main flow path of the tank 2000, the local flow rate of the coolant over the compute units 2003A, 2003B, 2003C, 2003D increases and the local temperature of the coolant over the compute units 2003A, 2003B, 2003C, 2003D decreases, thereby increasing the efficiency of the convection cooling of the compute units 2003A, 2003B, 2003C, 2003D.

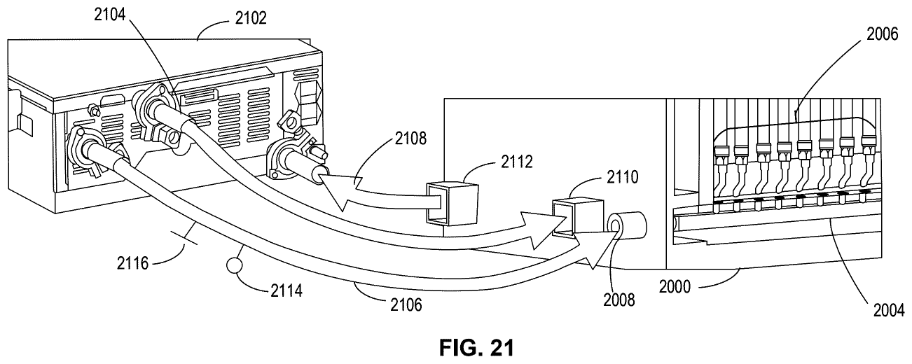

FIG. 21 illustrates the flow of coolant between the tank 2000 of FIG. 20 and an example coolant distribution unit (CDU) 2102. In the illustrated example of FIG. 21, the coolant flows into the tank 2000 via the example manifold inlet 2008 of FIG. 20, an example main inlet 2110, and an example outlet line 2108. In the illustrated example of FIG. 21, the tank 2000 includes the manifold inlet 2008, an example main inlet 2110, and an example outlet 2112. In the illustrated example of FIG. 21, the second inlet line 2106 includes an example flow meter 2114 and an example valve 2116.

The CDU 2102 cools, pumps, and distributes the coolant into one or more immersion cooling tanks (e.g., the tank 2000, etc.). The example CDU 2102 can include one or more heat exchanger(s) that cools the coolant via the flow of another fluid (e.g., a shell and tube heat exchanger with facility tap water, a tube-in-tube heat exchanger with facility tap water, etc.). In some such examples, the CDU 2102 can include a connection to a municipal water supply to access and discharge water used to regulate the temperature of the coolant. In some examples, the CDU 2102 can include one or more radiators to cool the coolant and/or the heat exchange fluid via air convection. Additionally or alternatively, the CDU 2102 can include one or more pumps to drive the coolant through the lines 2104, 2106, 2108 and/or the tank 2000.

The lines 2104, 2106, 2108 are tubes that transfer coolant between the tank 2000 and the CDU 2102. In some examples, some or all of the lines 2104, 2106, 2108 can be flexible tubes (e.g., rubber tubes, plastic tubes, etc.). Additionally or alternatively, some or all of the lines 2104, 2106, 2108 can be rigid or substantially rigid tubes (e.g., metal piping, plastic tubes, etc.). In the illustrated example of FIG. 21, the lines 2104, 2106, 2108 have a generally circular cross-section. In other examples, the lines 2104, 2106, 2108 can have any suitable shape. In some examples, some or all of the lines 2104, 2106, 2108 can be insulated to reduce heat transfer between the coolant in the corresponding ones of the lines 2104, 2106, 2108 and the ambient environment.

In the illustrated example of FIG. 21, the CDU 2102 provides coolant to the tank 2000 via the inlets 2008, 2110. In the illustrated example of FIG. 21, the first line 2104 provides coolant to the main inlet 2110, which then flows through the main flow path of the tank 2000. The example second inlet line 2106 provides coolant to the manifold 2004, which then flows through the internal flow paths of the chassis disposed in the tank 2000 (e.g., the internal flow paths 2010A, 2010B of FIG. 20, etc.). In other examples, the CDU 2102 provides coolant to the tank 2000 via a single line. In some such examples, the coolant can be split between the manifold 2004 and the main flow path of the tank 2000 via an internal structure of the tank 2000. In some examples, after the coolant exits the internal flow paths of the chassis of the tanks 2000 and reenters the main flow path of the tank 2000, the coolant exiting the tank 2000 is discharged via the third line 2108. In other examples, the tank 2000 and/or the CDU 2102 can include additional discharge lines.

The example valve 2116 regulates the flow rate and pressure through the second inlet line 2106. The example flow meter 2114 measures the flow rate of the coolant via the second inlet line 2106. In some examples, operation of the valve 2116 and the output of the flow meter can be used to control the volume of the coolant flowing through the second inlet line 2106, the manifold 2004, and the internal flow paths of the chassis of the tank 2000 (e.g., the internal flow paths 2010A, 2010B, etc.). In some examples, the valve 2116 can be used to adjust the flow rate of the coolant based on the cooling needs of the compute units of the tank 2000 (which can vary over time based on, for example, workloads of the compute units).

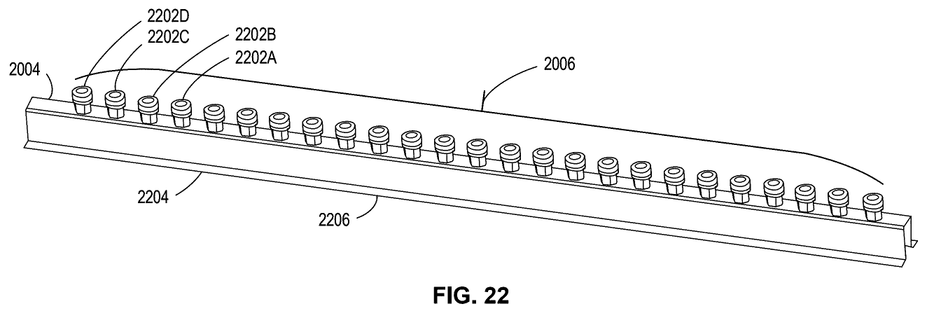

FIG. 22 is a perspective view of the example manifold 2004 of FIGS. 20 and 21. In the illustrated example of FIG. 22, the manifold includes the connector array 2006 of FIG. 20, which includes an example first connector 2202A, an example second connector 2202B, an example third connector 2202C, and an example fourth connector 2202D, and an example shell 2204. In the illustrated example, the manifold 2004 includes an example lip 2206.

The connectors 2202A, 2202B, 2202C, 2202D and the other connectors of the connector array 2006 can receive one or more corresponding features of a chassis (e.g., a server chassis such as the chassis 2002A, 2002B of FIG. 20, etc.) and removably couple chassis (e.g., the chassis 2002A, 2002B, etc.) to the tank 2000. The connectors 2202A, 2202B, 2202C, 2202D and the other connectors of the connector array 2006 include internal flow paths to facilitate coolant flows from the body of the manifold 2004 into the chassis 2002A, 2002B. In the illustrated example of FIG. 22, the connectors 2202A, 2202B, 2202C, 2202D and the other connectors of the connector array 2006 are quick disconnect (QD) connectors. In some such examples, the connectors 2202A, 2202B, 2202C, 2202D and the other connectors of the connector array 2006 connect upon contact with a guide feature of the chassis 2002A, 2002B to facilitate support the chassis 2002A, 2002B in the tank of FIG. 20. In some such examples, the connectors 2202A, 2202B, 2202C, 2202D and the other connectors of the connector array 2006 can include a togglable self-lock mechanism, which can be disabled to enable the removal of the corresponding chassis without manual operation of individual ones of the connectors 2202A, 2202B, 2202C, 2202D by a user.

In the illustrated example of FIG. 22, the manifold 2004 and/or the shell 2204 are generally U-shaped. In other examples, the manifold 2004 and/or the shell 2204 can have any other suitable shape. In the illustrated example of FIG. 22, the shell 2204 has an open (e.g., hollow) cross section. In other examples, the shell 2204 can have a solid cross-section. In some such examples, the shell 2204 can include internal channels to channel or direct the coolant to the connectors of the connector array 2006. In the illustrated example of FIG. 22, the ends of the shell 2204 include the example lip 2206 extending therefrom. In the illustrated example of FIG. 22, the lip 2206 includes a plurality of holes. In some such examples, the manifold 2004 can be coupled within a tank 2000 via fasteners coupled via the plurality of holes. In other examples, the manifold 2004 can be coupled within a tank 2000 via any other suitable method (e.g., via one or more welds, via one or more shrink fits, via one or more press fits, etc.). In some examples, the lip 2206 can be absent. In the illustrated example of FIG. 22, the shell 2204 and the lip 2206 are an integral part (e.g., formed from a bent/formed metal sheet, machined from a blank, etc.). In other examples, the shell 2204 and the lip 2206 can be manufactured as separate components and joined (e.g., via a weld, via one or more fasteners, etc.).

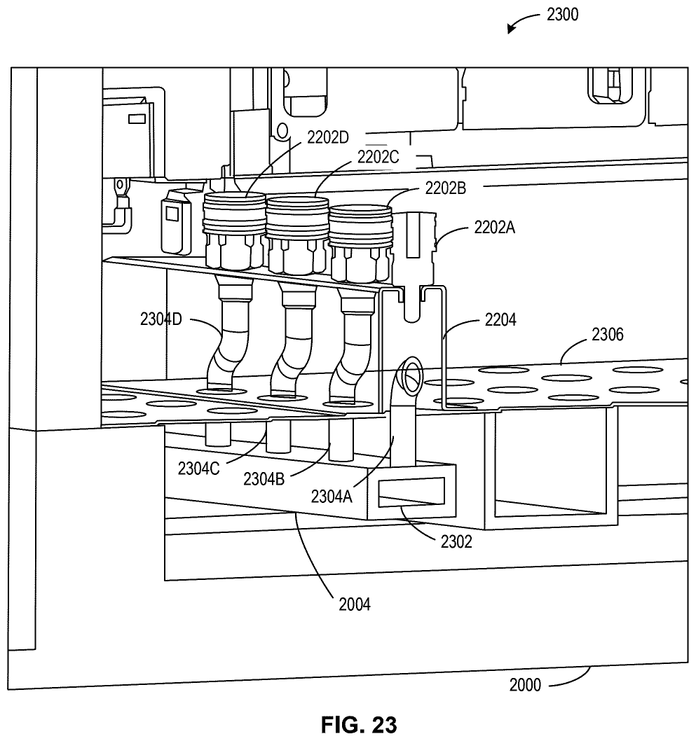

FIG. 23 is a cross-sectional view of an example portion 2300 of the tank 2000 of FIG. 20 and the manifold 2004 of FIG. 20. In the illustrated example of FIG. 23, the manifold 2004 (e.g., the manifold assembly, etc.) receives coolant from an example manifold inlet flow path 2302, the example connectors 2202A, 2202B, 2202C, 2202D of FIG. 22, an example first internal tube 2304A, an example second internal tube 2304B, an example third internal tube 2304C, an example fourth internal tube 2304D, and the example shell 2204 of FIG. 22. In the illustrated example of FIG. 23, the tank 2000 includes an example rectification plate 2306.

The rectification plate 2306 rectifies the flow of the coolant (e.g., makes the coolant more uniform than if the rectification plate was not present) moving through the main flow path of the rectification plate 2306. In other examples, the rectification plate 2306 can be absent. The internal tubes 2304A, 2304B, 2304C, 2304D extend from the internal flow path 2302 to direct flow into the internal flow paths of the chassis of the tank 2000 (e.g., the internal flow paths 2010A, 2010B of the chassis 2002A, 2002B, respectively, etc.). The internal tubes 2304A, 2304B, 2304C, 2304D can be flexible tubes (e.g., rubber tubes, plastic tubes, etc.). Additionally or alternatively, some or all of the internal tubes 2304A, 2304B, 2304C, 2304D can be rigid or substantially rigid tubes (e.g., metal piping, plastic tubes, etc.). In some examples, some or all of the internal tubes 2304A, 2304B, 2304C, 2304D be insulated. In the illustrated example of FIG. 23, the internal tubes 2304A, 2304B, 2304C, 2304D extend through holes (e.g., the rectification holes, etc.) of the rectification plate 2306. In other examples, the internal tubes 2304A, 2304B, 2304C, 2304D can reach the connectors 2202A, 2202B, 2202C, 2202D by any other suitable path. In the illustrated example of FIG. 23, the internal tubes 2304A, 2304B, 2304C, 2304D have a generally circular cross-section. In other examples, the internal tubes 2304A, 2304B, 2304C, 2304D can have any suitable shape.

In the illustrated example of FIG. 23, the connectors 2202A, 2202B, 2202C, 2202D can be at least partially loose or “floating” (e.g., not rigidly coupled to the internal tubes 2304A, 2304B, 2304C, 2304D, etc.). For instance, the locations of connectors 2202A, 2202B, 2202C, 2202D in the tank 2000 can shift during coupling of the chassis 2002A, 2002B to the tank 2000, thereby mitigating minor assembly tolerance variation(s). In other examples, the connectors 2202A, 2202B, 2202C, 2202D can be coupled to the shell 2204 via one or more fasteners, chemical adhesives, and any other suitable means (e.g., a press fit, a shrink fit, etc.). Additionally or alternatively, an inner diameter of the connectors 2202A, 2202B, 2202C, 2202D can be threaded and received by corresponding threaded feature of the shell 2204 and/or the internal tubes 2304A, 2304B, 2304C, 2304D to threadedly couple the connectors 2202A, 2202B, 2202C, 2202D.

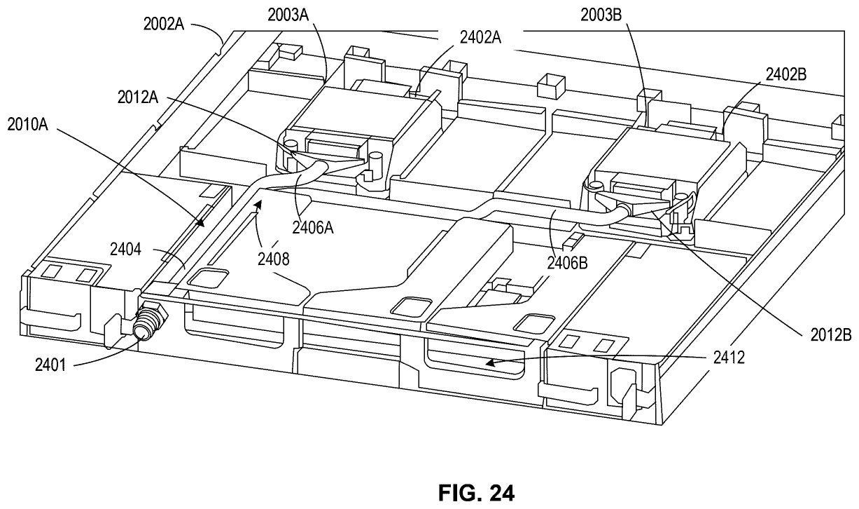

FIG. 24 is a perspective view of the first chassis 2002A of FIG. 20. In the illustrated example of FIG. 24, the chassis 2002A includes the example first internal flow path 2010A of FIG. 20, the example nozzles 2012A, 2012B of FIG. 24, the example compute units 2003A, 2003B of FIG. 20 and an example connector 2401. In the illustrated example of FIG. 24, an example first heat sink 2402A is associated with (e.g., coupled to, carried by) the first compute unit 2003A and an example second heat sink 2402B is associated with (e.g., coupled to, carried by) the second compute unit 2003B. In the illustrated example of FIG. 24, the internal flow path 2010A is formed via an example first tube 2404, an example second tube 2406A, and an example third tube 2406B.

The example connector 2401 of FIG. 24 can removably couple one of the connectors of the connector array 2006. In some examples, the connector 2401 can be a QD connector, that enables the connector 2401 to affix to a respective one of the connector array 2006 without a user manually accessing the connector 2401 or the connector array 2006 to cause the coupling. For example, the top of the chassis 2002A can include a user input (e.g., a self-lock toggle, etc.) that controls locking and unlocking of the connector 2401 and one of the connector array 2006 when such connectors are in contact. In some such examples, the connector 2401 enables the first chassis 2002A to be removed from the tank 2000 during operation of the tank 2000 (e.g., to be replaced, to be serviced, to be inspected, etc.) without interrupting circulation of the coolant elsewhere through the tank 2000 and/or the operation of the compute components of the other chassis 2002B in the tank 2000 (e.g., a “hot swap” or field replacement of the first chassis 200A, etc.). Additionally or alternatively, the connector 2401 can include threads that can be joined to one of the connector array 2006 via corresponding threads disposed thereon. In other examples, the connector 2401 can be joined to the manifold 2004 via any other suitable means. In the illustrated example of FIG. 24, the connector 2401 is disposed on a left side of an example rear panel 2412 of the first chassis 2002A (when the chassis 2002A is oriented as shown in FIG. 24). In other examples, the connector 2401 can be disposed at any other suitable location (e.g., another location on the rear panel 2412, on a front face of the chassis 2002A, on a rear face of the chassis 2002B, etc.).

In the illustrated example of FIG. 24, coolant, flowing sequentially from a connector of the connector array 2006 of FIG. 22, the manifold flow path 2302 of FIG. 23, the manifold inlet 2008 of FIG. 20, and the main inlet 2110 of FIG. 21, is received by the first chassis 2002A via the connector 2401. In the illustrated example of FIG. 24, the coolant leaves the connector 2401 and flows through the second tube 2406A to an example junction 2408. In the illustrated example of FIG. 24, after leaving the junction 2408, the coolant is split (e.g., evenly split, unevenly split, etc.) between the second tube 2406A and the third tube 2406B and subsequently discharged into the main flow path of the tank via the nozzles 2012A, 2012B, respectively. The tubes 2404, 2406A, 2406B can be composed of any suitable material (e.g., metal, rubber, plastic, etc.) and can be rigid, substantially rigid, or flexible. In the illustrated example of FIG. 24, the tubes 2404, 2406A, 2406B have a generally circular cross-section. In other examples, the tubes 2404, 2406A, 2406B can have any suitable shape. In the illustrated example of FIG. 24, the nozzles 2012A, 2012B are coupled to the ends of the tubes 2406A, 2406B, respectively (e.g., via threads, via one or more fasteners, via a press fit, via a shrink fit, etc.). The discharging of coolant from the internal flow path 2010A by the nozzles 2012A, 2012B increases the local flow rate and decreases the temperature of the coolant flowing over the heat sinks 2402A, 2402B, thereby increasing the efficiency of the cooling of the heat sinks 2402A, 2402B. In some examples, coolant from the internal flow path 2010A mixes with the coolant of the main flow path and is expelled via the outlet 2112 of the tank 2000. While one example implementation of the internal flow path 2010A is depicted in FIG. 24, the internal flow path 2010A can have any other suitable configuration.

The heat sinks 2402A, 2402B are associated with (e.g., coupled to, disposed over at least a portion of) the compute units 2003A, 2003B, respectively. The heat sinks 2402A, 2402B absorb heat from the compute units 2003A, 2003B via conduction. In the illustrated example of FIG. 24, the heat sinks 2402A, 2402B include fins that extend parallel to the flow direction of the coolant over the chassis 2002A. As coolant flows over the heat sinks 2402A, 2402B and through fins of the heat sinks 2402A, 2402B, heat is dissipated from the heat sinks 2402A, 2402B into the coolant via convection (e.g., natural convection, forced convection, etc.). In some examples, the fins of the heat sinks 2402A, 2402B create high flow impedance in the main flow path around the compute units 2003A, 2003B. As such, in this example, an amount of the coolant (e.g., most of the coolant) of the main flow path bypasses the heat sinks 2402A, 2402B and creates a region of lower mass flow rate over the heat sinks 2402A, 2402B. The heat sinks 2402A, 2402B can be composed of any suitable material that is thermally conductive and compatible with the coolant of the tank 2000 (e.g., copper, aluminum, another metal, etc.). In some examples, because of the increased flow rate and lower temperature associated with the spot cooling of the nozzles 2012A, 2012B, the heat sinks 2402A, 2402B can be composed of a less costly material (e.g., aluminum, etc.) having lower thermal conductivity than a material such as copper that might otherwise be used for the heat sinks 2402A, 2402B without the targeted cooling by the nozzles 2012A, 2012B.

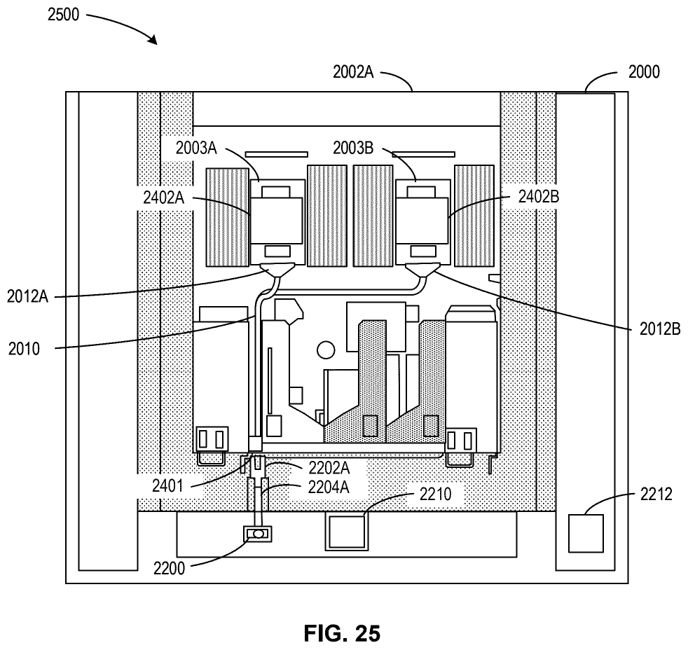

Two example configurations of the chassis 2002A relative to the manifold 2004 are disclosed below in conjunction with FIGS. 25-27. While FIGS. 25-27 describe two possible configurations of the mounting arrangement of the chassis 2002A on to the manifold 2004, it should be appreciated that other configurations can be used. For example, the examples of FIGS. 25-27 include internal flow paths and main flow paths that move coolant in a bottom-to-top (e.g., from a location closer to Earth to a location farther from Earth, etc.). In other examples, one or both of the internal flow paths and main flow paths of a tank and/or a chassis can move coolant top-to-bottom, etc.). Additionally or alternatively, chassis can be rotated 180 degrees (e.g., upside down in the tank 2000, etc.). In some such examples, the required coolant level in the tank 2000 can be reduced.

FIG. 25 is a front view of the first chassis 2002A of FIG. 20 in an example first configuration 2500 relative to the manifold 2200 of FIGS. 22 and 23. In the illustrated example of FIG. 25, the first configuration 2500 includes a direct connection between the connector 2401 of FIG. 24 and connector 2202A of FIG. 23. In the illustrated example of FIG. 25, coolant is received by the manifold 2200 from the CDU 2102 of FIG. 21 (e.g., via the second inlet line 2106 of FIG. 21, etc.), flows through one of the internal tube 2204A and the other internal tubes of the manifold 2200. After leaving the internal tubes of the internal tube 2204A, the coolant flow through the connectors 2202A, 2401 and into the internal flow path 2010 of the chassis 2002A and then is directed onto to the heat sinks 2402A, 2402B by the nozzles 2012A, 2012B, etc. In some examples, concurrently with the flow through the internal flow path 2010, coolant also flows over the length of the chassis 2002A via the main flow path of the tank 2000, which enters the tank 2000 via the tank inlet 2210. After flowing through the tank 2000 and the internal flow path, coolant leaves the tank via the outlet 2212.

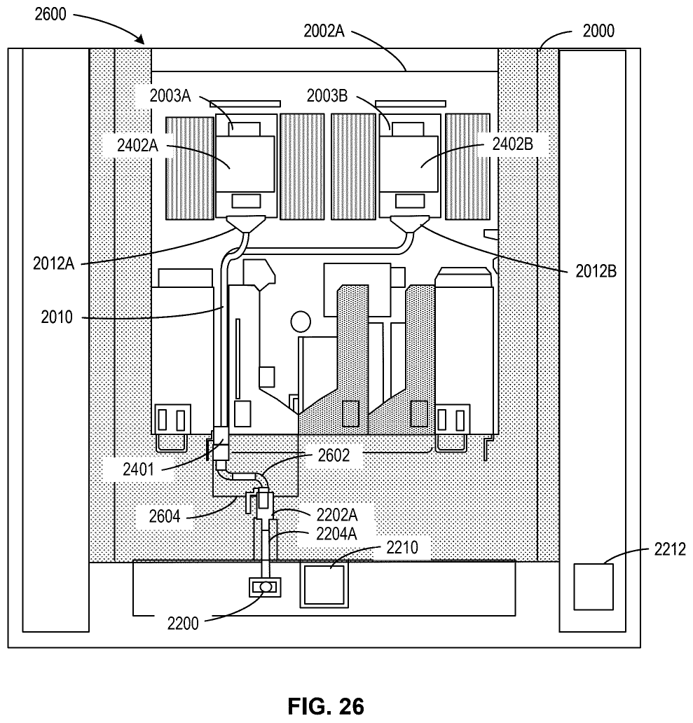

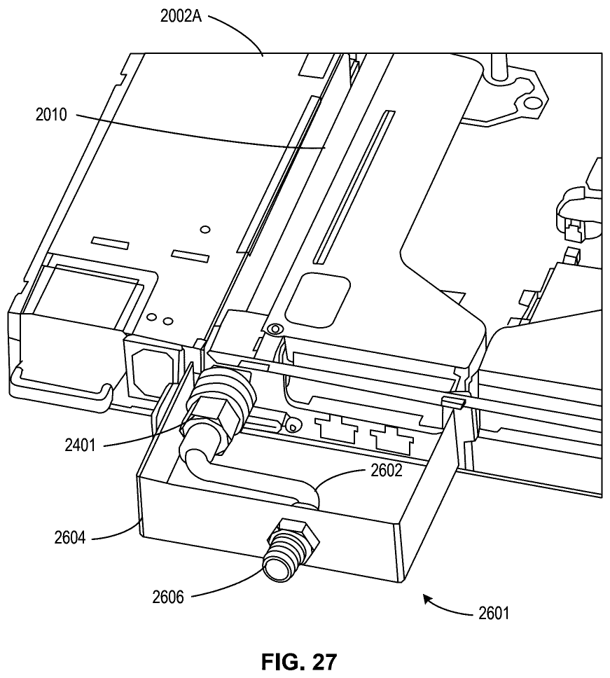

FIGS. 26 and 27 are a front view and a perspective view, respectively, of the first chassis 2002A and the manifold 2004 in an example second configuration 2600. In the illustrated examples of FIGS. 26 and 27, the chassis 2002A includes an example bracket assembly 2601, which includes an example bracket tube 2602, an example bracket 2604, and an example bracket connector 2606.

The bracket tube 2602 extends between the bracket connector 2606 and the connector 2401. The bracket tube 2602 can be a flexible tube (e.g., a rubber tube, a plastic tube, etc.). Additionally or alternatively, the bracket tube 2602 can be a rigid or substantially rigid tube (e.g., metal piping, plastic tubes, etc.). In some examples, the bracket tube 2602 can be insulated. While the bracket tube 2602 is generally S-shaped in the illustrated examples of FIGS. 26 and 27, the bracket tube 2602 can have any other suitable shape based on the locations of the connector 2401 and manifold and/or the configuration of the tank 2000. In the illustrated example of FIG. 26, the bracket tube 2601 has a generally circular cross-section. In other examples, the bracket tube 2601 can have any suitable shape.

The bracket 2604 is disposed between the manifold 2200 and the first chassis 2002A. In some examples, the bracket 2604 supports the vertical load associated with the first chassis 2002A. In other examples, the first chassis 2002A can be supported in any other suitable matter. In other examples, if the bracket 2604 is horizontally disposed in the tank 2000, the bracket can support the shear load associated with the first chassis 2002A. In the illustrated example of FIG. 26, the bracket 2604 is generally U-shaped. In other examples, the bracket 2604 can have any other suitable shape (e.g., based on the mechanical specifications of the bracket 2604, the comparative locations of the chassis inlet and the manifold, the shape of the bracket tube 2602, the means of coupling the bracket 2604 to the first chassis 2002A, etc.). The bracket 2604 can be composed of any suitable material (e.g., a metal, a plastic, a composite, a ceramic, etc.).

In the illustrated examples of FIGS. 26 and 27, the bracket 2604 has a width that is approximately equal in length with the width of the first chassis 2002A. In other examples, the bracket 2604 can be comparatively shorter than the width of the first chassis 2002A. In other examples, the bracket 2604 can extend along the entire or substantially length of the tank 2000, thereby enclosing other bracket tubes (e.g., associated with other chassis, etc.) similar to the bracket tube 2602. In the illustrated example of FIGS. 26 and 27, the bracket 2604 does not include front or back side walls. In other examples, the bracket 2604 can include side walls that partially or fully enclose the bracket tube 2602. In some such examples, the space within the bracket 2604 does not include coolant, thereby reducing the coolant volume of the tank 2000.

The example bracket connector 2606 of FIG. 26 couples with one of the connectors of the connector array 2006. In some examples, the bracket connector 2606 can be fixedly coupled to a connector array 2006 (e.g., via a weld, via a shrink fit, as an integral part, etc.). In some such examples, the bracket connector 2606 enables the first chassis 2002A to be removed from the bracket assembly 2601 and/or the tank 2000 during operation of the tank 2000 (e.g., to be replaced, to be serviced, to be inspected, etc.) without interrupting circulation of the coolant elsewhere through the tank 2000 and/or the operation of the compute components other chassis 2002B in the tank 2000 (e.g., a “hot swap,” etc.). In the illustrated examples of FIGS. 26 and 27, the bracket connector 2606 are QD connectors. Additionally or alternatively, the connector 2606 can be removably coupled to a connector array 2006 (e.g., via threads, via fastener, via a press fit, etc.). In some examples, the bracket connector 2606 can be any other suitable type of connector. The bracket assembly 2601 can be fixedly coupled to the chassis 2003A in a manner that allows the chassis 2003A and the bracket 2601 to be removed as a single unit from the tank 2000.

In the illustrated example of FIG. 26, the second configuration 2600 includes an additional portion between the connector 2202A and the connector 2401 as compared to the first configuration 2500 of FIG. 25, namely the bracket tube 2602. In the illustrated example of FIG. 26, coolant is received by the manifold 2200 from the CDU 2102 of FIG. 21 (e.g., via the second inlet line 2106 of FIG. 21, etc.) and then flows through one of the internal tube 2204A and the other internal tubes of the manifold 2200. After leaving the internal tubes of the internal tube 2204A, the coolant flows through the bracket connector 2606 and into the bracket tube 2602. After flowing through the bracket tube 2602, the coolant enters the internal flow path 2010 of the chassis 2002A via the connector 2401 and then is directed onto to the heat sinks 2402A, 2402B by the nozzles 2012A, 2012B, etc. In some examples, concurrently with the flow through the internal flow path 2010, coolant also flows over the length of the chassis 2002A, which enters the tank 2000 via the tank inlet 2210. After flowing through the tank 2000 and the internal flow path, the coolant leaves the tank via the outlet 2212. The first configuration 2500 and the second configuration 2600 can be selected based on properties of, for instance, the chassis 2002A, 2002B (e.g., size parameters such as a length of the chassis 2002A, 2002B) and/or other variables. For instance, the second configuration 2600 can be used in instances in which the connectors of the chassis 2002A do not align with the connectors 2006 of the manifold 2004.

FIG. 28 is a front view of a system 2800 including a prior tank 2802 and a prior chassis 2804. In FIG. 28, the chassis 2804 includes a first upstream compute unit 2804A, a second upstream compute unit 2804B, a third downstream compute unit 2805A, and a fourth downstream compute unit 2805B. In FIG. 28, the tank 2802 is filled with coolant 2806, which flows through the tank 2802 in a flow direction 2810. In FIG. 28, the coolant 2806 is provided by a CDU 2812 and enters the tank 2802 through an inlet 2808. In FIG. 28, the coolant 2806 is cooled in the CDU 2812 via facility fluid 2814. In FIG. 28, the tank 2802 has a first level 2816, a second level 2818, a third level 2820, and a fourth level 2822.

The tank 2802 is a single phase immersion cooling tank. For example, the coolant 2806 can enter the tank 2802 via the inlet 2808, flows through the tank in flow direction 2810, and exits the tank through an outlet (not illustrated). During operation of the tank 2802 and the chassis 2804, the coolant enters and leaves the tank 2802 (e.g., via natural flow, via one or more pump(s) of the CDU 2812, etc.) at a constant and equal rate or substantially constant and equal, thereby maintaining the coolant 2806 at the fourth level 2822 while continuously cycling hot coolant out of the tank 2802 for cooling via the CDU 2812.

The chassis 2804 is disposed in (e.g., supported by, coupled within) the tank 2802. The chassis 2804 includes one or more the compute units 2804A, 2804B, 2805A, 2805B and related compute components (e.g., power supplies, permeant memory, temporary memory, etc.). In the illustrated example of FIG. 28, the chassis 2804 has a shadowed form factor (e.g., the first upstream compute unit 2804A and the first downstream compute unit 2805A are disposed in sequence, the second upstream compute unit 2805A and the second downstream compute unit 2805B, etc.). In other examples, the compute units 2804A, 2804B, 2805A, 2805B of the chassis 2804 can have other orientation(s)/layout(s)/form factor(s) (e.g., spreadcore, etc.). Operation of the chassis 2804 generates a comparatively high amount of heat, which is absorbed and dissipated via the circulation of the coolant through the tank 2802. The tank 2802 can include a plurality of additional chassis disposed in parallel to the chassis 2804, where compute components thereof are similarly cooled via the circulation of the coolant through the tank 2802.

The CDU 2812 is a mechanical unit that cools, pumps, and distributes the coolant 2806 into one or more immersion cooling tanks, including the tank 2802. The example CDU 2812 can include one or more heat exchanger(s) (e.g., one or more shell and tube heat exchanger(s), one or more tube-in-tube heat exchanger(s), etc.) that cools the coolant via the flow of the facility fluid 2814. In some examples, the facility fluid is a water from a municipal water supply. In some such examples, the municipal water supply generally supplies facility fluid 2814 at a fixed temperature (e.g., 32 degrees Celsius (C), 45 degrees C., etc.). In some such examples, the CDU 2812 can include an inlet and/or an outlet to access and discharge water used to regulate the temperature of the coolant. In some examples, the CDU 2812 can include one or more radiators to cool the coolant and/or the heat exchange fluid via air convection. Additionally or alternatively, the CDU 2812 can include one or more pumps to drive the coolant through the tank 2802. Because the CDU 2812 uses facility fluid 2814 to cool the coolant via one or more heat exchangers, the inlet temperature of the coolant 2806 (e.g., the temperature of the coolant 2806 at the inlet 2808, the temperature of the coolant 2806 at the first level 2816, etc.) is limited (e.g., cannot be less than, etc.) the temperature of the facility fluid 2814.

The compute units 2804A, 2804B, 2805A, 2805B typically have the highest TDP of the components of the chassis 2804. If the compute units 2804A, 2804B, 2805A, 2805B exceed desired operating temperatures, the performance (e.g., processing action rate, etc.) can be throttled to reduce the TDP of the compute units 2804A, 2804B, 2805A, 2805B. In some examples, the efficiency of the convection cooling of the compute units 2804A, 2804B, 2805A, 2805B by the coolant 2806 is based on the thermal properties of the coolant, the rate of flow of the coolant 2806 through the tank 2802, and/or the temperature of the coolant 2806 when the coolant flows over the respective ones of the compute units 2804A, 2804B, 2805A, 2805B. While the thermal properties of the coolant 2806 are defined by the coolant type, the flow rate of the coolant 2806 can be increased (e.g., via higher power pumps at the CDU 2812, etc.) and the temperature of the coolant 2806 can be controlled by the CDU 2812 and the geometry of the tank 2802.

At the first level 2816, the coolant 2806 is approximately equal in temperature to the temperature of the coolant 2806 at the inlet 2808. As the coolant 2806 flows in the flow direction 2810, the coolant 2806 undergoes some warming (e.g., 1% warming, 2% warming, 5% warming, etc.) from the downstream coolant 2806 (e.g., via conduction, etc.) and convection from the components of the chassis 2804 between the first level 2816 and the second level 2818. Between the second level 2818 and the third level 2820, the coolant 2806 encounters the upstream units 2804A, 2804B. As the coolant flows over the upstream compute units 2804A, 2804B, the coolant 2806 absorbs heat from the compute units 2804A, 2804B and increases in temperature. Because of the heat absorption from the compute units 2804A, 2804B, the coolant 2806 at the third level 2818 is substantially warmer (e.g., 20% warmer, 25% warmer, etc.) than the coolant 2806 at the second level 2818. As such, the coolant 2806 is substantially warmer when the coolant 2806 cools the downstream compute units 2805A, 2805B than when the coolant 2806 cools the upstream compute units 2804A, 2804B. Accordingly, the cooling of the downstream units 2805A, 2805B by the coolant 2806 may be less effective than the cooling of the upstream units 2804A, 2804B by the coolant 2806. As used herein, the warming of coolant by upstream compute units before the coolant cools downstream compute units is referred to as “coolant preheat” or “preheat.” Coolant preheat may reduce the cooling capacity of the coolant 2806 used to cool the downstream units 2805A, 2805B. As a result, performance of the downstream compute units 2805A, 2805B may be affected.

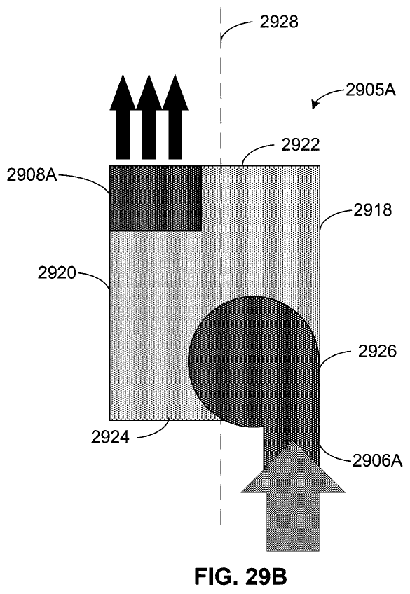

FIG. 29A is a front view of an example immersion cooling system 2900 in accordance with teachings of this disclosure. In the illustrated example of FIG. 29A, the immersion cooling system 2900 includes an example tank 2901 (which may be the same or substantially similar to the tank 2802 of FIG. 28), the coolant 2806 of FIG. 28, and an example chassis 2902. In the illustrated example of FIG. 29A, the chassis 2902 includes an example first upstream unit 2903A, an example second upstream unit 2903B, an example first downstream unit 2904A, and an example second downstream unit 2904B. The chassis 2902 can include additional or fewer compute units. In the illustrated example, an example first cold plate 2905A, an example second cold plate 2905B, an example third cold plate 2905C, and an example fourth cold plate 2905D is associated with (e.g., coupled to) the compute units 2903A, 2903B, 2904A, 2904B, respectively. The example first cold plate 2905A includes an example first inlet 2906A and an example first outlet 2908A. The example second cold plate 2905B includes an example second inlet 2906B and an example second outlet 2908B. The example third cold plate 2905C includes an example third inlet 2906C and an example third outlet 2908C. The example fourth cold plate 2905D includes an example fourth inlet 2906D and an example fourth outlet 2908D. In the illustrated example of FIG. 28, the tank 2802 has the first level 2816, the second level 2818 of FIG. 28, and the third level 2820 of FIG. 28.

The example tank 2901 of FIG. 29A is a single phase immersion cooling tank. For example, the coolant 2806 can enter the tank 2901 via the inlet 2808, flows through the tank in flow direction 2810, and exits the tank through an outlet (not illustrated). During operation of the tank 2901, the coolant enters and leaves the tank 2901 (e.g., via natural flow, via one or more pump(s) of the CDU 2812, etc.) at a constant and equal or substantially constant and equal rate, thereby maintaining the coolant 2806 in the tank 2901 at a constant or substantially constant level.

The chassis 2902 is disposed in (e.g., coupled within, supported by) the tank 2901. In this example, the chassis 2902 includes (e.g., carries) the compute units 2903A, 2903B, 2904A, 2904B and related compute components (e.g., power supplies, permeant memory, temporary memory, etc.). The chassis 2902 can include additional or fewer compute components and/or types of compute components than the example shown in FIG. 29A. In the illustrated example of FIG. 29A, the chassis 2902 has a shadowed form factor (e.g., the first upstream compute unit 2903A and the first downstream compute unit 2904A are disposed in sequence, the second upstream compute unit 2903B and the second downstream compute unit 2904B, etc.). In other examples, the compute units 2903A, 2903B, 2904A, 2904B of the chassis 2902 can have any suitable orientation(s)/layout(s)/form factor(s) (e.g., spreadcore, etc.). Operation of the compute components of the chassis 2902 generates heat, which is absorbed and dissipated via the circulation of the coolant through the tank 2901 and the cold plates 2905A, 2905B, 2905C, 2905D. The tank 2901 can include additional chassis disposed in parallel to the chassis 2902, where compute components thereof are similarly cooled via the circulation of the coolant through the tank 2901.

In the illustrated example of FIG. 29A, the cold plates 2905A, 2905B, 2905C, 2905D are coupled to respective ones of the compute units associated with the 2903A, 2903B, 2904A, 2904B, etc. In some examples, the cold plates 2905A, 2905B, 2905C, 2905D can include a pad (not illustrated) that abuts an internal heat sink (IHS) of a compute component (e.g., an integrated circuit (IC)) associated with corresponding ones of the compute units 2903A, 2903B, 2904A, 2904B. In the illustrated example of FIG. 29A, the cold plates 2905A, 2905B, 2905C, 2905D include internal pumps (not illustrated in FIG. 29A, see the pump 2926 of FIG. 29B, etc.), which draw the coolant 2806 from the tank 2901 via respective ones of the inlets 2906A, 2906B, 2906C, 2906D into respective internal flow circuits (not illustrated) and expel coolant via respective ones of the example outlets 2908A, 2908B, 2908C, 2908D. As the coolant 2806 flows through the flow circuits of the cold plates 2905A, 2905B, 2905C, 2905D, the coolant 2806 absorbs heat from the body of the cold plates 2905A, 2905B, 2905C, 2905D, thereby cooling the compute units 2903A, 2903B, 2904A, 2904B. The cold plates 2905A, 2905B, 2905C, 2905D increase the local flow rate of the coolant 2806 (e.g., via the action of the integrated pumps, etc.) as compared to cold plates that do not include such pumps. As such, the example cold plates 2905A, 2905B, 2905C, 2905D of FIG. 29A improve the efficiency of the convection cooling of the compute units 2903A, 2903B, 2904A, 2904B by the coolant 2806.

In the illustrated example of FIG. 29A, the cold plates 2905A, 2905B, 2905C, 2905D at least partially mitigate the effects of coolant preheat on the convection cooling of the downstream units 2904A, 2904B. In the illustrated example of FIG. 29A, the outlets 2908A, 2908B of the cold plates 2905A, 2905B of the upstream units 2903A, 2903B are offset along the flow direction 2810 from the inlets 2906A, 2906B of the cold plates 2905C, 2905D of the downstream units 2904A, 2904B to minimize the intake of coolant 2806 used to cool the upstream units 2903A, 2903B by the cold plates 2905C, 2905D of the downstream units 2904A, 2904B. In the illustrated example of FIG. 29A, the inlets 2906A, 2906B, 2906C, 2906D are on an opposite side (e.g., a right side, etc.) of the respective ones of the cold plates 2905A, 2905B, 2905C, 2905D as the side (e.g., a left side, etc.) of the outlets 2908A, 2908B, 2908C, 2908D of the 2905A, 2905B, 2905C, 2905D. In other examples, the sides of the inlets 2906A, 2906B, 2906C, 2906D and the outlets 2908A, 2908B, 2908C, 2908D can be reversed (e.g., the inlets 2906A, 2906B, 2906C, 2906D are on a left side of the respective cold plates 2905A, 2905B, 2905C, 2905D, the outlets 2908A, 2908B, 2908C, 2908D on a right side of the respective cold plates 2905A, 2905B, 2905C, 2905D, etc.). In some examples, the outlets 2908A, 2908B associated with the upstream units 2903A, 2903B can include tube(s) (not illustrated) that direct the comparatively warm coolant being expelled from the cold plates 2905A, 2905B to a location along the flow path of the tank 2901 adjacent to or downstream from the inlets 2906C, 2906D of the downstream units 2904A, 2904B. In some such examples, the tube(s) prevent or substantially prevent hot coolant from the outlets 2908A, 2908B from being taken in by the inlets 2906C, 2906D of the downstream units 2904A, 2904B, thereby further mitigating detrimental preheat effects. In other examples, the inlets 2906A, 2906B, 2906C, 2906D and the outlets 2908A, 2908B, 2908C, 2908D can have any other suitable orientations and/or positions. The example first cold plate 2905A is disclosed in greater detail below in conjunction with FIG. 29B with the understanding that the other cold plates 2905B, 2905C, 2905D can be the same or substantially the same as the first cold plate 2905A. An example implementation of the cold plates 2905A, 2905B, 2905C, 2905D is disclosed below in conjunction with FIGS. 34A-36.

FIG. 29B is a front view of the first cold plate 2905A of FIG. 28A. In the illustrated example of FIG. 29B, the cold plate 2905A includes the inlet 2906A of FIG. 29A, the outlet 2908A of FIG. 29A, an example first side face 2918, an example second side face 2920, an example downstream face 2922 (e.g., when the cold plate 2905A is oriented as shown in FIG. 29B), an example upstream face 2924 (e.g., when the cold plate 2905A is oriented as shown in FIG. 29B), and the example integrated pump 2926. While FIG. 29B describes the first cold plate 2905A, the second cold plate 2905B, the third cold plate 2905C, the fourth cold plate 2905D can have a same or substantially the same features as the first cold plate 2905A. In other examples, some or all of the cold plates 2905A, 2905B, 2905C, 2905D can have different features (e.g., size, shape, location of components).

The integrated pump 2926 pumps coolant into the integrated cold plate 2905A from the main flow path of the tank 2901. In some examples, the integrated pump 2926 can be powered via a power source associated with the chassis 2902 (not illustrated). In other examples, the integrated pump 2926 can be powered by a dedicated power supply associated with the cold plate 2905A. In some examples, the integrated pump 2926 can be implemented by a centrifugal pump. In other examples, the integrated pump 2926 can be implemented by one or more of any other suitable type of pump (e.g., a positive-displacement pump, an axial-flow pump, an impulse pump, a rotodynamic pump, etc.) or a combination thereof. In the illustrated example of FIG. 29B, the pump 2926 and the inlet 2906A are integral components (e.g., integrally formed). In other examples, the pump 2926 and the inlet 2906A can be separate components. In some such examples, the pump 2926 can be disposed at any suitable location on the cold plate 2905A.

In the illustrated example of FIG. 29B, the inlet 2906A is disposed on the upstream face 2924 and the outlet 2908A is disposed on the downstream face 2922. In other examples, the inlet 2906A and the outlet 2908A can be disposed at any other suitable positions (e.g., on the side faces 2918, 2920, etc.). Additionally or alternatively, the cold plate 2905A can have additional inlets and/or outlets disposed at any suitable locations (e.g., additional inlets on the upstream face 2924, additional outlets on the downstream face 2922, additional outlets on one or both of the side faces 2918, 2920, additional inlets on the one or both of the side faces 2918, 2920, etc.). In the illustrated example of FIG. 29B, the cold plate 2905A has an example centerline axis 2928 collinearly oriented in a same direction as the flow direction 2810 when the cold plate 2905A is disposed in the tank 2901. In the illustrated example of FIGS. 29A and 29B, the inlet 2906A is on a first side (e.g., a right side, etc.) of the centerline axis 2928 and the outlet 2908A is on a second side (e.g., the left side, etc.). In other examples, the positions of the inlet 2906A and the outlet 2908A can be mirrored about the centerline 2928 (e.g., the inlet 2906A on the left side, the outlet 2908B on the right side, etc.). As described above in conjunction in FIG. 29A, the misalignment (e.g., the offset, etc.) of the inlet 2906A and the outlet 2908A at least partially mitigates the effects on coolant preheat on the downstream compute units 2904A, 2904B when the chassis 2902 is disposed in the tank 2901.

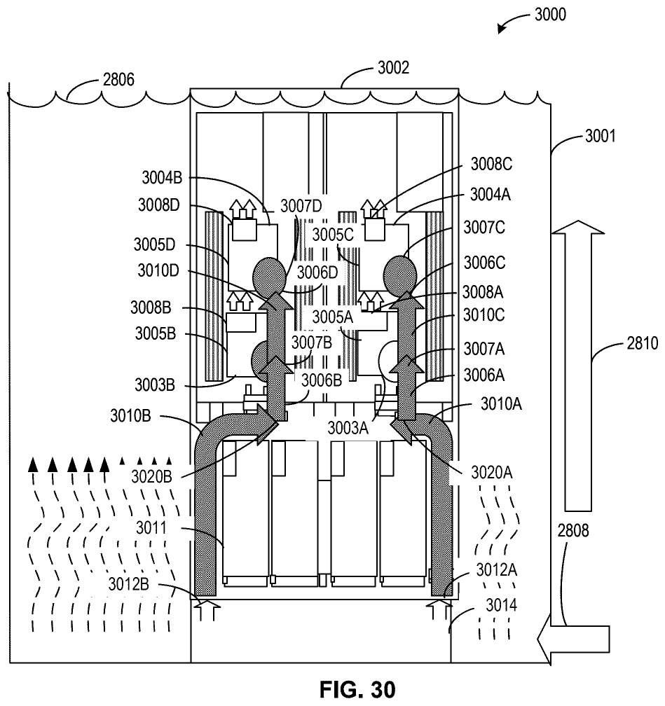

FIG. 30 is a front view of another example immersion cooling system 3000 in accordance with teachings of this disclosure. In the illustrated example of FIG. 30, the immersion cooling system 3000 includes a tank 3001 (which can be the same or substantially similar to the tank(s) 2802, 2901 of FIGS. 28 and 29), the coolant 2806 of FIG. 28, and an example chassis 3002. In the illustrated example of FIG. 30, the chassis 3002 includes an example first upstream compute unit 3003A, an example second upstream compute unit 3003B, an example first downstream compute unit 3004A, and an example second downstream compute unit 3004B. The chassis 3002 can include additional or fewer compute units and/or other types of compute components. In the illustrated example, an example first cold plate 3005A, an example second cold plate 3005B, an example third cold plate 3005C, and an example fourth cold plate 3005D is associate with (e.g., coupled to) the compute units 3003A, 3003B, 3004A, 3004B, respectively. The cold plates 3005A, 3005B, 3005C, 3005D include an example first inlet 3006A, an example second inlet 3006B, an example third inlet 3006C, and an example fourth inlet 3006D, respectively. The cold plates 3005A, 3005B, 3005C, 3005D include an example first pump 3007A, an example second pump 3007B, an example third pump 3007C, and an example fourth pump 3007D, respectively. The cold plates 3005A, 3005B, 3005C, 3005D include an example first outlet 3008A, an example second outlet 3008B, an example third outlet 3008C, and an example fourth outlet 3008D, respectively.

The example tank 3001 of FIG. 30 is a single phase immersion cooling tank. For example, the coolant 2806 enters the tank 3001 via the inlet 2808, flows through the tank in flow direction 2810, and exits the tank through an outlet (not illustrated). During operation of the tank 3001, the coolant enters and leaves the tank 3001 (e.g., via natural flow, via one or more pump(s) of the CDU 2812, etc.) at a constant and equal rate, thereby maintaining the coolant 2806 at a constant level.

The chassis 3002 is disposed in (e.g., supported by, coupled within) the tank 3001. The example chassis 3002 of FIG. 30 includes (e.g., carries) the compute units 3003A, 3003B, 3004A, 3004B, an example power supply array 3011, and other compute components (e.g., permeant memory, temporary memory, etc.). The chassis 3002 can include additional or fewer compute components and/or types of compute components than the example shown in FIG. 30. In the illustrated example of FIG. 30, the chassis 3002 has a shadowed form factor (e.g., the first upstream compute unit 3003A and the first downstream compute unit 3004A are disposed in sequence, the second upstream compute unit 3003B and the second downstream compute unit 3004B, etc.). In other examples, the compute units 3003A, 3003B, 3004A, 3004B of the chassis 3002 can have any suitable orientation(s)/layout(s)/form factor(s) (e.g., spreadcore, etc.). Operation of the compute components of the chassis 3002 generates heat, which is absorbed and dissipated via the circulation of the coolant through the tank 3001 and the cold plates 3005A, 3005B, 3005C, 3005D. The tank 3001 can include additional chassis disposed in parallel to the chassis 3002, where compute components thereof are similarly cooled via the circulation of the coolant through the tank 3001.

In the illustrated example of FIG. 30, the inlets 3006A, 3006B, 3006C, 3006D of the cold plates 3005A, 3005B, 3005C, 3005D receive coolant from an example first pipe 3010A, an example second pipe 3010B, an example third pipe 3010C, and an example fourth pipe 3010D. In the illustrated example of FIG. 30, the first pipe 3010A and the third pipe 3010C receive coolant from an example first outlet 3008A of an example manifold 3014. In some examples, the cold plates 3005A, 3005B, 3005C, 3005D are the same or substantially the same as the cold plates 2905A, 2905B, 2905C, 2905D of FIGS. 29A and 29B. In the illustrated example of FIG. 30, the second pipe 3010B and the fourth pipe 3010D receive coolant from an example second outlet 3008B of the example manifold 3014. In other examples, each of the pipes 3010A, 3010B, 3010C, 3010D can be coupled to a distinct and/or separate outlet of the manifold 3014.

In the illustrated example of FIG. 30, the cold plates 3005A, 3005B, 3005C, 3005D are coupled to respective ones of the compute units 3003A, 3003B, 3004A, 3004B, etc. In some examples, the cold plates 3005A, 3005B, 3005C, 3005D can include a pad (not illustrated) that abuts an internal heat sink (IHS) of a compute component (e.g., an integrated circuit (IC)) associated with corresponding ones of the compute units 3003A, 3003B, 3004A, 3004B. In the illustrated example of FIG. 30, the integrated pumps 3007A, 3007B, 3007C, 3007D draw the coolant 2806 from the tank 3001 from the corresponding ones of the pipes 3010A, 3010B, 3010C, 3010D into respective ones of the inlets 3006A, 3006B, 3006C, 3006D. In some examples, after the coolant 2806 enters the cold plates 3005A, 2905B, 2905C, 2905D, the coolant 2806 flows through respective internal flow circuits (not illustrated) and is expelled via respective ones of the example outlets 3008A, 3008B, 3008C, 3008D. As the coolant 2806 flows through the flow circuits of the cold plates 3005A, 3005B, 3005C, 3005D, the coolant 2806 absorbs heat from the body of the cold plates 3005A, 3005B, 3005C, 3005D, thereby cooling the compute units 3003A, 3003B, 3004A, 3004B.

The integrated pumps 3007A, 3007B, 3007C, 3007D pump the coolant 2806 into the integrated cold plates 3005A, 3005B, 3005C, 3005D from the main flow path of the tank 3001. In some examples, the integrated pumps 3007A, 3007B, 3007C, 3007D can be powered via a power supply array 3011. Additionally, or alternatively, the integrated pumps 3007A, 3007B, 3007C, 3007D can be powered by a dedicated power supply associated with the cold plates 3005A, 3005B, 3005C, 3005D. In some examples, the integrated pump 3007A, 3007B, 3007C, 3007D can be implemented by one or more centrifugal pump(s). In other examples, some or all of the integrated pumps 3007A, 3007B, 3007C, 3007D can be implemented by one or more of any other suitable type of pump (e.g., a positive-displacement pump, an axial-flow pump, an impulse pump, a rotodynamic pump, etc.) or a combination thereof. In the illustrated example of FIG. 30, each of the pumps 3007A, 3007B, 3007C, 3007D is integral with (e.g., integrally formed with) the corresponding ones of the inlets 3006A, 3006B, 3006C, 3006D. In other examples, some or all of the pumps 3007A, 3007B, 3007C, 3007D and the corresponding inlets 3006A, 3006B, 3006C, 3006D can be separate components. The pumps 3007A, 3007B, 3007C, 3007D of the cold plates 3005A, 3005B, 3005C, 3005D increase the local flow rate of the coolant 2806 over the compute units 3003A, 3003B, 3004A, 3003B as compared to cold plates that do not include such pumps. As such, the cold plates 3005A, 3005B, 3005C, 3005D improve the efficiency of the convection cooling of the compute units 3003A, 3003B, 3004A, 3003B by the coolant 2806.

In the illustrated example of FIG. 30, the immersion cooling system 3000 includes the example pipes 3010A, 3010B, 3010C, 3010D to direct coolant from the inlet 2808 to cold plates 3005A, 3005B, 3005C, 3005D (e.g., directly to the cold plates 3005A, 3005B, 3005C, 3005D). In the illustrated example of FIG. 30, the third pipe 3010C branches from the first pipe 3010A near the first inlet 3006A and the fourth pipe 3010D branches from the second pipe 3010B near the second inlet 3006B. In other examples, some or both of the third pipe 3010C and the fourth pipe 3010D can be connected to the manifold 3014 via independent inlets (e.g., inlets different than the inlets 3012A, 3012B, etc.). In some examples, some or all of the pipes 3010A, 3010B, 3010C, 3010D can be flexible tubes (e.g., rubber tubes, plastic tubes, etc.). Additionally or alternatively, some or all of the pipes 3010A, 3010B, 3010C, 3010D can be rigid or substantially rigid tubes (e.g., metal piping, plastic tubes, etc.). In the illustrated example of FIG. 30, the pipes 3010A, 3010B, 3010C, 3010D have a generally circular cross-section. In other examples, the pipes 3010A, 3010B, 3010C, 3010D can have any suitable shape. In some examples, some or all of the pipes 3010A, 3010B, 3010C, 3010D can be insulated to reduce heat transfer between the coolant in the corresponding ones of the pipes 3010A, 3010B, 3010C, 3010D and the ambient environment. In some examples, the pipes 3010A, 3010B, 3010C, 3010D include sealing mechanisms (e.g., seals, gaskets, etc.) to prevent coolant 2806 in the pipes 3010A, 3010B, 3010C, 3010D from leaking into the tank 3001.

In the illustrated example of FIG. 30, the first pipe 3010A is connected to the first inlet 3006A and the third pipe 3010C via an example first connector 3020A and the second pipe 3010B is connected to the second inlet 3006B and the fourth pipe 3010D via an example second connector 3020B. In the illustrated example of FIG. 30, the connectors 3020A, 3020B are quick disconnect (QD) connectors. In some such examples, the connectors 3020A, 3020B can include a togglable self-lock mechanism, which can be enabled/disabled to enable the installation/removal of the corresponding compute units 3003A, 3003B, 3004A, 3004B without stopping the functioning of the other compute units. In other examples, the connectors 3020A, 3020B can be implemented by any other suitable connector.

In the example of FIG. 30, the manifold 3014 is disposed at a bottom of the tank 3001 and/or adjacent the inlet 2808 (e.g., in the orientation shown in FIG. 30). For example, the manifold 3014 can be the same or substantially similar to the manifold 2004 of FIGS. 20-23. In the illustrated example of FIG. 30, the pipes 3010A, 3010B, 3010C, 3010D receive coolant 2806 from the manifold 3014 via the inlet 3012A, 3012B. In some examples, the manifold 3014 can receive the coolant 2806 directly from the inlet 2808 (e.g., via a pipe, etc.). Additionally or alternatively, the manifold 3014 can receive the coolant 2806 from a second inlet (e.g., the inlet 2008 of FIGS. 20 and 21, etc.) different than the inlet 2808. In some examples, the manifold 3014 can be absent. In some such examples, the inlets 3012A, 3012B can draw the coolant 2806 directly from the bottom of the tank 3001.

In the illustrated example of FIG. 30, the cold plates 3005A, 3005B, 3005C, 3005D mitigate (e.g., fully mitigate, partly mitigate, etc.) the effects of coolant preheat on the convection cooling of the downstream units 3004A, 3004B by drawing coolant 2806 from (e.g., directly from) the manifold 3014. In some such examples, the coolant 2806 in the manifold is approximately the same temperature as the coolant 2806 at the inlet 2808, which, in this example, is the coolant 2806 having the lowest temperature available for cooling the compute components of the chassis 3002. As such, the coolant 2806 used to cool the compute units 3003A, 3003B, 3004A, 3004B (e.g., the coolant 2806 circulating through the cold plates 3005A, 3005B, 3005C, 3005D, etc.) is approximately equal in temperature as the coolant 2806 of the inlet 2808 and is approximately the same temperature for both the upstream compute units 3003A, 3003B and the downstream units 3004A, 3004B. Accordingly, the downstream units 3004A, 3004B are not subjected to coolant preheat that could otherwise be caused by the cooling of the upstream units 3003A, 3003B. In some examples, the outlets 3008A, 3008B associated with the upstream units 3003A, 3003B can include tube(s) (not illustrated) that direct the comparatively warm coolant expelled from the cold plates 3005A, 3005B to a location along the flow path of the tank 3001 adjacent to or downstream of the downstream units 3004A, 3004B. In some such examples, the tube(s) prevent or substantially prevent hot coolant from the outlets 2908A, 2908B from interacting with the downstream units 3004A, 3004B (e.g., via convection), thereby further mitigating preheat effects. Also, the example immersion cooling system 3000 of FIG. 30 prevents or substantially prevents preheating of the coolant 2806 used to cool the units 3003A, 3003B, 3004A, 3004B by the heat output of the power supply array 3011. An example implementation of the cold plates 3005A, 3005B, 3005C, 3005D are described below in conjunction with FIGS. 34A-36.

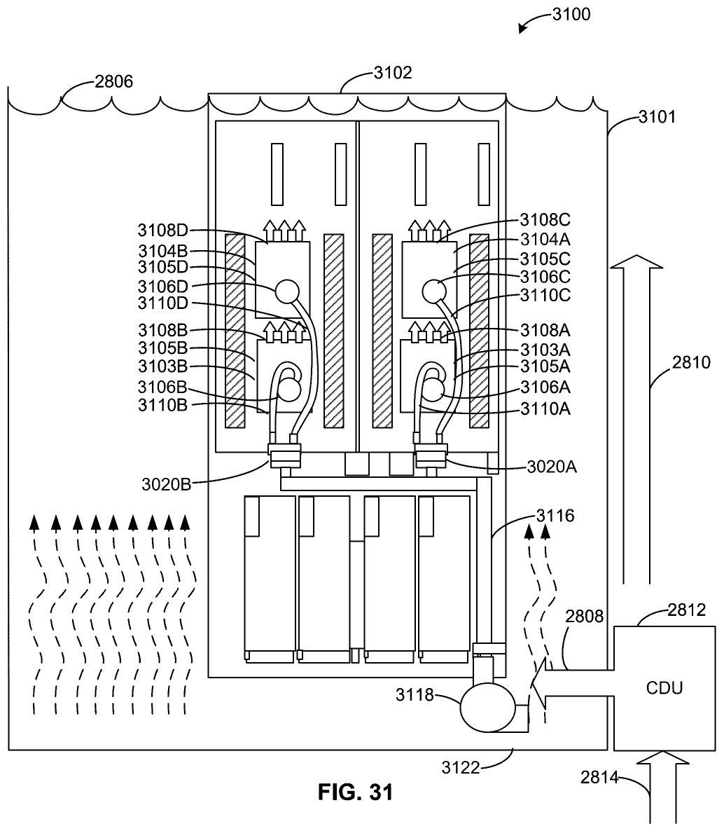

FIG. 31 is a front view of another example system 3100 including an example tank 3101 and an example chassis 3102 in accordance with teachings of this disclosure. In the illustrated example of FIG. 31, the cooling system 3100 includes an example tank 3101, the coolant 2806 of FIG. 28, and an example chassis 3002. In the illustrated example of FIG. 31, the chassis 3102 includes an example first upstream compute unit 3103A, an example second upstream compute unit 3103B, an example first downstream compute unit 3104A, and an example second downstream compute unit 3104B. In the illustrated example, an example first cold plate 3105A, an example second cold plate 3105B, an example third cold plate 3105C, and an example fourth cold plate 3105D is associated with (e.g., coupled to) the compute units 3103A, 3103B, 3104A, 3104B, respectively. The cold plates 3105A, 3105B, 3105C, 3105D include an example first receiver 3106A, an example second receiver 3106B, an example third receiver 3106C, and an example fourth receiver 3106D, respectively. The cold plates 3105A, 3105B, 3105C, 3105D include an example first outlet 3108A, an example second outlet 3108B, an example third outlet 3108C, and an example fourth outlet 3108D, respectively.

In the illustrated example of FIG. 31, the receivers 3106A, 3106B, 3106C, 3106D receive coolant from an example first tube 3110A, an example second tube 3110B, an example third tube 3110C, and an example fourth tube 3110D. In the illustrated example of FIG. 31, the tubes 3110A, 3110B, 3110C, 3110D receive coolant from example piping 3116, which is pumped by an example pump 3118. In the illustrated example of FIG. 31, the first tube 3110A and the third tube 3110C are connected to the piping 3116 via an example first connector 3120A. In the illustrated example of FIG. 31, the second tube 3110B and the fourth tube 3110D are connected to the piping 3116 via an example second connector 3120B. In the illustrated example of FIG. 31, the tubes 3110A, 3110B, 3110C, 3110D have a generally circular cross-section. In other examples, the tubes 3110A, 3110B, 3110C, 3110D can have any suitable shape. In The example tank 3101 of FIG. 31 is a single phase immersion cooling tank. For example, the coolant 2806 enters the tank 3101 via the inlet 2808, flows through the tank in flow direction 2810, and exits the tank through an outlet (not illustrated). During operation of the tank 3101, the coolant enters and leaves the tank 3101 (e.g., via natural flow, via one or more pump(s) of the CDU 2812, etc.) at a constant and equal or substantially constant and equal rate, thereby maintaining the coolant 2806 at a constant or substantially constant level.

The chassis 3102 is disposed in (e.g., supported by, coupled within) the tank 3101. The chassis 3102 includes (e.g., carries) the compute units 3103A, 3103B, 3104A, 3104B and other compute components (e.g., power supply, permeant memory, temporary memory, etc.). The chassis 3102 can include additional or fewer compute components and/or types of compute components than the example shown in FIG. 31. In the illustrated example of FIG. 31, the chassis 3102 has a shadowed form factor (e.g., the first upstream compute unit 3103A and the first downstream compute unit 3104A are disposed in sequence, the second upstream compute unit 3103B and the second downstream compute unit 3104B, etc.). In other examples, the compute units 3103A, 3103B, 3104A, 3104B of the chassis 3102 can have any suitable orientation(s)/layout(s)/form factor(s) (e.g., spreadcore, etc.). Operation of the compute components of the chassis 3102 generates a heat, which is absorbed and dissipated via the circulation of the coolant through the tank 3001 and the cold plates 3105A, 3105B, 3105C, 3105D. The tank 3101 can include a plurality of additional chassis disposed in parallel to the chassis 3102, where compute components thereof are similarly cooled via the circulation of the coolant through the tank 3101.

In the illustrated example of FIG. 31, the cold plates 3105A, 3105B, 3105C, 3105D are coupled to respective ones of the compute units associated with the 3103A, 3103B, 3104A, 3104B, etc. In some examples, the cold plates 3105A, 3105B, 3105C, 3105D can include a pad (not illustrated) that abuts an internal heat sink (IHS) of a compute component (e.g., an integrated circuit (IC)) associated with corresponding ones of the compute units 3103A, 3103B, 3104A, 3104B. In the illustrated example of FIG. 31, the pump 3118 pumps the coolant 2806 from the tank 3101 into the piping 3116, then into corresponding ones of the tubes 3110A, 3110B, 3110C, 3110D into respective ones of the receivers 3106A, 3106B, 3106C, 3106D. In some examples, after the coolant 2806 enters the cold plates 3105A, 3105B, 3105C, 3105D, the coolant 2806 flows through respective internal flow circuits (not illustrated) and is expelled via respective ones of the example outlets 3108A, 3108B, 3108C, 3108D. As the coolant 2806 flows through the flow circuits of the cold plates 3105A, 3105B, 3105C, 3105D, the coolant 2806 absorbs heat from the body of the cold plates 3105A, 3105B, 3105C, 3105D, thereby cooling the compute units 3103A, 3103B, 3104A, 3104B.

In the illustrated example of FIG. 31, the immersion cooling system 3100 includes the example tubes 3110A, 3110B, 3110C, 3110D to direct coolant from the piping 3116 to cold plates 3105A, 3105B, 3105C, 3105D. In some examples, some or all of the tubes 3110A, 3110B, 3110C, 3110D can be flexible tubes (e.g., rubber tubes, plastic tubes, etc.). Additionally or alternatively, some or all of the tubes 3110A, 3110B, 3110C, 3110D can be rigid or substantially rigid tubes (e.g., metal piping, plastic tubes, etc.). In some examples, some or all of the tubes 3110A, 3110B, 3110C, 3110D can be insulated to reduce heat transfer between the coolant in the corresponding ones of the tubes 3110A, 3110B, 3110C, 3110D and the ambient environment. In some examples, the tubes 3110A, 3110B, 3110C, 3110D include scaling mechanisms (e.g., seals, gaskets, etc.) to prevent coolant 2806 in the tubes 3110A, 3110B, 3110C, 3110D from leaking into the tank 3101.

In the illustrated example of FIG. 31, the first tube 3110A and the third tube 3110C are connected to the piping 3116 via the first connector 3120A. In the illustrated example of FIG. 31, the second tube 3110B and the fourth tube 3110D are connected to the piping 3116 via the second connector 3120B. In some examples, the connectors 3120A, 3120B are QD connectors. In some such examples, the connectors 3120A, 3120B can include a togglable self-lock mechanism, which can be enabled/disabled to enable the installation/removal of the corresponding units 3103A, 3103B, 3104A, 3104B without stopping the functioning of the other units. In other examples, the connectors 3120A, 3120B can be implemented by any other suitable connector. In some examples, the tubes 3110A, 3110B, 3110C, 3110D and/or the connectors 3120A, 3120B can include features (e.g., snap-fit features, one or more slides, one or more self-alignment features, etc.) that enable to blind mating between the tubes 3110A, 3110B, 3110C, 3110D and/or the connectors 3120A, 3120B (e.g., mating without the use of hand tools, etc.).

The receivers 3106A, 3106B, 3106C, 3106D of the cold plates 3105A, 3105B, 3105C, 3105D are coupled to the respective ones of the tubes 3110A, 3110B, 3110C, 3110D. In the illustrated example of FIG. 31, the receivers 3106A, 3106B, 3106C, 3106D are disposed on a front surface of the cold plates 3105A, 3105B, 3105C, 3105D (e.g., when the cold plates 3105A, 3105B, 3105C, 3105D are oriented as shown in FIG. 31). In other examples, the receivers 3106A, 3106B, 3106C, 3106D can be disposed at any other suitable location of the 3106A, 3106B, 3106C, 3106D.

The pump 3118 pumps the coolant 2806 into the cold plates 3105A, 3105B, 3105C, 3105D from the main flow path of the tank 3101. The pump 3118 can be powered by a dedicated power supply associated with the cold plates 3105A, 3105B, 3105C, 3105D or a power supply associated with respective ones of the cold plates 3105A, 3105B, 3105C, 3105D. In some examples, the pump 3118 can be implemented by one or more centrifugal pump(s). In other examples, some or all of the pump 3118 can be implemented by one or more of any other suitable type of pump (e.g., a positive-displacement pump, an axial-flow pump, an impulse pump, a rotodynamic pump, etc.) or a combination thereof. The pump 3118 increases the local flow rate of the coolant 2806 over the compute units 3103A, 3103B, 3104A, 3103B. As such, the pump 3118 and the cold plates 3105A, 3105B, 3105C, 3105D improve the efficiency of the convection cooling of the compute units 3103A, 3103B, 3104A, 3103B by the coolant 2806.

In the illustrated example of FIG. 31, the pump 3118 is disposed on a bottom of the tank 3101 and is adjacent the inlet 2808 (e.g., in the orientation of FIG. 31). For example, the pump 3118 can be coupled to an example bottom surface 3122 of the tank 3101 and/or a side of the tank 3101 near the bottom surface 3122 of the tank 3101. In other examples, the pump 3118 can be coupled to any other suitable location on the tank 3101. In the illustrated example of FIG. 31, the pump 3118 draws the coolant 2806 from the main reservoir of the tank 3101. In other examples, the pump 3118 can draw coolant from any suitable source (e.g., directly from the CDU 2812, etc.).

In the illustrated example of FIG. 31, the cold plates 3105A, 3105B, 3105C, 3105D mitigate (e.g., fully mitigate, partly mitigate, etc.) the effects of coolant preheat on the convection cooling of the downstream units 3104A, 3104B by drawing coolant 2806 near the inlet 2808, which, in this example, is the coolant 2806 having the lowest temperature available for cooling the compute component of the chassis 3102. As such, the coolant 2806 used to cool the compute units 3103A, 3103B, 3104A, 3104B (e.g., the coolant 2806 circulating through the cold plates 3105A, 3105B, 3105C, 3105D, etc.) is approximately equal in temperature as the coolant 2806 of the inlet 2808 and is approximately the same temperature for cooling both the upstream compute units 3103A, 3103B and the downstream units 3104A, 3104B. Accordingly, the downstream units 3104A, 3104B are not subjected to coolant preheat that could otherwise be caused by the cooling of the upstream units 3103A, 3103B. In the illustrated example of FIG. 31, the outlets 3108A, 3108B, 3108C, 3108D can extend an entire or substantially entire width of the tops of the cold plates 3105A, 3105B, 3105C, 3105D (e.g., because the cold plates 3105A, 3105B, 3105C, 3105D do not draw coolant from the coolant of the immediate surrounding ones of the compute units 3103A, 3103B, 3104A, 3104B). In other examples, the outlets 3108A, 3108B, 3108C, 3108D can be at any suitable location on the cold plates 3105A, 3105B, 3105C, 3105D and/or be of any other suitable size.

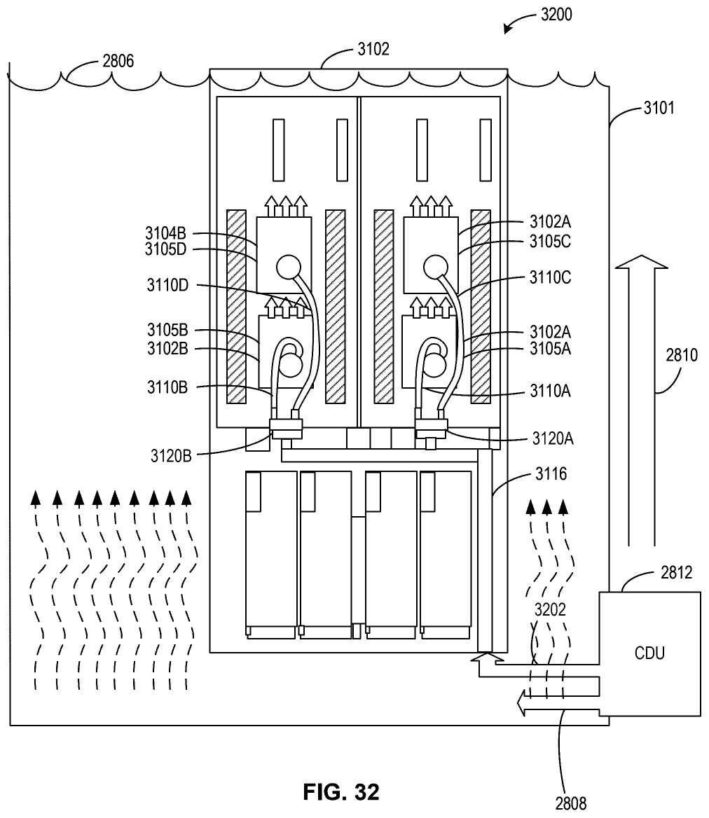

FIG. 32 is a front view of another example system 3200 including the tank 3101 of FIG. 31 and the chassis 3102 of FIG. 31 in accordance with teachings of this disclosure. Like the system 3100 of FIG. 31, the cold plates 3105A, 3105B, 3105C, 3105D mitigate (e.g., fully mitigate, partly mitigate, etc.) the effects of coolant preheat on the convection cooling of the downstream units 3104A, 3104B by drawing coolant 2806 near the inlet 2808, which, in this example, is the coolant 2806 having the lowest temperature available for cooling the compute components of chassis 3102. In the illustrated example of FIG. 32, the coolant 2806 flows through the piping 3116, into the connectors 3120A, 3120B, into respective ones of the tubes 3110A, 3110B, 3110C, 3110D, and then into the cold plates 3105A, 3105B, 3105C, 3105D.

The example system 3200 of FIG. 32 includes an example second inlet 3202 that couples the piping 3116 directly to the CDU 2812. In the illustrated example of FIG. 32, the second inlet 3202 is located at a bottom of the tank 3102 and adjacent to the first inlet 2808 (e.g., similar to the inlet 2008 of FIGS. 20 and 21, etc.). In some examples, the second inlet 3202 can be absent. In some such examples, the piping 3116 can be coupled to any other source of coolant. In some examples, coolant from the CDU 2812 is pumped (e.g., via a pump associated with the second inlet 3202, via a pump associated with the CDU 2812, etc.) into the piping 3116.

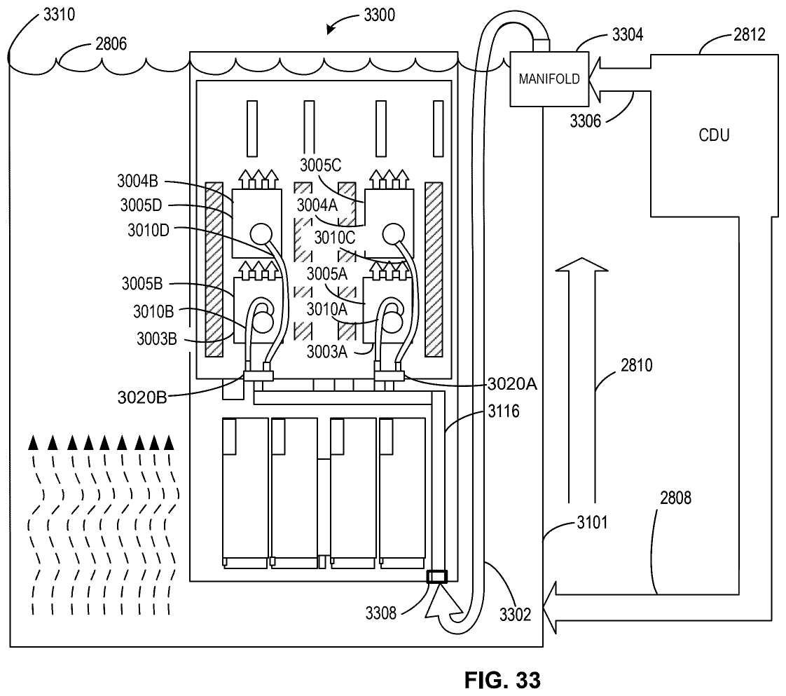

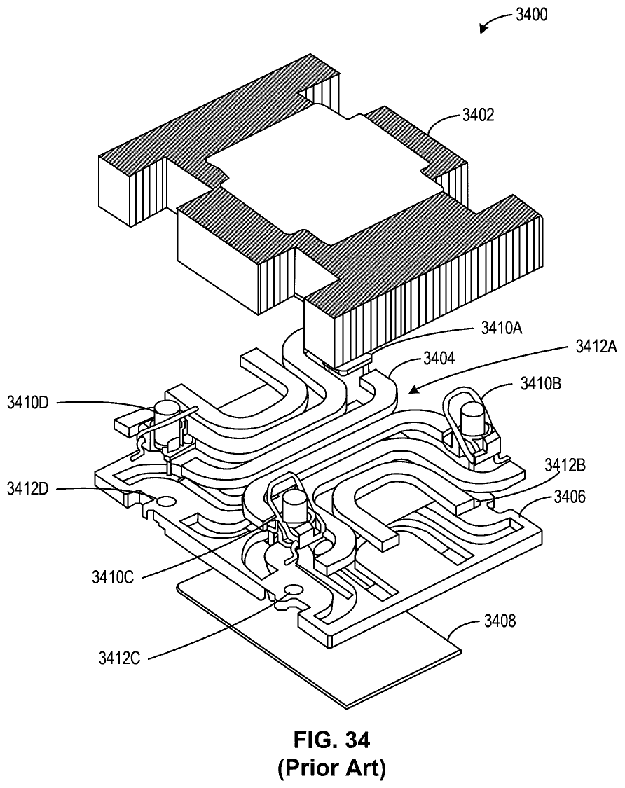

FIG. 33 is a front view of another example system 3300 including the tank 3101 of FIG. 31 and the chassis 3102 of FIG. 31 in accordance with teachings of this disclosure. As disclosed in connection with the system 3100 of FIG. 31, the cold plates 3105A, 3105B, 3105C, 3105D mitigate (e.g., fully mitigate, partly mitigate, etc.) the effects of coolant preheat on the convection cooling of the downstream units 3104A, 3104B by drawing coolant 2806 near the inlet 2808, which, in this example, is the coolant 2806 having the lowest temperature available for cooling the compute components of the chassis 3102. In the illustrated example of FIG. 32, the coolant 2806 flows through the piping 3116, into the connectors 3120A, 3120B, into respective ones of the tubes 3110A, 3110B, 3110C, 3110D, and then into the cold plates 3105A, 3105B, 3105C, 3105D.

The example system 3300 of FIG. 32 includes example inlet tube 3302, an example manifold 3304, and an example manifold inlet 3306. In the illustrated example of FIG. 33, coolant from the CDU 2812 flows from the manifold inlet 3302 into the manifold 3304. The coolant leaves the manifold 3304 and flows through the manifold tube 3302 into the piping 3116. In the illustrated example of FIG. 33, the manifold 3304 is coupled to an example lip 3310 of the tank 3101 that couples the inlet 3306 and the manifold tube 3302.

The manifold tube 3302 can be insulated to reduce heat transfer between the coolant in the tube 3302 and the ambient environment. In some examples, the manifold tube 3302 can include sealing mechanisms (e.g., seals, gaskets, etc.) to prevent coolant 2806 in the manifold tube 3302 from leaking into the tank 3101. While the manifold tube 3302 is depicted as inside the tank 3001 and submerged in the coolant 2806, in other examples, the manifold tube 3302 can extend along an external surface of the tank 3101 and/or be partially submerged in the coolant 2806. In the illustrated example, the manifold tube 3302 is coupled to the piping 3116 via an example connector 3308. In some examples, the connector 3308 can be a quick disconnect connector and/or a blind connector. In some such examples, the connector 3308 can enable the installation/removal of the corresponding chassis 3102 within the tank 3101 without manual installation of the chassis 3102.

FIG. 34 is an exploded view of a prior heat sink 3400. In FIG. 34, the heat sink 3400 includes fins 3402, heat pipes 3404, a pipe carrier 3406, a base plate 3408, a first fastener 3410A, a second fastener 3410B, a third fastener 3410C, and a fourth fastener 3410D. In FIG. 34, the pipe carrier 3406 includes a first hole 3412A, a second hole 3412B, a third hole 3412C, and a fourth hole 3412D. During operation, the heat sink 3400 absorbs heat generated by the operation of an electronic component such as a compute component or compute node (e.g., an integrated circuit (IC)) via the base plate 3408. The base plate 3408 transfers heat to the fins 3402 via heat pipes 3404, where the heat is distributed into the ambient environment via convection and/or radiation.

The fins 3402 absorb heat from the heat pipes 3404 and dissipate the heat into the ambient environment. The fins 3402 define a plurality of channels between individual ones of the fins 3402. The heat sink 3400 is typically disposed in an ambient environment that generates a flow of a fluid (e.g., forced airflow from a fan, flow of immersion fluid in the tanks of FIGS. 17A-33, etc.) through the fins 3402. Heat in the fins 3402 is dissipated via convection into the fluid, thereby cooling the heat sink 3400 and electronic component associated therewith (e.g., coupled thereto, in proximity to). The fins 3402 are typically composed of a thermally conductive material, such as copper and/or aluminum. In some examples, a fan can be coupled to the fins 3402 to generate a forced flow of fluid (e.g., air, water, immersion fluid, etc.).

The heat pipes 3404 are heat-transferring structures that transfer (e.g., conduct, etc.) heat between the base plate 3408 and/or the pipe carrier 3406 to the fins 3402. The heat pipes 3404 can include internal channels that include a fluid (e.g., ammonia, methanol, ethanol, water, mercury, etc.) that vaporizes as the fluid absorbs heat from the base plate 3408 and the pipe carrier 3406. The vapor can travel to a portion (e.g., a top, etc.) of the heat pipes 3404 adjacent to the fins 3402, dissipate heat into the fins 3402, and condense into a liquid and return to a portion of the heat pipes 3404 close to the base plate 3408 (e.g., via gravity, via capillary action, etc.). The body of the heat pipes 3404 is typically composed of a highly conductive material, such as copper, aluminum, silver, etc. The internal region(s) of the heat pipes 3404 can have a wick/capillary design (e.g., a grooved wick design, a sintered wick design, mesh-weave wick design, etc.). The thermal conductivity and cooling efficacy of the heat pipes 3404 depend on the material of the heat pipe, the fluid disposed therein, and the geometry of the heat pipes 3404. In FIG. 34, the heat pipes 3404 are retained by the pipe carrier 3406. The pipe carrier 3406 includes channel to carry the heat pipes 3404.

The base plate 3408 of the heat sink 3400 abuts, for instance, an integrated circuit (IC) package (e.g., a CPU, etc.). The base plate 3408 can be in thermal contact with the integrated heat sink (IHS) of an IC package. Typically, a thermally conductive paste is disposed between the base plate 3408 and the IHS to improve the rate of conduction between the IC package and the heat sink 3400. The base plate 3408 is typically composed of a thermally conductive material (e.g., copper, aluminum, etc.).

While the prior heat sink 3400 dissipates heat generated from IC packages, the prior heat sink 3400 may reduce cooling efficacy for large server applications, such as those associated with the data centers of 102, 106, 116 and/or building(s) 110 of FIG. 1 and/or the data center 200 of FIG. 2. For example the heat sink 3400 is a passive heat sink and does not provide for local distribution of the flow of coolant over the heat sink 3400. Instead, the heat sink 3400 may be in an ambient environment that typically includes a pump that can regulate the flow over a plurality of heat sinks (e.g., all the heats in a specific tank, etc.). In some such examples, adjusting the pump power and/or flow rate through the tank has a minimal effect on the flow of coolant over the heat sink 3400. Additionally, increasing pump power and/or flow rate through a tank to increase the flow rate over a specific node (e.g., an overheating compute component, etc.) of the tank disproportionally increases electricity demand and can increase the total cost of operation of the server and/or data center.

Further, the comparatively large flow impedance (e.g., flow resistance, etc.) associated with the fins 3402 can impede cooling efficacy provided by the heat sink 3400. When compared to other components coupled to the chassis of immersion tanks (e.g., memory, power supplies, etc.), the fins 3402 have a comparatively large amount of surface area, which reduces the local flow rate through the fins 3402 due to flow resistance. As such, increasing the flow rate of coolant through a tank may not proportionally increase the flow rate of coolant over the fins 3402 due to the flow resistance of the fins 3402, thereby causing the increased flow of coolant (or a substantial portion thereof) to bypass the fins by flowing through areas of lower impedance. The comparatively large amount of coolant that bypasses the fins 3402 can reduce the effectiveness of the heat sink 3400 and can limit on the performance of the heat sink 3400.

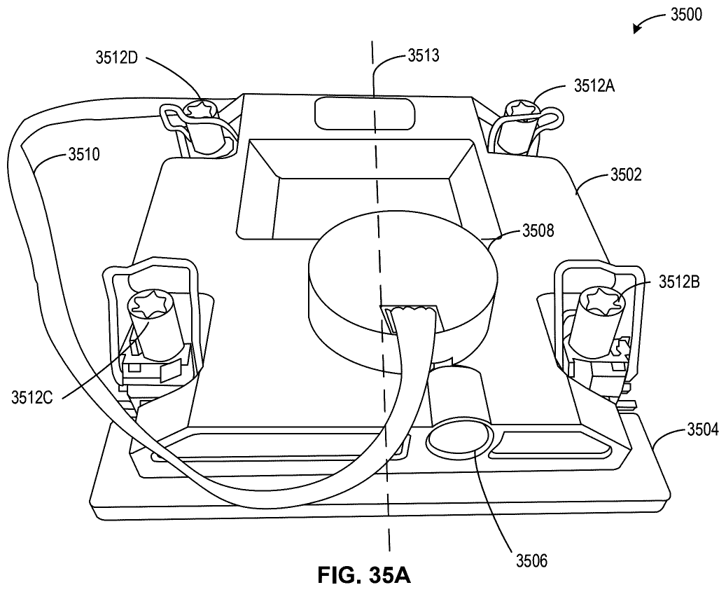

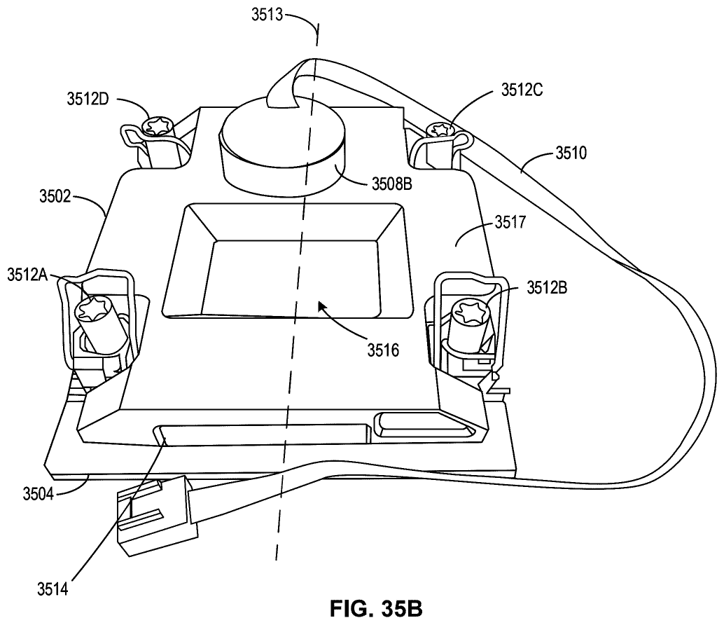

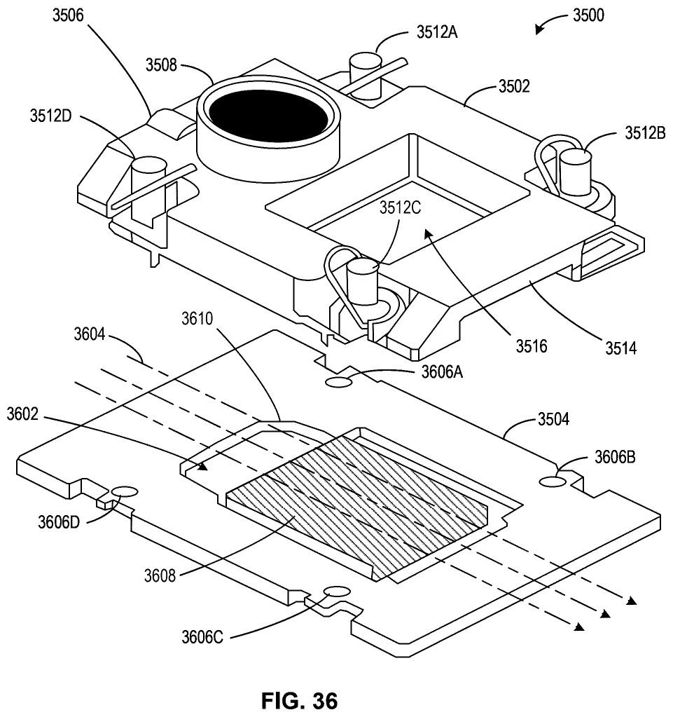

The prior heat sink 3400 also does not compensate for coolant preheat. As mentioned above, coolant preheat can reduce the effectiveness of immersion cooling of downstream nodes in particular chassis configurations. For example, in spreadcore configurations, upstream nodes dissipate heat into coolant, which is subsequently encountered by downstream nodes. If such nodes have passive heat sinks such as the heat sink 3400, the effectiveness of the downstream heat sinks is reduced due to the comparatively warm coolant flowing through the fins 3402. The example cold plates disclosed with reference to FIGS. 35A-36 address the above-noted deficiencies using, for instance, active pumping systems.

FIGS. 35A and 35B are perspective views of a cold plate 3500 in accordance with teachings of this disclosure. The example cold plate 3500 can be used to implement one or more cold plates 2905A, 2905B, 2905C, 2905D of FIGS. 29A and 29B and/or cold plates 3005A, 3005B, 3005C, 3005D of FIG. 30. In the illustrated example of FIGS. 35A and 35B, the cold plate 3500 includes an example top cover 3502 (where the reference to top is relative to the orientation of the cold plate 3500 shown in FIGS. 35A and 35B), an example base plate 3504, an example inlet 3506, an example integrated pump 3508, an example power cable 3510, an example first fastener 3512A, an example second fastener 3512B, an example third fastener 3512C, an example fourth fastener 3512D, and an example outlet 3514. In the illustrated example of FIG. 35, the top cover 3502 includes an example depressed portion 3516 formed on an example top surface 3517 of the top cover 3502.

In the illustrated example of FIGS. 35A and 35B, the top cover 3502 of the cold plate 3500 is a single integral component (e.g., a casted component, a machined component, an additive component, etc.). In other examples, the top cover 3502 can be composed of multiple components. The top cover 3502 can be composed of any suitable material (e.g., steel, aluminum, copper, cast iron, a composite, a plastic, etc.).

The base plate 3504 of the cold plate 3500 abuts, for instance, an integrated circuit (IC) package (e.g., a CPU, etc.). The base plate 3504 can be in thermal contact with the integrated heat sink (IHS) of an IC package. In some examples, a thermally conductive paste is disposed between the base plate 3504 and the IHS to increase the rate of conduction between the IC package and the base plate 3504. In the illustrated example of FIG. 35, the base plate 3504 and the top cover 3502 define a flow path for the coolant received by the inlet 3506 and the outlet 3514. The base plate 3504 directly dissipates heat into the received coolant via convection. In some examples, the base plate 3504 can include features (e.g., fins, skived features, etc.) that increase the rate of convection between the base plate 3504 and the coolant flowing through the base plate 3504. The base plate 3504 can be composed of a thermally conductive material (e.g., copper, aluminum, silver, gold, etc.). In other examples, the base plate 3504 can be composed of any other suitable material. The internal geometry of the example base plate 3504 is disclosed in greater detail below in conjunction with FIG. 35.

The top cover 3502 and the base plate 3504 are coupled together to form the cold plate 3500. In some examples, the top cover 3502 and the base plate 3504 are coupled via the fasteners 3512A, 3512B, 3512C, 3512D. Additionally or alternatively, the top cover 3502 and the base plate 3504 can be coupled via one or more welds, one or more other fasteners, one or more chemical adhesives, one or more shrink fits, one or more press fits, etc. In other examples, the top cover 3502 and the base plate 3504 can be integral components. In some such examples, the top cover 3502 and the base plate 3504 can be formed via additive manufacturing.

The inlet 3506 is an opening formed by a gap between the top cover 3502 and the base plate 3504. In the illustrated example of FIG. 35, the inlet 3506 is a circular opening (e.g., a cylindrical hole, etc.) on a side surface of the top cover 3502. In other examples, the inlet 3506 can have any other suitable shape. In some examples, the inlet 3506 is shaped to receive a coolant tube (e.g., one of the pipes 3010A, 3010B, 3010C, 3010D of FIG. 30, one of the tubes 3110A, 3110B, 3110C, 3110D, etc.). In other examples, the inlet 3506 can have any other suitable shape (e.g., rectangular, ovoid, elliptical, polygonal, etc.). Additionally or alternatively, the inlet 3506 can directly draw coolant from the ambient environment of the cold plate 3500. In the illustrated example of FIG. 35, the inlet 3506 is axially aligned (e.g., relative to the centerline axis 3513 of the pump 3508, etc.) with the pump 3508. In other examples, the inlet 3506 can be disposed at any other suitable location on the top cover 3502 and/or the base plate 3504 (e.g., on the top surface 3517, etc.).

The pump 3508 pumps coolant into the cold plate 3500 (e.g., into a cavity defined by the top cover 3502 and base plate 3504, etc.). In the illustrated example of FIG. 35, the pump 3508 is disposed on the top surface 3517 of the cold plate 3500 adjacent the inlet 3506. In other examples, the pump 3508 can be disposed at any other suitable location on the top cover 3502 and/or the base plate 3504. In other examples, the pump 3508 can be external to the cold plate 3500. In the illustrated example of FIG. 35, the pump 3508 receives power from the power cable 3510. In some examples, the power cable 3510 can be electrically coupled to a power supply associated with the compute node associated with the cold plate 3500. In other examples, the power cable 3510 can be absent. In some such examples, the cold plate 3500 can receive power from another power supply associated with the node (e.g., directly from a PCB, etc.). In some examples, the pump 3508 can be powered via a power source of the chassis. In some examples, the pump 3508 can be implemented by a centrifugal pump. In other examples, the pump 3508 can be implemented by one or more of any other suitable type of pump (e.g., a positive-displacement pump, an axial-flow pump, an impulse pump, a rotodynamic pump, etc.) or a combination thereof. In some examples, the pump 3508 and the inlet 3506 are integral components. In other examples, the pump 3508 and the inlet 3506 can be separate components. In some such examples, the pump 3508 can be disposed at any suitable location on the cold plate 2905A.

The outlet 3514 is an opening formed by a gap between the top cover 3502 and the base plate 3504. In the illustrated example of FIG. 35, the inlet 3506 is a rectangular opening (e.g., a rectangular prism hole, etc.) defined in a side surface of the top cover 3502, opposite the side surface of the top cover 3502 including the inlet 3506. In other examples, the inlet 3506 can have any other suitable shape (e.g., rectangular, ovoid, elliptical, polygonal, etc.) and/or location at the cold plate 3500. In the illustrated example of FIG. 35, the outlet 3514 is configured to expel coolant into the ambient environment of the cold plate 3500 (e.g., into or directly into a flow path). In other examples, the outlet 3514 can shaped to receive a coolant tube. In some such examples, the outlet 3514 can expel coolant into a tube, which expels the coolant further downstream than the cold plate 3500 (e.g., downstream of the inlet of a downstream cold plate in sequence with the cold plate 3500, etc.). In the illustrated example of FIG. 35, the outlet 3514 is symmetrical about the centerline axis 3513. In other examples, the outlet 3514 can be at any other suitable location on the top cover 3502 and/or the base plate 3504 (e.g., on the top surface 3517, etc.).

The fasteners 3512A, 3512B, 3512C, 3512D can couple the cold plate 3500 to the components of the compute node. The fasteners 3512A, 3512B, 3512C, 3512D retain the cold plate 3500 on the chassis and/or to the other components of the node. The fasteners 3512A, 3512B, 3512C, 3512D can include a portion (e.g., a fastener body, etc.) that extends through the base plate 3504 and into a corresponding feature of the compute node (e.g., a back plate of the compute node, etc.). In the illustrated example of FIG. 35, the fasteners 3512A, 3512B, 3512C, 3512D are fixedly coupled to the top cover 3502. In other examples, the fasteners 3512A, 3512B, 3512C, 3512D can be fixedly coupled to any other portion of the cold plate 3500. In the illustrated example of FIG. 35, the fasteners 3512A, 3512B, 3512C, 3512D are polyetheretherketone (PEEK) nuts including anti-tilt features. In other examples, the fasteners 3512A, 3512B, 3512C, 3512D can be implemented by any other suitable fasteners.

FIG. 36 is an exploded view of the cold plate 3500 of FIGS. 35A and 35B depicting an example interior cavity 3602 defined by the coupling of the top cover 3502 and the base plate 3504. In the illustrated example, the inlet 3506, the interior cavity 3602, and the outlet 3514 define an example flow path 3604 for the coolant. In the illustrated example of FIG. 36, the base plate 3504 includes example holes 3606A, 3606B, 3606C, 3606D. In the illustrated example of FIG. 36, the interior cavity 3602 includes example fins 3608.

In the illustrated example of FIG. 36, the interior cavity 3602 is formed by a gap between the top cover 3502 and the base plate 3504. In the illustrated example of FIG. 36, the base plate 3504 includes an example depressed portion 3610. In some examples, the depressed portion 3610 can be formed via milling and/or any other suitable manufacturing process. In other examples, the depressed portion 3610 can be absent. The interior cavity 3602 includes the fins 3608. In the illustrated example of FIG. 36, the depressed portion 3516 of the top cover 3502 is aligned with the fins 3608 such that the coolant flowing through the flow path 3604 passes through the fins 3608. In some examples, a portion of the top cover 3502 associated with the base plate 3504 abuts the fins 3608. In other examples, a gap can be present between the fins 3608 and the top cover 3502.

In the illustrated example of FIG. 36, the fins 3608 increase the surface area of the base plate 3504 exposed to the flow path 3604, thereby increasing the rate of convection between the cold plate 3500 and the coolant. In the illustrated example of FIG. 36, the fins 3608 define a plurality of channels (e.g., microchannels, etc.) that are aligned with the flow path 3604. In other examples, the fins 3608 can define any other suitable channel structure(s) for coolant of the flow path 3604 to flow through. In some examples, the fins 3608 can be formed via skiving. In other examples, the fins 3608 can be formed by any other suitable manufacturing technique.

The holes 3606A, 3606B, 3606C, 3606C receive (e.g., circumvent, etc.) corresponding features of respective ones of the fasteners 3512A, 3512B, 3512C, 3512D. For example, the holes 3606A, 3606B, 3606C, 3606C enable the features of the fasteners 3512A, 3512B, 3512C, 3512D (e.g., threaded portions of the fasteners 3512A, 3512B, 3512C, 3512D, bodies of the fasteners 3512A, 3512B, 3512C, 3512D, etc.). In some examples, the holes 3606A, 3606B, 3606C, 3606C can be absent. In some such examples, the fasteners 3512A, 3512B, 3512C, 3512D can extend outside of the base plate 3504.

The base plate 3504 can be coupled to the compute nodes such that a bottom surface of the base plate 3504 is aligned with the fins 3608 adjacent to the IHS of the IC package. In operation, the base plate 3504 conducts heat from the IC package and into the fins 3608. As the pump 3508 causes coolant to flow through the flow path 3604, coolant removes heat from the fins 3608 and the other portions of the base plate 3504 via convection. After flowing through the flow path 3604, the coolant is expelled via the outlet 3514.

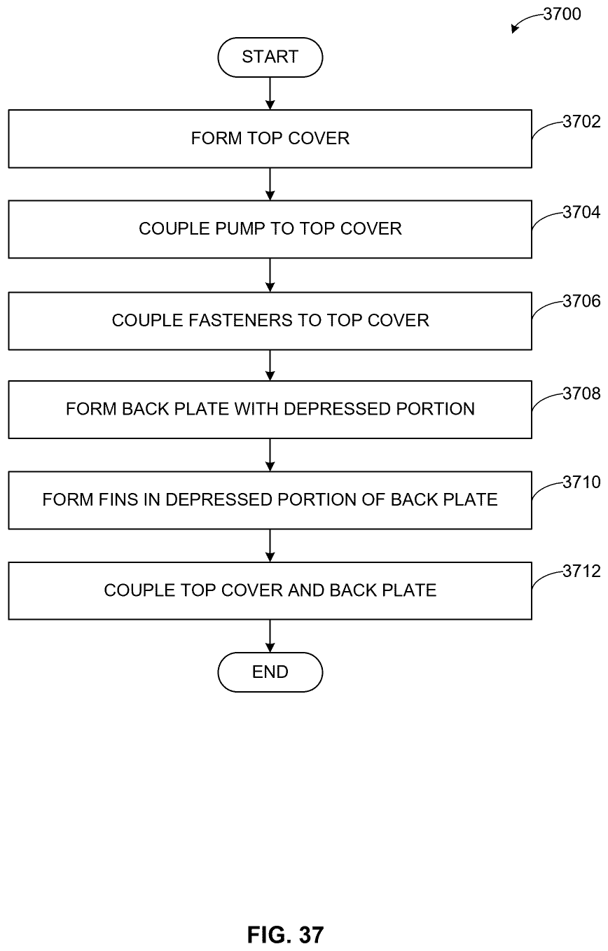

FIG. 37 is a flow diagram of example operations 3700 that can be used to assemble the cold plate of FIGS. 35A-36. The operations 3700 begin at block 3702, at which the top cover 3502 is formed. For example, the top cover 3502 can be manufactured via casting, machining, stamping, additive manufacturing, etc.). In some examples, the top cover 3502 can be composed of multiple components. In some such examples, the components of the top cover 3502 can be coupled by any suitable means. At block 3704, the pump 3508 is coupled to the top cover 3502. For example, the pump 3508 can be coupled to the top cover via one or more fasteners, one or more press fits, one or more shrink fits, one or more chemical adhesives, etc. At block 3706, the fasteners 3512A, 3512B, 3512C, 3512D are coupled to the top cover 3502. For example, the fasteners 3512A, 3512B, 3512C, 3512D are fixedly coupled to the top cover 3502 via one or more press fits and/or shrink fits. In other examples, the fasteners 3512A, 3512B, 3512C, 3512D can be coupled to the top cover in any other suitable manner.

At block 3708, the back plate 3504 with the depressed portion is formed. For example, the back plate 3504 can be manufactured via casting, machining, stamping, additive manufacturing, etc.). In some examples, the back plate 3504 can be composed of multiple components. In some such examples, the components of the back plate 3504 can be coupled by any suitable means. At block 3710, the fins are formed in the depressed portion of the back plate 3504. For example, the fins 3608 can be formed via skiving. In other examples, the fins 3608 can be formed by any other suitable manufacturing technique. At block 3712, the top cover 3502 and the back plate 3504 are coupled. For example, the top cover 3502 and the base plate 3504 are coupled via the fasteners 3512A, 3512B, 3512C, 3512D. Additionally or alternatively, the top cover 3502 and the base plate 3504 can be coupled via one or more welds, one or more other fasteners, one or more chemical adhesives, one or more shrink fits, one or more press fits, etc. In other examples, the top cover 3502 and the base plate 3504 can be integral components. In some such examples, the top cover 3502 and the base plate 3504 can be formed via additive manufacturing.

Although the example operations 3700 are described with reference to the flowchart illustrated in FIG. 37, many other methods of assembling the cold plate disclosed herein may alternatively be used. For example, the order of execution of the blocks may be changed, and/or some of the blocks described may be changed, eliminated, or combined.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities and/or steps, the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities and/or steps, the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements or method actions may be implemented by, e.g., the same entity or object. Additionally, although individual features may be included in different examples or claims, these may possibly be combined, and the inclusion in different examples or claims does not imply that a combination of features is not feasible and/or advantageous.

From the foregoing, it will be appreciated that example systems, methods, apparatus, and articles of manufacture have been disclosed that improve immersion cooling systems and/or facilitate cooling of electronic components within such cooling systems. Further examples and combinations thereof include the following:

Example 1 includes an immersion cooling chassis comprising a first face, a second face opposite the first face, a third face disposed between the first face and the second face, the third face perpendicular to the first face, a fourth face disposed between the first face and the second face, the fourth face perpendicular to the first face and opposite the third face, and a first portion to be cooled via a first convection of a coolant fluid, the first portion including a coolant inlet defined in the third face, and a coolant outlet defined in the first face, and a second portion to be cooled via a second convection of air, the second portion including an air inlet defined in the first face between the fourth face and the coolant outlet.

Example 2 includes the immersion cooling chassis of example 1, wherein the first portion is to house first electronic components and the second portion is to house second electronic components, the first electronic components having a greater average thermal power demand than the second electronic components.

Example 3 includes the immersion cooling chassis of examples 1 or 2, wherein the second portion includes at least one fan to direct airflow onto the second electronic components.

Example 4 includes the immersion cooling chassis of any of examples 1-3, wherein the second electronic components include at least one of a solid state drive or a hard disk drive, and the first electronic components include at least one of a central processing unit, a graphics processing unit, or a random access memory module.

Example 5 includes the immersion cooling chassis of any of examples 1-4, wherein the second portion includes an air outlet defined in the fourth face of the immersion cooling chassis.

Example 6 includes the immersion cooling chassis of any of examples 1-5, wherein the coolant outlet disposed proximate to the air inlet and distal to the third face.

Example 7 includes the immersion cooling chassis of any of examples 1-6, further including a fifth face disposed between the first face and the second face, the fifth face perpendicular to the third face, wherein the coolant outlet is a first coolant outlet, the first portion including a second coolant outlet defined in the fifth face.

Example 8 includes the immersion cooling chassis of any of examples 1-7, further including a wall disposed in the immersion cooling chassis between the first portion and the second portion.

Example 9 includes an apparatus comprising a tank defining a first flow path, the tank including a first inlet disposed in the first flow path, and a second inlet, and a tube to couple with a chassis disposed in the first flow path, the tube defining a second flow path from the second inlet to the chassis.

Example 10 includes the apparatus of example 9, further including a manifold, the manifold defining a manifold flow path to receive coolant from the second inlet of the tank, the manifold including a connector fluidly coupling the manifold flow path to the tube.

Example 11 includes the apparatus of examples 9 or 10, wherein the connector is a quick disconnect connector.

Example 12 includes the apparatus of any of examples 9-11, wherein the tube is a first tube and the tank further includes a rectification plate, the manifold including a second tube, the second tube extending through an opening defined in the rectification plate.

Example 13 includes the apparatus of any of examples 9-12, wherein the second inlet is coupled to an inlet line, the inlet line including a valve, and a flow meter.

Example 14 includes the apparatus of any of examples 9-13, wherein the tank further includes an outlet, the outlet in communication with the first flow path and the second flow path.

Example 15 includes the apparatus of any of examples 9-14, further including a nozzle disposed on a first end of the tube, the nozzle to be disposed upstream of a compute unit of the chassis when the tube is coupled to the chassis.

Example 16 includes an apparatus comprising a tank defining a first flow path for a coolant, and a chassis disposed in the first flow path, the chassis including a plate defining a second flow path, and a pump to intake the coolant from the first flow path into the second flow path.

Example 17 includes the apparatus of example 16, wherein the pump is disposed on a first face of the plate and the plate further includes an outlet disposed on a second face opposite the first face.

Example 18 includes the apparatus of any of examples 16-17, wherein the plate is a first plate, the pump is a first pump, the outlet is a first outlet, and wherein the chassis further includes a second plate is disposed in parallel and downstream of the first plate, the second plate including a second pump, and a second outlet.

Example 19 includes the apparatus of any of examples 16-18, wherein an axis extends through the first plate and the second plate, the first outlet and the second outlet disposed on a first side of the axis, and the first pump and the second pump disposed on a second side of the axis.

Example 20 includes the apparatus of any of examples 16-18, wherein the first outlet includes an outlet pipe, the outlet pipe to exhaust coolant downstream of the second pump.

Example 21 includes the apparatus of any of examples 16-20, wherein the tank includes a first inlet for the first flow path, the plate includes a second inlet for the second flow path, and further including a pipe coupled to the second inlet, the pipe having a third inlet adjacent to the first inlet.

Example 22 includes the apparatus of any of examples 16-21, wherein the plate is a first plate, the pipe is a first pipe, and wherein the chassis further includes a second plate downstream of the first plate, the second plate including a fourth inlet, and a second pipe coupling the fourth inlet to the first pipe.

Example 23 includes the apparatus of any of examples 16-22, wherein the first plate and the second plate are to expel coolant into the first flow path.

Example 24 includes a cold plate to be coupled to a compute component, the cold plate comprising a cover, a plate to be coupled to the compute component, the cover and the plate defining a flow path, and a pump coupled to at least one of the cover or the plate, the pump to cause a coolant to move through the flow path.

Example 25 includes the cold plate of example 24, wherein the cover includes an inlet at a first end of the flow path, the inlet to receive the coolant, and an outlet at a second end of the flow path, the outlet to expel the coolant.

Example 26 includes the cold plate of any of the examples 24 or 25, wherein the inlet is circular.

Example 27 includes the cold plate of any of examples 24-26, wherein the outlet is rectangular.

Example 28 includes the cold plate of any of examples 24-27, wherein the cover defines a centerline axis, the pump and the inlet offset from centerline axis.

Example 29 includes the cold plate of any of examples 24-28, wherein the plate includes fins disposed within the flow path.

Example 30 includes the cold plate of any of examples 24-29, wherein the fins define a plurality of channels, the channels aligned with the flow path.

Example 31 includes the cold plate of any of examples 24-30, wherein the cover includes a depressed portion, the depressed portion aligned with the fins.

Example 32 includes a method to assemble a cold plate, the method comprising coupling a cover to a plate to define a flow path, and disposing a pump within at least one of the cover or the plate, the pump to cause a coolant to move through the flow path.

Example 33 includes the method of example 32, further including forming the plate, and forming fins within a depressed portion of the plate.

Example 34 includes the method of any of examples 32 or 33, wherein the fins define a plurality of channels, the channels aligned with the flow path.

Example 35 includes the method of any of examples 32-34, further including forming an inlet in the cover at a first end of the flow path, the inlet to receive the coolant.

Example 36 includes the method of any of examples 32-35, wherein the inlet is circular.

Example 37 includes the method of any of examples 32-36, further including forming an outlet in the cover at a second end of the flow path, the outlet to expel the coolant.

Example 38 includes the method of any of examples 32-37, wherein the outlet is rectangular.

Example 39 includes an apparatus comprising a tank defining a first flow path for a coolant, and a plate to be disposed over a compute unit in the tank, the plate defining a second flow path, the plate including a pump to intake the coolant from the first flow path into the second flow path.

Example 40 includes the apparatus of example 39, wherein the pump is coupled to a first face of the plate and the plate further includes an outlet disposed on a second face on an opposite side of the plate.

Example 41 includes the apparatus of any of examples 39 or 40, wherein the plate is a first plate, the pump is a first pump, the outlet is a first outlet, and further including a second plate disposed in parallel and downstream of the first plate, the second plate including a second pump, and a second outlet.

Example 42 includes the apparatus of any of examples 39-41, wherein an axis extends through the first plate and the second plate, the first outlet and the second outlet disposed on a first side of the axis, and the first pump and the second pump disposed on a second side of the axis.

Example 43 includes the apparatus of any of examples 39-42, wherein the plate includes fins disposed within the second flow path.

Example 44 includes the apparatus of any of examples 39-43, wherein the fins define a plurality of channels, the channels aligned with the second flow path.

The following claims are hereby incorporated into this Detailed Description by this reference. Although certain example systems, methods, apparatus, and articles of manufacture have been disclosed herein, the scope of coverage of this patent is not limited thereto. On the contrary, this patent covers all systems, methods, apparatus, and articles of manufacture fairly falling within the scope of the claims of this patent.

1-44. (canceled)

45. An apparatus comprising:
a tank defining a first flow path, the tank including:
a first inlet in the first flow path; and
a second inlet; and
a tube to couple with a chassis in the first flow path, the tube defining a second flow path from the second inlet to a compute unit of the chassis.

46. The apparatus of claim 45, further including a manifold, the manifold defining a manifold flow path to receive coolant from the second inlet of the tank, the manifold including a connector fluidly coupling the manifold flow path to the tube.

47. The apparatus of claim 46, wherein the connector is a quick disconnect connector.

48. The apparatus of claim 46, wherein the tube is a first tube and the tank further includes a rectification plate, the manifold including a second tube, the second tube extending through an opening defined in the rectification plate.

49. The apparatus of claim 45, wherein the tank further includes an outlet, the outlet in communication with the first flow path and the second flow path.

50. The apparatus of claim 45, further including a nozzle on a first end of the tube, the nozzle upstream of the compute unit of the chassis.

51. A system including:
a tank defining a first flow path, the tank including:
a first inlet in the first flow path; and
a second inlet;
a chassis within the tank, the chassis supporting a compute unit, the chassis in the first flow path;
a heat sink thermally coupled to the compute unit; and
a tube coupled to the chassis, the tube defining a second flow path from the second inlet to the compute unit.

52. The system of claim 51, further including a manifold, the manifold defining a manifold flow path to receive coolant from the second inlet of the tank, the manifold including a connector fluidly coupling the manifold flow path to the tube.

53. The system of claim 52, wherein the connector is a quick disconnect connector.

54. The system of claim 52, wherein the tube is a first tube and the tank further includes a rectification plate, the manifold including a second tube, the second tube extending through an opening defined in the rectification plate.

55. The system of claim 51, wherein the tank further includes an outlet, the outlet to receive coolant from the first flow path and the second flow path.

56. The system of claim 51, further including a nozzle on a first end of the tube, the nozzle upstream of the compute unit.

57. An apparatus comprising:
a tank defining a first flow path for a coolant; and
a chassis in the first flow path, the chassis including:
a plate defining a second flow path; and
a pump to intake the coolant from the first flow path into the second flow path.

58. The apparatus of claim 57, wherein the pump is on a first face of the plate and the plate further includes an outlet on a second face opposite the first face.

59. The apparatus of claim 58, wherein the plate is a first plate, the pump is a first pump, the outlet is a first outlet, and wherein the chassis further includes a second plate is in parallel and downstream of the first plate, the second plate including:
a second pump; and
a second outlet.

60. The apparatus of claim 59, wherein an axis extends through the first plate and the second plate, the first outlet and the second outlet on a first side of the axis, and the first pump and the second pump on a second side of the axis.

61. The apparatus of claim 59, wherein the first outlet includes an outlet pipe, the outlet pipe to exhaust coolant downstream of the second pump.

62. The apparatus of claim 57, wherein the tank includes a first inlet for the first flow path, the plate includes a second inlet for the second flow path, and further including a pipe coupled to the second inlet, the pipe having a third inlet adjacent to the first inlet.

63. The apparatus of claim 62, wherein the plate is a first plate, the pipe is a first pipe, and wherein the chassis further includes:
a second plate downstream of the first plate, the second plate including a fourth inlet; and
a second pipe coupling the fourth inlet to the first pipe.

64. The apparatus of claim 63, wherein the first plate and the second plate are to expel a coolant into the first flow path.
